(19) United States
(12) Patent Application Publication
(10) Pub. No.: US 2022/0384395 A1
(43) Pub. Date: Dec. 1, 2022

(54) HIGH REFLECTIVITY WIDE BONDING PAD ELECTRODES

(71) Applicant: Meta Platforms Technologies, LLC, Menlo Park, CA (US)

(72) Inventors: Wei Sin TAN, Plymouth (GB); Samir MEZOUARI, Swindon (GB); Andrea PINOS, Plymouth (GB); John Lyle WHITEMAN, St. Austell (GB)

(21) Appl. No.: 17/332,621

(22) Filed: May 27, 2021

(51) Int. Cl. H01L 25/075; H01L 33/42; H01L 33/46; H01L 33/00

(52) U.S. Cl. CPC H01L 25/0753; H01L 33/42; H01L 33/46; H01L 33/0025; H01L 33/0075; H01L 2933/0016; H01L 2933/0058

(57) ABSTRACT

Disclosed herein are light emitting diode devices having one or more high reflectivity wide bonding pad electrodes and methods of fabricating thereof.

### BACKGROUND

Light emitting diodes (LEDs) convert electrical energy into optical energy, and offer many benefits over other light sources, such as reduced size, improved durability, and increased efficiency. LEDs can be used as light sources in many display systems, such as televisions, computer monitors, laptop computers, tablets, smartphones, projection systems, and wearable electronic devices. Micro-LEDs (“LEDs”) based on III-nitride semiconductors, such as alloys of AlN, GaN, InN, AlGaInP, other quaternary phosphide compositions, and the like, have begun to be developed for various display applications due to their small size (e.g., with a linear dimension less than 100 μm, less than 50 μm, less than 10 μm, or less than 5 μm), high packing density (and hence higher resolution), and high brightness. For example, micro-LEDs that emit light of different colors (e.g., red, green, and blue) can be used to form the sub-pixels of a display system, such as a television or a near-eye display system.

### SUMMARY

This disclosure relates generally to micro light emitting diodes (micro-LEDs). More specifically, this disclosure relates to micro-LEDs with one or more high reflectivity electrodes and methods of fabricating micro-LEDs with one or more high reflectivity electrodes.

According to some embodiments, a light emitting diode (LED) device includes a plurality of mesa structures. Each mesa structure includes (i) a layer of a first semiconductor material, (ii) an active layer formed on the layer of the first semiconductor material, the active layer configured to emit light, (iii) a layer of a second semiconductor material on the active layer, and (iv) a contact layer on the layer of the second semiconductor material. The LED device also includes a layer of a low index conductive material on sidewalls of the layer of the first semiconductor material of each mesa structure, the low index conductive material having a refractive index lower than the first semiconductor material. In addition, the LED device includes a first metal layer on at least a portion of sidewalls of each mesa structure, the first metal layer in contact with the layer of the low index conductive material. The layer of the low index conductive material is disposed between the first metal layer and the layer of the first semiconductor material.

According to some embodiments, a method of fabricating a light emitting diode (LED) device includes forming an LED layer stack comprising a layer of a first semiconductor material on a substrate, an active layer on the layer of a first semiconductor material, a layer of a second semiconductor material on the active layer, and a patterned contact layer on the layer of the second semiconductor material. The method also includes etching, using a mask layer, to remove peripheral regions of the active layer and the layer of the second semiconductor material from the LED layer stack to form one or more precursor mesa structures. The method also includes forming a dielectric layer on the one or more precursor mesa structures and etching, using the mask layer, to remove peripheral regions of the layer of the first semiconductor material to form one or more pixel mesa structures and forming a layer of low refractive index conductive material on sidewalls of the layer of the first semiconductor material of each mesa structure. In addition, the method includes forming a first metal layer on sidewalls of each pixel mesa structure of the one or more pixel mesa structures. The layer of low refractive index conductive material is disposed between the first metal layer and the layer of the first semiconductor material.

According to some embodiments, a light emitting diode (LED) device includes a plurality of mesa structures. Each mesa structure includes (i) a layer of a first semiconductor material, (ii) an active layer disposed on the layer of the first semiconductor material, the active layer configured to emit light, and (iii) a layer of a second semiconductor material on the active layer. The LED device also includes one or more transparent conductive layers disposed on the layer of second semiconductor material and a first metal layer in contact with the one or more transparent conductive layers. In addition, the LED device includes a layer of low refractive index material between the first metal layer and the one or more transparent conductive layers The layer of low refractive index material includes material having a refractive index lower than a refractive index of the second semiconductor material and/or material of the one or more conductive layers.

According to some embodiments, a method of fabricating a light emitting diode (LED) device includes forming an LED layer stack including a layer of a first semiconductor material grown on a substrate, an active layer on the layer of a first semiconductor material, a layer of a second semiconductor material on the active layer, and a patterned conductive oxide layer on the layer of the second semiconductor material. The method also includes etching, using a mask layer, to remove peripheral regions of the active layer and the layer of the second semiconductor material from the LED layer stack to form one or more precursor mesa structures and forming a first dielectric layer on the one or more precursor mesa structures. The method also includes etching, using the mask layer, to remove peripheral regions of the layer of the first semiconductor material to form one or more pixel mesa structures and depositing a metal contact layer on sidewalls of at least the layer of the first semiconductor material of the one or more pixel mesa structures. The method also includes depositing a dielectric material on the metal contact layer and between the one or more pixel mesa structures and opening a dielectric window in the dielectric material to the patterned conductive oxide layer. The method also includes depositing a second conductive oxide layer through the dielectric window to contact the patterned conductive oxide layer and depositing a second dielectric layer or a distributed Bragg reflector (DBR) on the second conductive oxide layer. In addition, the method includes opening a window in the second dielectric layer or the DBR, the window opened in a dead zone between adjacent mesa structures and forming a second metal layer in the window.

According to some embodiments, a light emitting diode (LED) device includes a plurality of mesa structures. Each mesa structure includes (i) a layer of a first semiconductor material, (ii) an active layer disposed on the layer of the first semiconductor material, the active layer configured to emit light; and (iii) a layer of a second semiconductor material on the active layer. The LED device also includes one or more conductive layers disposed on the layer of second semiconductor material and a first metal layer in contact with the one or more conductive layers. The LED device also includes a layer of a first low refractive index material between the first metal layer and at least one of the conductive layers. The layer of low refractive index material includes material having a refractive index lower than a refractive index of the second semiconductor material and/or material of the one or more conductive layers. The LED device also includes a layer of a second low index conductive material formed on sidewalls of the layer of the first semiconductor material of each mesa structure, the second low index conductive material having a refractive index lower than the first semiconductor material. In addition, the LED device includes a second metal layer formed on at least a portion of sidewalls of each mesa structure, the second metal layer in contact with the layer of the low index conductive material. The layer of the low index conductive material is disposed between the second metal layer and the layer of the first semiconductor material.

This summary is neither intended to identify key or essential features of the claimed subject matter, nor is it intended to be used in isolation to determine the scope of the claimed subject matter. The subject matter should be understood by reference to appropriate portions of the entire specification of this disclosure, any or all drawings, and each claim. The foregoing, together with other features and examples, will be described in more detail below in the following specification, claims, and accompanying drawings.

### BRIEF DESCRIPTION OF THE DRAWINGS

Illustrative embodiments are described in detail below with reference to the following figures.

FIG. 1 is a simplified block diagram of an example of an artificial reality system environment including a near-eye display according to certain embodiments.

FIG. 2 is a perspective view of an example of a near-eye display in the form of a head-mounted display (HMD) device for implementing some of the examples disclosed herein.

FIG. 3 is a perspective view of an example of a near-eye display in the form of a pair of glasses for implementing some of the examples disclosed herein.

FIG. 4 illustrates an example of an optical see-through augmented reality system including a waveguide display according to certain embodiments.

FIG. 5A illustrates an example of a near-eye display device including a waveguide display according to certain embodiments.

FIG. 5B illustrates an example of a near-eye display device including a waveguide display according to certain embodiments.

FIG. 6 illustrates an example of an image source assembly in an augmented reality system according to certain embodiments.

FIG. 7A illustrates an example of a light emitting diode (LED) having a vertical mesa structure according to certain embodiments.

FIG. 7B is a cross-sectional view of an example of an LED having a parabolic mesa structure according to certain embodiments.

FIG. 8A illustrates an example of a method of die-to-wafer bonding for arrays of LEDs according to certain embodiments.

FIG. 8B illustrates an example of a method of wafer-to-wafer bonding for arrays of LEDs according to certain embodiments.

FIGS. 9A-9D illustrates an example of a method of hybrid bonding for arrays of LEDs according to certain embodiments.

FIG. 10 illustrates an example of an LED array with secondary optical components fabricated thereon according to certain embodiments.

FIG. 11 is a cross-sectional view of an example of an LED device with micro-LEDs having high reflectivity mesa sidewall electrodes (e.g., n-electrodes) according to certain embodiments.

FIG. 12 is a cross-sectional view of another example of an LED device with micro-LEDs having high reflectivity mesa sidewall electrodes (e.g., n-electrodes) according to certain embodiments.

FIG. 13 is a cross-sectional view of another example of an LED device with micro-LEDs having high reflectivity mesa sidewall electrodes (e.g., n-electrodes) according to certain embodiments.

FIGS. 14A-14H illustrates an example of a method of fabricating micro-LEDs with high reflectivity mesa sidewall electrodes according to certain embodiments.

FIG. 15 includes a simplified flowchart illustrating an example of a method of fabricating micro-LEDs with high reflectivity mesa sidewall electrodes according to certain embodiments.

FIG. 16 is a cross-sectional view of an example of an LED device with micro-LEDs having high reflectivity wide bonding pad electrodes (e.g., p-electrodes) according to certain embodiments.

FIG. 17 is a cross-sectional view of another example of an LED device with micro-LEDs having high reflectivity wide bonding pad electrodes (e.g., p-electrodes) according to certain embodiments.

FIGS. 18A-18H illustrates an example of a method of fabricating micro-LEDs with high reflectivity wide bonding pad electrodes according to certain embodiments.

FIG. 19 includes a simplified flowchart illustrating an example of a method of fabricating micro-LEDs with high reflectivity wide bonding pad electrodes according to certain embodiments.

FIG. 20 is a cross-sectional view of an example of an LED device including micro-LEDs having both high reflectivity mesa sidewall electrodes and high reflectivity wide bonding pad electrodes according to certain embodiments.

FIGS. 21A-21L illustrates an example of a method of fabricating micro-LEDs with both high reflectivity mesa sidewall electrodes and high reflectivity wide bonding pad electrodes according to certain embodiments.

FIG. 22 includes a simplified flowchart illustrating an example of a method of fabricating micro-LEDs with both high reflectivity mesa sidewall electrodes and high reflectivity wide bonding pad electrodes according to certain embodiments.

FIGS. 23A-23C includes plots of simulation data for examples of micro-LEDs according to certain embodiments.

FIGS. 24A-24C includes plots of simulation data for examples of micro-LEDs according to certain embodiments.

FIG. 25 is a simplified block diagram of an electronic system of an example of a near-eye display according to certain embodiments.

The figures depict embodiments of the present disclosure for purposes of illustration only. One skilled in the art will readily recognize from the following description that alternative embodiments of the structures and methods illustrated may be employed without departing from the principles, or benefits touted, of this disclosure.

In the appended figures, similar components and/or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

### DETAILED DESCRIPTION

This disclosure relates generally to light emitting diodes (LEDs). More specifically, and without limitation, disclosed herein are techniques for promoting internal reflection and improving light extraction from LEDs. Various inventive embodiments are described herein, including devices, systems, methods, materials, and the like.

Some LED arrays include individual mesa structures, each made of inorganic materials such as, for example, multiple layers of semiconductor materials. For example, a mesa structure may include an LED stack including an active layer grown on a layer of a first semiconductor material (e.g., an n-type semiconductor layer) and another layer of a second semiconductor material (e.g., a p-type semiconductor layer) grown on the active layer. For some LEDs, a metal electrode (e.g., an n-electrode) is formed on sidewalls of the layer of the first semiconductor material and another metal electrode (e.g., a p-electrode) is formed on a metal contact layer disposed on the layer of the second semiconductor material. In these constructs, the metal electrodes may partially reflect and at least partially absorb light from the active region of the LED stack, which can affect light extraction from the LEDs.

According to certain embodiments, an LED device includes one or more layers of low index of refraction materials between the LED stack and one or both of the metal electrodes. This layer or layers of low index of refraction materials have a lower refractive index than the semiconductor materials in the LED stack and may serve to cause constructive interference of the light emitted by the active region and reflect light before reaching the metal electrode(s) to reduce the amount of light that can be absorbed. The inclusion of this layer or layers of low index of refraction materials between the metal electrodes and the LED stack may promote total internal reflection (TIR) in the LED and improve light extraction from the LED.

In certain implementations, a micro-LED includes a layer of low refractive index conductive material (e.g., layer of ITO) formed on sidewalls of the mesa structure between the layer of the first semiconductor material and a metal (electrode) layer providing ohmic contact to the layer of the first semiconductor material. The layer of low refractive index conductive material has a lower index of refraction than the first semiconductor material and may cause constructive interference of light emitted by the active region of the LED stack promoting TIR and improving light extraction from micro-LED. The layer of low refractive index conductive material also maintains low resistance to the layer of first semiconductor material. In these implementations, the metal layer acts as a high reflectivity mesa sidewall electrode such as, e.g., a high reflectivity n-electrode. In addition or alternatively, the micro-LED may include a layer of low refractive index material or a distributed Bragg reflector (DBR) between the LED stack and another metal layer in ohmic contact with the layer of the second semiconductor material in the LED stack. The low refractive index material has a lower refractive index than the second semiconductor material and may also cause constructive interference of light emitted by the active region of the LED stack promoting total internal reflection and improving light extraction from the micro-LED. In these implementations, the other metal layer also acts as a high reflectivity wide bonding pad electrode (e.g., a p-electrode) with a wide footprint pad for bonding to a contact pad of, e.g., of a CMOS backplane with drive circuitry for an array of micro-LEDs in which the micro-LED is disposed. This wide footprint pad may relax the wafer alignment requirements during the bonding process and/or the associated tolerances in the sizes and locations of the contact pads in the circuit and/or in the micro-LEDs. This relaxation in the alignment requirements may result in cost savings in the bonding process and/or in fabricating the circuits and the array of micro-LEDs. In one of these implementations, the micro-LED also includes one or more layers of transparent conductive material, such as ITO, that are formed on the layer of the second semiconductor material which may help spread current to this layer. At least one of the layers of transparent conductive material may have a footprint larger than the footprint of the mesa structure that provides an end portion in a dead zone between adjacent mesa structures where the epitaxial layers have been etched. The metal layer in ohmic contact with the layer of the second semiconductor material may contact, via a metal plug for example, the end portion of this conductive material in the dead zone to avoid light absorption by the metal electrode. The location of the metal plug in the dead zone may be particularly advantageous in micro-LED implementations where the area of a metal plug may take up a large portion (e.g., 25%) of the active area in a small pixel micro-LED which may improve reflectivity and reduce absorption by the metal plug.

The micro-LEDs described herein may be used in conjunction with various technologies, such as an artificial reality system. An artificial reality system, such as a head-mounted display (HMD) or heads-up display (HUD) system, generally includes a display configured to present artificial images that depict objects in a virtual environment. The display may present virtual objects or combine images of real objects with virtual objects, as in virtual reality (VR), augmented reality (AR), or mixed reality (MR) applications. For example, in an AR system, a user may view both displayed images of virtual objects (e.g., computer-generated images (CGIs)) and the surrounding environment by, for example, seeing through transparent display glasses or lenses (often referred to as optical see-through) or viewing displayed images of the surrounding environment captured by a camera (often referred to as video see-through). In some AR systems, the artificial images may be presented to users using an LED-based display subsystem.

As used herein, the term “light emitting diode (LED)” refers to a light source that includes at least an n-type semiconductor layer, a p-type semiconductor layer, and a light emitting region (i.e., active region) between the n-type semiconductor layer and the p-type semiconductor layer. The light emitting region may include one or more semiconductor layers that form one or more heterostructures, such as quantum wells. In some embodiments, the light emitting region may include multiple semiconductor layers that form one or more multiple-quantum-wells (MQWs), each including multiple (e.g., about 2 to 6) quantum wells.

As used herein, the term “micro-LED” or “LED” refers to an LED that has a chip where a linear dimension of the chip is less than about 200 μm, such as less than 100 μm, less than 50 μm, less than 20 μm, less than 10 μm, or smaller. For example, the linear dimension of a micro-LED may be as small as 6 μm, 5 μm, 4 μm, 2 μm, or smaller. Some micro-LEDs may have a linear dimension (e.g., length or diameter) comparable to the minority carrier diffusion length. However, the disclosure herein is not limited to micro-LEDs, and may also be applied to mini-LEDs and large LEDs.

As used herein, the term “bonding” may refer to various methods for physically and/or electrically connecting two or more devices and/or wafers, such as adhesive bonding, metal-to-metal bonding, metal oxide bonding, wafer-to-wafer bonding, die-to-wafer bonding, hybrid bonding, soldering, under-bump metallization, and the like. For example, adhesive bonding may use a curable adhesive (e.g., an epoxy) to physically bond two or more devices and/or wafers through adhesion. Metal-to-metal bonding may include, for example, wire bonding or flip chip bonding using soldering interfaces (e.g., pads or balls), conductive adhesive, or welded joints between metals. Metal oxide bonding may form a metal and oxide pattern on each surface, bond the oxide sections together, and then bond the metal sections together to create a conductive path. Wafer-to-wafer bonding may bond two wafers (e.g., silicon wafers or other semiconductor wafers) without any intermediate layers and is based on chemical bonds between the surfaces of the two wafers. Wafer-to-wafer bonding may include wafer cleaning and other preprocessing, aligning and pre-bonding at room temperature, and annealing at elevated temperatures, such as about 250° C. or higher. Die-to-wafer bonding may use bumps on one wafer to align features of a pre-formed chip with drivers of a wafer. Hybrid bonding may include, for example, wafer cleaning, high-precision alignment of contacts of one wafer with contacts of another wafer, dielectric bonding of dielectric materials within the wafers at room temperature, and metal bonding of the contacts by annealing at, for example, 250-300° C. or higher. As used herein, the term “bump” may refer generically to a metal interconnect used or formed during bonding.

In the following description, for the purposes of explanation, specific details are set forth in order to provide a thorough understanding of examples of the disclosure. However, it will be apparent that various examples may be practiced without these specific details. For example, devices, systems, structures, assemblies, methods, and other components may be shown as components in block diagram form in order not to obscure the examples in unnecessary detail. In other instances, well-known devices, processes, systems, structures, and techniques may be shown without necessary detail in order to avoid obscuring the examples. The figures and description are not intended to be restrictive. The terms and expressions that have been employed in this disclosure are used as terms of description and not of limitation, and there is no intention in the use of such terms and expressions of excluding any equivalents of the features shown and described or portions thereof. The word “example” is used herein to mean “serving as an example, instance, or illustration.” Any embodiment or design described herein as “example” is not necessarily to be construed as preferred or advantageous over other embodiments or designs.

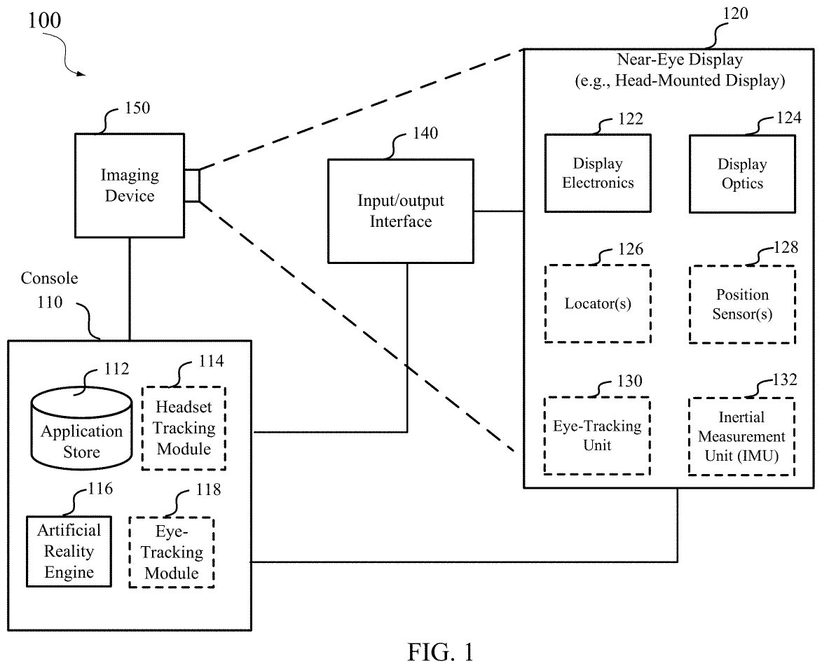

FIG. 1 is a simplified block diagram of an example of an artificial reality system environment 100 including a near-eye display 120 in accordance with certain embodiments. Artificial reality system environment 100 shown in FIG. 1 may include near-eye display 120, an optional external imaging device 150, and an optional input/output interface 140, each of which may be coupled to an optional console 110. While FIG. 1 shows an example of artificial reality system environment 100 including one near-eye display 120, one external imaging device 150, and one input/output interface 140, any number of these components may be included in artificial reality system environment 100, or any of the components may be omitted. For example, there may be multiple near-eye displays 120 monitored by one or more external imaging devices 150 in communication with console 110. In some configurations, artificial reality system environment 100 may not include external imaging device 150, optional input/output interface 140, and optional console 110. In alternative configurations, different or additional components may be included in artificial reality system environment 100.

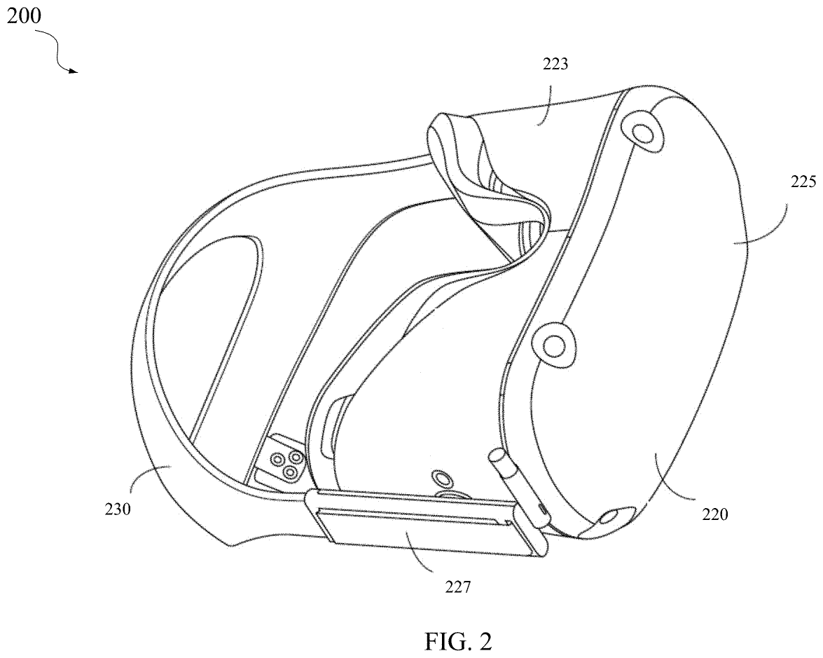

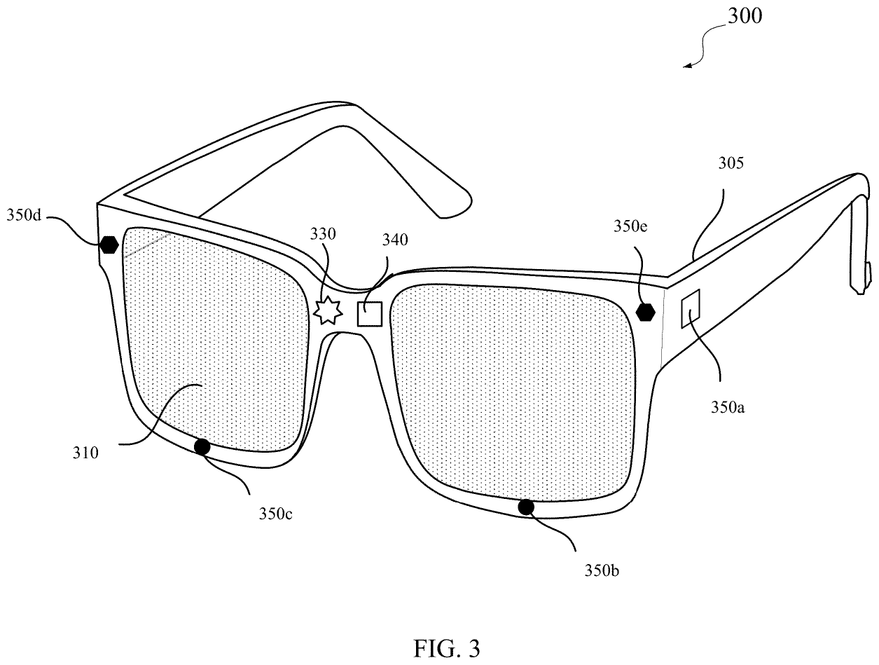

Near-eye display 120 may be a head-mounted display that presents content to a user. Examples of content presented by near-eye display 120 include one or more of images, videos, audio, or any combination thereof. In some embodiments, audio may be presented via an external device (e.g., speakers and/or headphones) that receives audio information from near-eye display 120, console 110, or both, and presents audio data based on the audio information. Near-eye display 120 may include one or more rigid bodies, which may be rigidly or non-rigidly coupled to each other. A rigid coupling between rigid bodies may cause the coupled rigid bodies to act as a single rigid entity. A non-rigid coupling between rigid bodies may allow the rigid bodies to move relative to each other. In various embodiments, near-eye display 120 may be implemented in any suitable form-factor, including a pair of glasses. Some embodiments of near-eye display 120 are further described below with respect to FIGS. 2 and 3. Additionally, in various embodiments, the functionality described herein may be used in a headset that combines images of an environment external to near-eye display 120 and artificial reality content (e.g., computer-generated images). Therefore, near-eye display 120 may augment images of a physical, real-world environment external to near-eye display 120 with generated content (e.g., images, video, sound, etc.) to present an augmented reality to a user.

In various embodiments, near-eye display 120 may include one or more of display electronics 122, display optics 124, and an eye-tracking unit 130. In some embodiments, near-eye display 120 may also include one or more locators 126, one or more position sensors 128, and an inertial measurement unit (IMU) 132. Near-eye display 120 may omit any of eye-tracking unit 130, locators 126, position sensors 128, and IMU 132, or include additional elements in various embodiments. Additionally, in some embodiments, near-eye display 120 may include elements combining the function of various elements described in conjunction with FIG. 1.

Display electronics 122 may display or facilitate the display of images to the user according to data received from, for example, console 110. In various embodiments, display electronics 122 may include one or more display panels, such as a liquid crystal display (LCD), an organic light emitting diode (OLED) display, an inorganic light emitting diode (ILED) display, a micro light emitting diode (μLED) display, an active-matrix OLED display (AMOLED), a transparent OLED display (TOLED), or some other display. For example, in one implementation of near-eye display 120, display electronics 122 may include a front TOLED panel, a rear display panel, and an optical component (e.g., an attenuator, polarizer, or diffractive or spectral film) between the front and rear display panels. Display electronics 122 may include pixels to emit light of a predominant color such as red, green, blue, white, or yellow. In some implementations, display electronics 122 may display a three-dimensional (3D) image through stereoscopic effects produced by two-dimensional panels to create a subjective perception of image depth. For example, display electronics 122 may include a left display and a right display positioned in front of a user's left eye and right eye, respectively. The left and right displays may present copies of an image shifted horizontally relative to each other to create a stereoscopic effect (i.e., a perception of image depth by a user viewing the image).

In certain embodiments, display optics 124 may display image content optically (e.g., using optical waveguides and couplers) or magnify image light received from display electronics 122, correct optical errors associated with the image light, and present the corrected image light to a user of near-eye display 120. In various embodiments, display optics 124 may include one or more optical elements, such as, for example, a substrate, optical waveguides, an aperture, a Fresnel lens, a convex lens, a concave lens, a filter, input/output couplers, or any other suitable optical elements that may affect image light emitted from display electronics 122. Display optics 124 may include a combination of different optical elements as well as mechanical couplings to maintain relative spacing and orientation of the optical elements in the combination. One or more optical elements in display optics 124 may have an optical coating, such as an anti-reflective coating, a reflective coating, a filtering coating, or a combination of different optical coatings.

Magnification of the image light by display optics 124 may allow display electronics 122 to be physically smaller, weigh less, and consume less power than larger displays. Additionally, magnification may increase a field of view of the displayed content. The amount of magnification of image light by display optics 124 may be changed by adjusting, adding, or removing optical elements from display optics 124. In some embodiments, display optics 124 may project displayed images to one or more image planes that may be further away from the user's eyes than near-eye display 120.

Display optics 124 may also be designed to correct one or more types of optical errors, such as two-dimensional optical errors, three-dimensional optical errors, or any combination thereof. Two-dimensional errors may include optical aberrations that occur in two dimensions. Example types of two-dimensional errors may include barrel distortion, pincushion distortion, longitudinal chromatic aberration, and transverse chromatic aberration. Three-dimensional errors may include optical errors that occur in three dimensions. Example types of three-dimensional errors may include spherical aberration, comatic aberration, field curvature, and astigmatism.

Locators 126 may be objects located in specific positions on near-eye display 120 relative to one another and relative to a reference point on near-eye display 120. In some implementations, console 110 may identify locators 126 in images captured by external imaging device 150 to determine the artificial reality headset's position, orientation, or both. A locator 126 may be an LED, a corner cube reflector, a reflective marker, a type of light source that contrasts with an environment in which near-eye display 120 operates, or any combination thereof. In embodiments where locators 126 are active components (e.g., LEDs or other types of light emitting devices), locators 126 may emit light in the visible band (e.g., about 380 nm to 750 nm), in the infrared (IR) band (e.g., about 750 nm to 1 mm), in the ultraviolet band (e.g., about 10 nm to about 380 nm), in another portion of the electromagnetic spectrum, or in any combination of portions of the electromagnetic spectrum.

External imaging device 150 may include one or more cameras, one or more video cameras, any other device capable of capturing images including one or more of locators 126, or any combination thereof. Additionally, external imaging device 150 may include one or more filters (e.g., to increase signal to noise ratio). External imaging device 150 may be configured to detect light emitted or reflected from locators 126 in a field of view of external imaging device 150. In embodiments where locators 126 include passive elements (e.g., retroreflectors), external imaging device 150 may include a light source that illuminates some or all of locators 126, which may retro-reflect the light to the light source in external imaging device 150. Slow calibration data may be communicated from external imaging device 150 to console 110, and external imaging device 150 may receive one or more calibration parameters from console 110 to adjust one or more imaging parameters (e.g., focal length, focus, frame rate, sensor temperature, shutter speed, aperture, etc.).

Position sensors 128 may generate one or more measurement signals in response to motion of near-eye display 120. Examples of position sensors 128 may include accelerometers, gyroscopes, magnetometers, other motion-detecting or error-correcting sensors, or any combination thereof. For example, in some embodiments, position sensors 128 may include multiple accelerometers to measure translational motion (e.g., forward/back, up/down, or left/right) and multiple gyroscopes to measure rotational motion (e.g., pitch, yaw, or roll). In some embodiments, various position sensors may be oriented orthogonally to each other.

IMU 132 may be an electronic device that generates fast calibration data based on measurement signals received from one or more of position sensors 128. Position sensors 128 may be located external to IMU 132, internal to IMU 132, or any combination thereof. Based on the one or more measurement signals from one or more position sensors 128, IMU 132 may generate fast calibration data indicating an estimated position of near-eye display 120 relative to an initial position of near-eye display 120. For example, IMU 132 may integrate measurement signals received from accelerometers over time to estimate a velocity vector and integrate the velocity vector over time to determine an estimated position of a reference point on near-eye display 120. Alternatively, IMU 132 may provide the sampled measurement signals to console 110, which may determine the fast calibration data. While the reference point may generally be defined as a point in space, in various embodiments, the reference point may also be defined as a point within near-eye display 120 (e.g., a center of IMU 132).

Eye-tracking unit 130 may include one or more eye-tracking systems. Eye tracking may refer to determining an eye's position, including orientation and location of the eye, relative to near-eye display 120. An eye-tracking system may include an imaging system to image one or more eyes and may optionally include a light emitter, which may generate light that is directed to an eye such that light reflected by the eye may be captured by the imaging system. For example, eye-tracking unit 130 may include a non-coherent or coherent light source (e.g., a laser diode) emitting light in the visible spectrum or infrared spectrum, and a camera capturing the light reflected by the user's eye. As another example, eye-tracking unit 130 may capture reflected radio waves emitted by a miniature radar unit. Eye-tracking unit 130 may use low-power light emitters that emit light at frequencies and intensities that would not injure the eye or cause physical discomfort. Eye-tracking unit 130 may be arranged to increase contrast in images of an eye captured by eye-tracking unit 130 while reducing the overall power consumed by eye-tracking unit 130 (e.g., reducing power consumed by a light emitter and an imaging system included in eye-tracking unit 130). For example, in some implementations, eye-tracking unit 130 may consume less than 100 milliwatts of power.

Near-eye display 120 may use the orientation of the eye to, e.g., determine an inter-pupillary distance (IPD) of the user, determine gaze direction, introduce depth cues (e.g., blur image outside of the user's main line of sight), collect heuristics on the user interaction in the VR media (e.g., time spent on any particular subject, object, or frame as a function of exposed stimuli), some other functions that are based in part on the orientation of at least one of the user's eyes, or any combination thereof. Because the orientation may be determined for both eyes of the user, eye-tracking unit 130 may be able to determine where the user is looking. For example, determining a direction of a user's gaze may include determining a point of convergence based on the determined orientations of the user's left and right eyes. A point of convergence may be the point where the two foveal axes of the user's eyes intersect. The direction of the user's gaze may be the direction of a line passing through the point of convergence and the mid-point between the pupils of the user's eyes.

Input/output interface 140 may be a device that allows a user to send action requests to console 110. An action request may be a request to perform a particular action. For example, an action request may be to start or to end an application or to perform a particular action within the application. Input/output interface 140 may include one or more input devices. Example input devices may include a keyboard, a mouse, a game controller, a glove, a button, a touch screen, or any other suitable device for receiving action requests and communicating the received action requests to console 110. An action request received by the input/output interface 140 may be communicated to console 110, which may perform an action corresponding to the requested action. In some embodiments, input/output interface 140 may provide haptic feedback to the user in accordance with instructions received from console 110. For example, input/output interface 140 may provide haptic feedback when an action request is received, or when console 110 has performed a requested action and communicates instructions to input/output interface 140. In some embodiments, external imaging device 150 may be used to track input/output interface 140, such as tracking the location or position of a controller (which may include, for example, an IR light source) or a hand of the user to determine the motion of the user. In some embodiments, near-eye display 120 may include one or more imaging devices to track input/output interface 140, such as tracking the location or position of a controller or a hand of the user to determine the motion of the user.

Console 110 may provide content to near-eye display 120 for presentation to the user in accordance with information received from one or more of external imaging device 150, near-eye display 120, and input/output interface 140. In the example shown in FIG. 1, console 110 may include an application store 112, a headset tracking module 114, an artificial reality engine 116, and an eye-tracking module 118. Some embodiments of console 110 may include different or additional modules than those described in conjunction with FIG. 1. Functions further described below may be distributed among components of console 110 in a different manner than is described here.

In some embodiments, console 110 may include a processor and a non-transitory computer-readable storage medium storing instructions executable by the processor. The processor may include multiple processing units executing instructions in parallel. The non-transitory computer-readable storage medium may be any memory, such as a hard disk drive, a removable memory, or a solid-state drive (e.g., flash memory or dynamic random access memory (DRAM)). In various embodiments, the modules of console 110 described in conjunction with FIG. 1 may be encoded as instructions in the non-transitory computer-readable storage medium that, when executed by the processor, cause the processor to perform the functions further described below.

Application store 112 may store one or more applications for execution by console 110. An application may include a group of instructions that, when executed by a processor, generates content for presentation to the user. Content generated by an application may be in response to inputs received from the user via movement of the user's eyes or inputs received from the input/output interface 140. Examples of the applications may include gaming applications, conferencing applications, video playback application, or other suitable applications.

Headset tracking module 114 may track movements of near-eye display 120 using slow calibration information from external imaging device 150. For example, headset tracking module 114 may determine positions of a reference point of near-eye display 120 using observed locators from the slow calibration information and a model of near-eye display 120. Headset tracking module 114 may also determine positions of a reference point of near-eye display 120 using position information from the fast calibration information. Additionally, in some embodiments, headset tracking module 114 may use portions of the fast calibration information, the slow calibration information, or any combination thereof, to predict a future location of near-eye display 120. Headset tracking module 114 may provide the estimated or predicted future position of near-eye display 120 to artificial reality engine 116.

Artificial reality engine 116 may execute applications within artificial reality system environment 100 and receive position information of near-eye display 120, acceleration information of near-eye display 120, velocity information of near-eye display 120, predicted future positions of near-eye display 120, or any combination thereof from headset tracking module 114. Artificial reality engine 116 may also receive estimated eye position and orientation information from eye-tracking module 118. Based on the received information, artificial reality engine 116 may determine content to provide to near-eye display 120 for presentation to the user. For example, if the received information indicates that the user has looked to the left, artificial reality engine 116 may generate content for near-eye display 120 that mirrors the user's eye movement in a virtual environment. Additionally, artificial reality engine 116 may perform an action within an application executing on console 110 in response to an action request received from input/output interface 140, and provide feedback to the user indicating that the action has been performed. The feedback may be visual or audible feedback via near-eye display 120 or haptic feedback via input/output interface 140.

Eye-tracking module 118 may receive eye-tracking data from eye-tracking unit 130 and determine the position of the user's eye based on the eye tracking data. The position of the eye may include an eye's orientation, location, or both relative to near-eye display 120 or any element thereof. Because the eye's axes of rotation change as a function of the eye's location in its socket, determining the eye's location in its socket may allow eye-tracking module 118 to more accurately determine the eye's orientation.

FIG. 2 is a perspective view of an example of a near-eye display in the form of an HMD device 200 for implementing some of the examples disclosed herein. HMD device 200 may be a part of, e.g., a VR system, an AR system, an MR system, or any combination thereof. HMD device 200 may include a body 220 and a head strap 230. FIG. 2 shows a bottom side 223, a front side 225, and a left side 227 of body 220 in the perspective view. Head strap 230 may have an adjustable or extendible length. There may be a sufficient space between body 220 and head strap 230 of HMD device 200 for allowing a user to mount HMD device 200 onto the user's head. In various embodiments, HMD device 200 may include additional, fewer, or different components. For example, in some embodiments, HMD device 200 may include eyeglass temples and temple tips as shown in, for example, FIG. 3 below, rather than head strap 230.

HMD device 200 may present to a user media including virtual and/or augmented views of a physical, real-world environment with computer-generated elements. Examples of the media presented by HMD device 200 may include images (e.g., two-dimensional (2D) or three-dimensional (3D) images), videos (e.g., 2D or 3D videos), audio, or any combination thereof. The images and videos may be presented to each eye of the user by one or more display assemblies (not shown in FIG. 2) enclosed in body 220 of HMD device 200. In various embodiments, the one or more display assemblies may include a single electronic display panel or multiple electronic display panels (e.g., one display panel for each eye of the user). Examples of the electronic display panel(s) may include, for example, an LCD, an OLED display, an ILED display, a μLED display, an AMOLED, a TOLED, some other display, or any combination thereof. HMD device 200 may include two eye box regions.

In some implementations, HMD device 200 may include various sensors (not shown), such as depth sensors, motion sensors, position sensors, and eye tracking sensors. Some of these sensors may use a structured light pattern for sensing. In some implementations, HMD device 200 may include an input/output interface for communicating with a console. In some implementations, HMD device 200 may include a virtual reality engine (not shown) that can execute applications within HMD device 200 and receive depth information, position information, acceleration information, velocity information, predicted future positions, or any combination thereof of HMD device 200 from the various sensors. In some implementations, the information received by the virtual reality engine may be used for producing a signal (e.g., display instructions) to the one or more display assemblies. In some implementations, HMD device 200 may include locators (not shown, such as locators 126) located in fixed positions on body 220 relative to one another and relative to a reference point. Each of the locators may emit light that is detectable by an external imaging device.

FIG. 3 is a perspective view of an example of a near-eye display 300 in the form of a pair of glasses for implementing some of the examples disclosed herein. Near-eye display 300 may be a specific implementation of near-eye display 120 of FIG. 1, and may be configured to operate as a virtual reality display, an augmented reality display, and/or a mixed reality display. Near-eye display 300 may include a frame 305 and a display 310. Display 310 may be configured to present content to a user. In some embodiments, display 310 may include display electronics and/or display optics. For example, as described above with respect to near-eye display 120 of FIG. 1, display 310 may include an LCD display panel, an LED display panel, or an optical display panel (e.g., a waveguide display assembly).

Near-eye display 300 may further include various sensors 350a, 350b, 350c, 350d, and 350e on or within frame 305. In some embodiments, sensors 350a-350e may include one or more depth sensors, motion sensors, position sensors, inertial sensors, or ambient light sensors. In some embodiments, sensors 350a-350e may include one or more image sensors configured to generate image data representing different fields of views in different directions. In some embodiments, sensors 350a-350e may be used as input devices to control or influence the displayed content of near-eye display 300, and/or to provide an interactive VR/AR/MR experience to a user of near-eye display 300. In some embodiments, sensors 350a-350e may also be used for stereoscopic imaging.

In some embodiments, near-eye display 300 may further include one or more illuminators 330 to project light into the physical environment. The projected light may be associated with different frequency bands (e.g., visible light, infra-red light, ultra-violet light, etc.), and may serve various purposes. For example, illuminator(s) 330 may project light in a dark environment (or in an environment with low intensity of infra-red light, ultra-violet light, etc.) to assist sensors 350a-350e in capturing images of different objects within the dark environment. In some embodiments, illuminator(s) 330 may be used to project certain light patterns onto the objects within the environment. In some embodiments, illuminator(s) 330 may be used as locators, such as locators 126 described above with respect to FIG. 1.

In some embodiments, near-eye display 300 may also include a high-resolution camera 340. Camera 340 may capture images of the physical environment in the field of view. The captured images may be processed, for example, by a virtual reality engine (e.g., artificial reality engine 116 of FIG. 1) to add virtual objects to the captured images or modify physical objects in the captured images, and the processed images may be displayed to the user by display 310 for AR or MR applications.

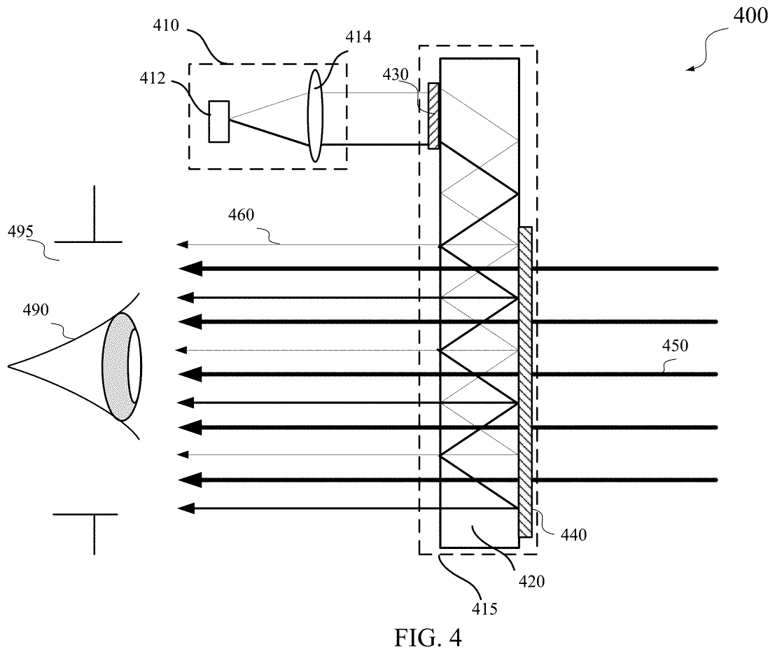

FIG. 4 illustrates an example of an optical see-through augmented reality system 400 including a waveguide display according to certain embodiments. Augmented reality system 400 may include a projector 410 and a combiner 415. Projector 410 may include a light source or image source 412 and projector optics 414. In some embodiments, light source or image source 412 may include one or more micro-LED devices described above. In some embodiments, image source 412 may include a plurality of pixels that displays virtual objects, such as an LCD display panel or an LED display panel. In some embodiments, image source 412 may include a light source that generates coherent or partially coherent light. For example, image source 412 may include a laser diode, a vertical cavity surface emitting laser, an LED, and/or a micro-LED described above. In some embodiments, image source 412 may include a plurality of light sources (e.g., an array of micro-LEDs described above), each emitting a monochromatic image light corresponding to a primary color (e.g., red, green, or blue). In some embodiments, image source 412 may include three two-dimensional arrays of micro-LEDs, where each two-dimensional array of micro-LEDs may include micro-LEDs configured to emit light of a primary color (e.g., red, green, or blue). In some embodiments, image source 412 may include an optical pattern generator, such as a spatial light modulator. Projector optics 414 may include one or more optical components that can condition the light from image source 412, such as expanding, collimating, scanning, or projecting light from image source 412 to combiner 415. The one or more optical components may include, for example, one or more lenses, liquid lenses, mirrors, apertures, and/or gratings. For example, in some embodiments, image source 412 may include one or more one-dimensional arrays or elongated two-dimensional arrays of micro-LEDs, and projector optics 414 may include one or more one-dimensional scanners (e.g., micro-mirrors or prisms) configured to scan the one-dimensional arrays or elongated two-dimensional arrays of micro-LEDs to generate image frames. In some embodiments, projector optics 414 may include a liquid lens (e.g., a liquid crystal lens) with a plurality of electrodes that allows scanning of the light from image source 412.

Combiner 415 may include an input coupler 430 for coupling light from projector 410 into a substrate 420 of combiner 415. Combiner 415 may transmit at least 50% of light in a first wavelength range and reflect at least 25% of light in a second wavelength range. For example, the first wavelength range may be visible light from about 400 nm to about 650 nm, and the second wavelength range may be in the infrared band, for example, from about 800 nm to about 1000 nm. Input coupler 430 may include a volume holographic grating, a diffractive optical element (DOE) (e.g., a surface-relief grating), a slanted surface of substrate 420, or a refractive coupler (e.g., a wedge or a prism). For example, input coupler 430 may include a reflective volume Bragg grating or a transmissive volume Bragg grating. Input coupler 430 may have a coupling efficiency of greater than 30%, 50%, 75%, 90%, or higher for visible light. Light coupled into substrate 420 may propagate within substrate 420 through, for example, total internal reflection (TIR). Substrate 420 may be in the form of a lens of a pair of eyeglasses. Substrate 420 may have a flat or a curved surface, and may include one or more types of dielectric materials, such as glass, quartz, plastic, polymer, poly(methyl methacrylate) (PMMA), crystal, or ceramic. A thickness of the substrate may range from, for example, less than about 1 mm to about 10 mm or more. Substrate 420 may be transparent to visible light.

Substrate 420 may include or may be coupled to a plurality of output couplers 440, each configured to extract at least a portion of the light guided by and propagating within substrate 420 from substrate 420, and direct extracted light 460 to an eyebox 495 where an eye 490 of the user of augmented reality system 400 may be located when augmented reality system 400 is in use. The plurality of output couplers 440 may replicate the exit pupil to increase the size of eyebox 495 such that the displayed image is visible in a larger area. As input coupler 430, output couplers 440 may include grating couplers (e.g., volume holographic gratings or surface-relief gratings), other diffraction optical elements (DOEs), prisms, etc. For example, output couplers 440 may include reflective volume Bragg gratings or transmissive volume Bragg gratings. Output couplers 440 may have different coupling (e.g., diffraction) efficiencies at different locations. Substrate 420 may also allow light 450 from the environment in front of combiner 415 to pass through with little or no loss. Output couplers 440 may also allow light 450 to pass through with little loss. For example, in some implementations, output couplers 440 may have a very low diffraction efficiency for light 450 such that light 450 may be refracted or otherwise pass through output couplers 440 with little loss, and thus may have a higher intensity than extracted light 460. In some implementations, output couplers 440 may have a high diffraction efficiency for light 450 and may diffract light 450 in certain desired directions (i.e., diffraction angles) with little loss. As a result, the user may be able to view combined images of the environment in front of combiner 415 and images of virtual objects projected by projector 410.

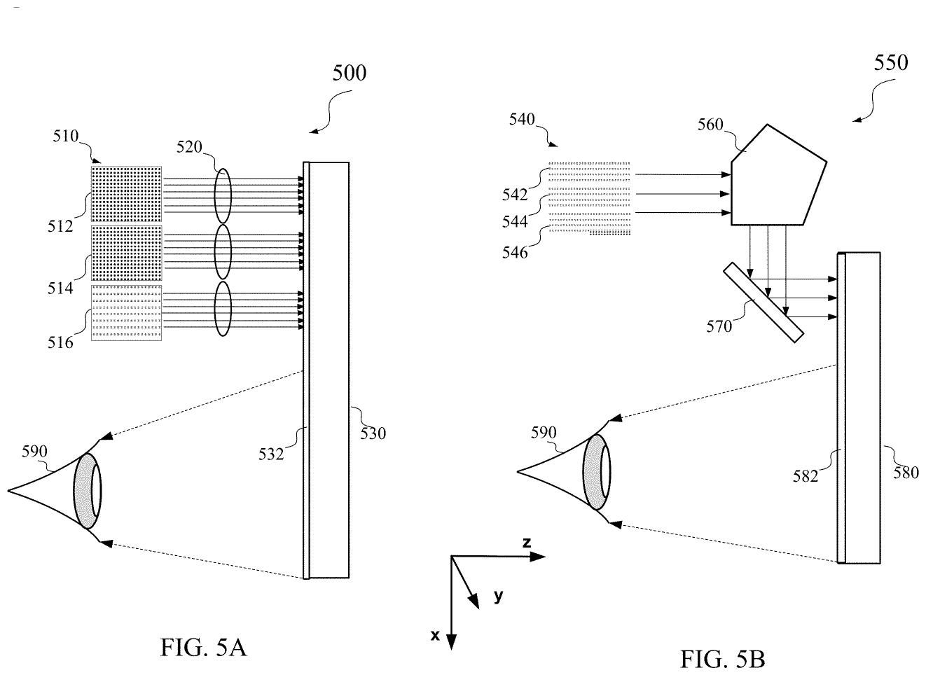

FIG. 5A illustrates an example of a near-eye display (NED) device 500 including a waveguide display 530 according to certain embodiments. NED device 500 may be an example of near-eye display 120, augmented reality system 400, or another type of display device. NED device 500 may include a light source 510, projection optics 520, and waveguide display 530. Light source 510 may include multiple panels of light emitters for different colors, such as a panel of red light emitters 512, a panel of green light emitters 514, and a panel of blue light emitters 516. The red light emitters 512 are organized into an array; the green light emitters 514 are organized into an array; and the blue light emitters 516 are organized into an array. The dimensions and pitches of light emitters in light source 510 may be small. For example, each light emitter may have a diameter less than 2 m (e.g., about 1.2 m) and the pitch may be less than 2 m (e.g., about 1.5 m). As such, the number of light emitters in each red light emitters 512, green light emitters 514, and blue light emitters 516 can be equal to or greater than the number of pixels in a display image, such as 960×720, 1280×720, 1440×1080, 1920×1080, 2160×1080, or 2560×1080 pixels. Thus, a display image may be generated simultaneously by light source 510. A scanning element may not be used in NED device 500.

Before reaching waveguide display 530, the light emitted by light source 510 may be conditioned by projection optics 520, which may include a lens array. Projection optics 520 may collimate or focus the light emitted by light source 510 to waveguide display 530, which may include a coupler 532 for coupling the light emitted by light source 510 into waveguide display 530. The light coupled into waveguide display 530 may propagate within waveguide display 530 through, for example, total internal reflection as described above with respect to FIG. 4. Coupler 532 may also couple portions of the light propagating within waveguide display 530 out of waveguide display 530 and towards user's eye 590.

FIG. 5B illustrates an example of a near-eye display (NED) device 550 including a waveguide display 580 according to certain embodiments. In some embodiments, NED device 550 may use a scanning mirror 570 to project light from a light source 540 to an image field where a user's eye 590 may be located. NED device 550 may be an example of near-eye display 120, augmented reality system 400, or another type of display device. Light source 540 may include one or more rows or one or more columns of light emitters of different colors, such as multiple rows of red light emitters 542, multiple rows of green light emitters 544, and multiple rows of blue light emitters 546. For example, red light emitters 542, green light emitters 544, and blue light emitters 546 may each include N rows, each row including, for example, 2560 light emitters (pixels). The red light emitters 542 are organized into an array; the green light emitters 544 are organized into an array; and the blue light emitters 546 are organized into an array. In some embodiments, light source 540 may include a single line of light emitters for each color. In some embodiments, light source 540 may include multiple columns of light emitters for each of red, green, and blue colors, where each column may include, for example, 1080 light emitters. In some embodiments, the dimensions and/or pitches of the light emitters in light source 540 may be relatively large (e.g., about 3-5 m) and thus light source 540 may not include sufficient light emitters for simultaneously generating a full display image. For example, the number of light emitters for a single color may be fewer than the number of pixels (e.g., 2560×1080 pixels) in a display image. The light emitted by light source 540 may be a set of collimated or diverging beams of light.

Before reaching scanning mirror 570, the light emitted by light source 540 may be conditioned by various optical devices, such as collimating lenses or a freeform optical element 560. Freeform optical element 560 may include, for example, a multi-facet prism or another light folding element that may direct the light emitted by light source 540 towards scanning mirror 570, such as changing the propagation direction of the light emitted by light source 540 by, for example, about 900 or larger. In some embodiments, freeform optical element 560 may be rotatable to scan the light. Scanning mirror 570 and/or freeform optical element 560 may reflect and project the light emitted by light source 540 to waveguide display 580, which may include a coupler 582 for coupling the light emitted by light source 540 into waveguide display 580. The light coupled into waveguide display 580 may propagate within waveguide display 580 through, for example, total internal reflection as described above with respect to FIG. 4. Coupler 582 may also couple portions of the light propagating within waveguide display 580 out of waveguide display 580 and towards user's eye 590.

Scanning mirror 570 may include a microelectromechanical system (MEMS) mirror or any other suitable mirrors. Scanning mirror 570 may rotate to scan in one or two dimensions. As scanning mirror 570 rotates, the light emitted by light source 540 may be directed to a different area of waveguide display 580 such that a full display image may be projected onto waveguide display 580 and directed to user's eye 590 by waveguide display 580 in each scanning cycle. For example, in embodiments where light source 540 includes light emitters for all pixels in one or more rows or columns, scanning mirror 570 may be rotated in the column or row direction (e.g., x or y direction) to scan an image. In embodiments where light source 540 includes light emitters for some but not all pixels in one or more rows or columns, scanning mirror 570 may be rotated in both the row and column directions (e.g., both x and y directions) to project a display image (e.g., using a raster-type scanning pattern).

NED device 550 may operate in predefined display periods. A display period (e.g., display cycle) may refer to a duration of time in which a full image is scanned or projected. For example, a display period may be a reciprocal of the desired frame rate. In NED device 550 that includes scanning mirror 570, the display period may also be referred to as a scanning period or scanning cycle. The light generation by light source 540 may be synchronized with the rotation of scanning mirror 570. For example, each scanning cycle may include multiple scanning steps, where light source 540 may generate a different light pattern in each respective scanning step.

In each scanning cycle, as scanning mirror 570 rotates, a display image may be projected onto waveguide display 580 and user's eye 590. The actual color value and light intensity (e.g., brightness) of a given pixel location of the display image may be an average of the light beams of the three colors (e.g., red, green, and blue) illuminating the pixel location during the scanning period. After completing a scanning period, scanning mirror 570 may revert back to the initial position to project light for the first few rows of the next display image or may rotate in a reverse direction or scan pattern to project light for the next display image, where a new set of driving signals may be fed to light source 540. The same process may be repeated as scanning mirror 570 rotates in each scanning cycle. As such, different images may be projected to user's eye 590 in different scanning cycles.

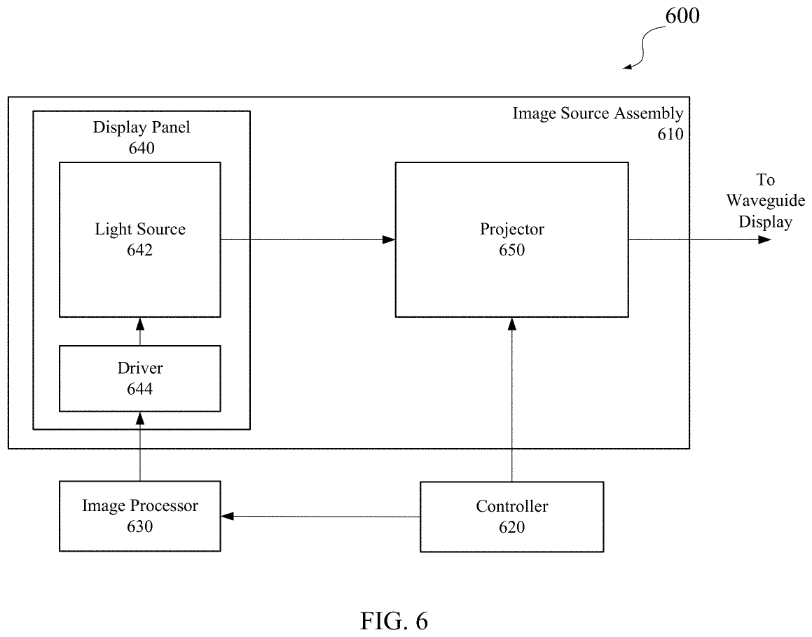

FIG. 6 illustrates an example of an image source assembly 610 in a near-eye display system 600 according to certain embodiments. Image source assembly 610 may include, for example, a display panel 640 that may generate display images to be projected to the user's eyes, and a projector 650 that may project the display images generated by display panel 640 to a waveguide display as described above with respect to FIGS. 4-5B. Display panel 640 may include a light source 642 and a driver circuit 644 for light source 642. Light source 642 may include, for example, light source 510 or 540. Projector 650 may include, for example, freeform optical element 560, scanning mirror 570, and/or projection optics 520 described above. Near-eye display system 600 may also include a controller 620 that synchronously controls light source 642 and projector 650 (e.g., scanning mirror 570). Image source assembly 610 may generate and output an image light to a waveguide display (not shown in FIG. 6), such as waveguide display 530 or 580. As described above, the waveguide display may receive the image light at one or more input-coupling elements, and guide the received image light to one or more output-coupling elements. The input and output coupling elements may include, for example, a diffraction grating, a holographic grating, a prism, or any combination thereof. The input-coupling element may be chosen such that total internal reflection occurs with the waveguide display. The output-coupling element may couple portions of the total internally reflected image light out of the waveguide display.

As described above, light source 642 may include a plurality of light emitters arranged in an array or a matrix. Each light emitter may emit monochromatic light, such as red light, blue light, green light, infra-red light, and the like. While RGB colors are often discussed in this disclosure, embodiments described herein are not limited to using red, green, and blue as primary colors. Other colors can also be used as the primary colors of near-eye display system 600. In some embodiments, a display panel in accordance with an embodiment may use more than three primary colors. Each pixel in light source 642 may include three subpixels that include a red micro-LED, a green micro-LED, and a blue micro-LED. A semiconductor LED generally includes an active light emitting layer within multiple layers of semiconductor materials. The multiple layers of semiconductor materials may include different compound materials or a same base material with different dopants and/or different doping densities. For example, the multiple layers of semiconductor materials may include an n-type material layer, an active region that may include hetero-structures (e.g., one or more quantum wells), and a p-type material layer. The multiple layers of semiconductor materials may be grown on a surface of a substrate having a certain orientation. In some embodiments, to increase light extraction efficiency, a mesa that includes at least some of the layers of semiconductor materials may be formed.

Controller 620 may control the image rendering operations of image source assembly 610, such as the operations of light source 642 and/or projector 650. For example, controller 620 may determine instructions for image source assembly 610 to render one or more display images. The instructions may include display instructions and scanning instructions. In some embodiments, the display instructions may include an image file (e.g., a bitmap file). The display instructions may be received from, for example, a console, such as console 110 described above with respect to FIG. 1. The scanning instructions may be used by image source assembly 610 to generate image light. The scanning instructions may specify, for example, a type of a source of image light (e.g., monochromatic or polychromatic), a scanning rate, an orientation of a scanning apparatus, one or more illumination parameters, or any combination thereof. Controller 620 may include a combination of hardware, software, and/or firmware not shown here so as not to obscure other aspects of the present disclosure.

In some embodiments, controller 620 may be a graphics processing unit (GPU) of a display device. In other embodiments, controller 620 may be other kinds of processors. The operations performed by controller 620 may include taking content for display and dividing the content into discrete sections. Controller 620 may provide to light source 642 scanning instructions that include an address corresponding to an individual source element of light source 642 and/or an electrical bias applied to the individual source element. Controller 620 may instruct light source 642 to sequentially present the discrete sections using light emitters corresponding to one or more rows of pixels in an image ultimately displayed to the user. Controller 620 may also instruct projector 650 to perform different adjustments of the light. For example, controller 620 may control projector 650 to scan the discrete sections to different areas of a coupling element of the waveguide display (e.g., waveguide display 580) as described above with respect to FIG. 5B. As such, at the exit pupil of the waveguide display, each discrete portion is presented in a different respective location. While each discrete section is presented at a different respective time, the presentation and scanning of the discrete sections occur fast enough such that a user's eye may integrate the different sections into a single image or series of images.

Image processor 630 may be a general-purpose processor and/or one or more application-specific circuits that are dedicated to performing the features described herein. In one embodiment, a general-purpose processor may be coupled to a memory to execute software instructions that cause the processor to perform certain processes described herein. In another embodiment, image processor 630 may be one or more circuits that are dedicated to performing certain features. While image processor 630 in FIG. 6 is shown as a stand-alone unit that is separate from controller 620 and driver circuit 644, image processor 630 may be a sub-unit of controller 620 or driver circuit 644 in other embodiments. In other words, in those embodiments, controller 620 or driver circuit 644 may perform various image processing functions of image processor 630. Image processor 630 may also be referred to as an image processing circuit.

In the example shown in FIG. 6, light source 642 may be driven by driver circuit 644, based on data or instructions (e.g., display and scanning instructions) sent from controller 620 or image processor 630. In one embodiment, driver circuit 644 may include a circuit panel that connects to and mechanically holds various light emitters of light source 642. Light source 642 may emit light in accordance with one or more illumination parameters that are set by the controller 620 and potentially adjusted by image processor 630 and driver circuit 644. An illumination parameter may be used by light source 642 to generate light. An illumination parameter may include, for example, source wavelength, pulse rate, pulse amplitude, beam type (continuous or pulsed), other parameter(s) that may affect the emitted light, or any combination thereof. In some embodiments, the source light generated by light source 642 may include multiple beams of red light, green light, and blue light, or any combination thereof.

Projector 650 may perform a set of optical functions, such as focusing, combining, conditioning, or scanning the image light generated by light source 642. In some embodiments, projector 650 may include a combining assembly, a light conditioning assembly, or a scanning mirror assembly. Projector 650 may include one or more optical components that optically adjust and potentially re-direct the light from light source 642. One example of the adjustment of light may include conditioning the light, such as expanding, collimating, correcting for one or more optical errors (e.g., field curvature, chromatic aberration, etc.), some other adjustments of the light, or any combination thereof. The optical components of projector 650 may include, for example, lenses, mirrors, apertures, gratings, or any combination thereof.

Projector 650 may redirect image light via its one or more reflective and/or refractive portions so that the image light is projected at certain orientations toward the waveguide display. The location where the image light is redirected toward the waveguide display may depend on specific orientations of the one or more reflective and/or refractive portions. In some embodiments, projector 650 includes a single scanning mirror that scans in at least two dimensions. In other embodiments, projector 650 may include a plurality of scanning mirrors that each scan in directions orthogonal to each other. Projector 650 may perform a raster scan (horizontally or vertically), a bi-resonant scan, or any combination thereof. In some embodiments, projector 650 may perform a controlled vibration along the horizontal and/or vertical directions with a specific frequency of oscillation to scan along two dimensions and generate a two-dimensional projected image of the media presented to user's eyes. In other embodiments, projector 650 may include a lens or prism that may serve similar or the same function as one or more scanning mirrors. In some embodiments, image source assembly 610 may not include a projector, where the light emitted by light source 642 may be directly incident on the waveguide display.

In semiconductor LEDs, photons are usually generated at a certain internal quantum efficiency through the recombination of electrons and holes within an active region (e.g., one or more semiconductor layers), where the internal quantum efficiency is the proportion of the radiative electron-hole recombination in the active region that emits photons. The generated light may then be extracted from the LEDs in a particular direction or within a particular solid angle. The ratio between the number of emitted photons extracted from an LED and the number of electrons passing through the LED is referred to as the external quantum efficiency, which describes how efficiently the LED converts injected electrons to photons that are extracted from the device.

The external quantum efficiency may be proportional to the injection efficiency, the internal quantum efficiency, and the extraction efficiency. The injection efficiency refers to the proportion of electrons passing through the device that are injected into the active region. The extraction efficiency is the proportion of photons generated in the active region that escape from the device. For LEDs, and in particular, micro-LEDs with reduced physical dimensions, improving the internal and external quantum efficiency and/or controlling the emission spectrum may be challenging. In some embodiments, to increase the light extraction efficiency, a mesa that includes at least some of the layers of semiconductor materials may be formed.

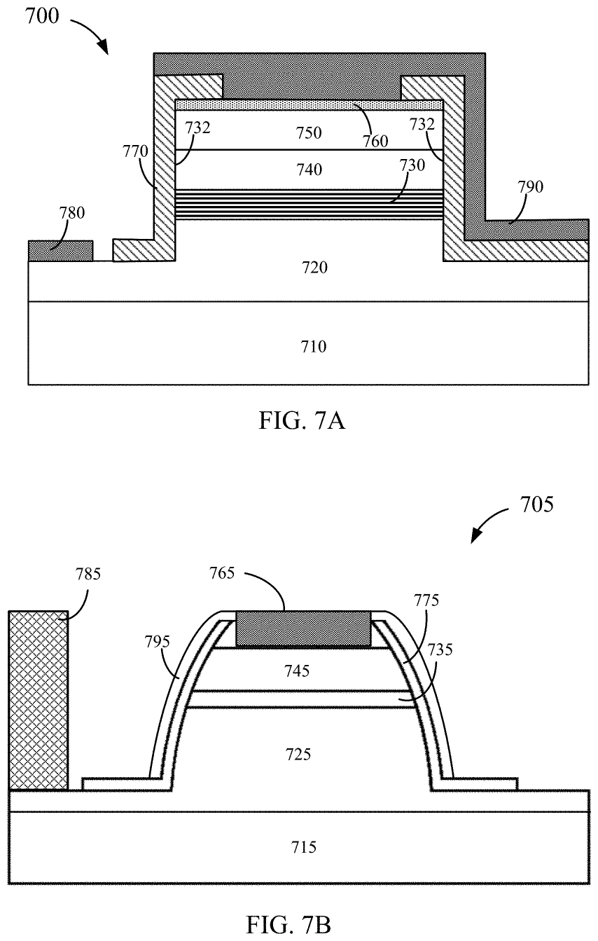

FIG. 7A illustrates an example of an LED 700 having a vertical mesa structure. LED 700 may be a light emitter in light source 510, 540, or 642. LED 700 may be a micro-LED made of inorganic materials, such as multiple layers of semiconductor materials. The layered semiconductor light emitting device may include multiple layers of III-V semiconductor materials. A III-V semiconductor material may include one or more Group III elements, such as aluminum (Al), gallium (Ga), or indium (In), in combination with a Group V element, such as nitrogen (N), phosphorus (P), arsenic (As), or antimony (Sb). When the Group V element of the III-V semiconductor material includes nitrogen, the III-V semiconductor material is referred to as a III-nitride material. The layered semiconductor light emitting device may be manufactured by growing multiple epitaxial layers on a substrate using techniques such as vapor-phase epitaxy (VPE), liquid-phase epitaxy (LPE), molecular beam epitaxy (MBE), or metalorganic chemical vapor deposition (MOCVD). For example, the layers of the semiconductor materials may be grown layer-by-layer on a substrate with a certain crystal lattice orientation (e.g., polar, nonpolar, or semi-polar orientation), such as a GaN, GaAs, or GaP substrate, or a substrate including, but not limited to, sapphire, silicon carbide, silicon, zinc oxide, boron nitride, lithium aluminate, lithium niobate, germanium, aluminum nitride, lithium gallate, partially substituted spinels, or quaternary tetragonal oxides sharing the beta-LiAlO₂ structure, where the substrate may be cut in a specific direction to expose a specific plane as the growth surface.

In the example shown in FIG. 7A, LED 700 may include a substrate 710, which may include, for example, a sapphire substrate or a GaN substrate. A semiconductor layer 720 may be grown on substrate 710. Semiconductor layer 720 may include a III-V material, such as GaN, and may be p-doped (e.g., with Mg, Ca, Zn, or Be) or n-doped (e.g., with Si or Ge). One or more active layers 730 may be grown on semiconductor layer 720 to form an active region. Active layer 730 may include III-V materials, such as one or more InGaN layers, one or more AlInGaP layers, and/or one or more GaN layers, which may form one or more heterostructures, such as one or more quantum wells or MQWs. A semiconductor layer 740 may be grown on active layer 730. Semiconductor layer 740 may include a III-V material, such as GaN, and may be p-doped (e.g., with Mg, Ca, Zn, or Be) or n-doped (e.g., with Si or Ge). One of semiconductor layer 720 and semiconductor layer 740 may be a p-type layer and the other one may be an n-type layer. Semiconductor layer 720 and semiconductor layer 740 sandwich active layer 730 to form the light emitting region. For example, LED 700 may include a layer of InGaN situated between a layer of p-type GaN doped with magnesium and a layer of n-type GaN doped with silicon or oxygen. In some embodiments, LED 700 may include a layer of AlInGaP situated between a layer of p-type AlInGaP doped with zinc or magnesium and a layer of n-type AlInGaP doped with selenium, silicon, or tellurium.

In some embodiments, an electron-blocking layer (EBL) (not shown in FIG. 7A) may be grown to form a layer between active layer 730 and at least one of semiconductor layer 720 or semiconductor layer 740. The EBL may reduce the electron leakage current and improve the efficiency of the LED. In some embodiments, a heavily-doped semiconductor layer 750, such as a P⁺ or P⁺⁺ semiconductor layer, may be formed on semiconductor layer 740 and act as a contact layer for forming an ohmic contact and reducing the contact impedance of the device. In some embodiments, a conductive layer 760 may be formed on heavily-doped semiconductor layer 750. Conductive layer 760 may include, for example, an indium tin oxide (ITO) or Al/Ni/Au film. In one example, conductive layer 760 may include a transparent ITO layer.

To make contact with semiconductor layer 720 (e.g., an n-GaN layer) and to more efficiently extract light emitted by active layer 730 from LED 700, the semiconductor material layers (including heavily-doped semiconductor layer 750, semiconductor layer 740, active layer 730, and semiconductor layer 720) may be etched to expose semiconductor layer 720 and to form a mesa structure that includes layers 720-760. The mesa structure may confine the carriers within the device. Etching the mesa structure may lead to the formation of mesa sidewalls 732 that may be orthogonal to the growth planes. A passivation layer 770 may be formed on sidewalls 732 of the mesa structure. Passivation layer 770 may include an oxide layer, such as a SiO₂ layer, and may act as a reflector to reflect emitted light out of LED 700. A contact layer 780, which may include a metal layer, such as Al, Au, Ni, Ti, or any combination thereof, may be formed on semiconductor layer 720 and may act as an electrode of LED 700. In addition, another contact layer 790, such as an Al/Ni/Au metal layer, may be formed on conductive layer 760 and may act as another electrode of LED 700.

When a voltage signal is applied to contact layers 780 and 790, electrons and holes may recombine in active layer 730, where the recombination of electrons and holes may cause photon emission. The wavelength and energy of the emitted photons may depend on the energy bandgap between the valence band and the conduction band in active layer 730. For example, InGaN active layers may emit green or blue light, AlGaN active layers may emit blue to ultraviolet light, while AlInGaP active layers may emit red, orange, yellow, or green light. The emitted photons may be reflected by passivation layer 770 and may exit LED 700 from the top (e.g., conductive layer 760 and contact layer 790) or bottom (e.g., substrate 710).

In some embodiments, LED 700 may include one or more other components, such as a lens, on the light emission surface, such as substrate 710, to focus or collimate the emitted light or couple the emitted light into a waveguide. In some embodiments, an LED may include a mesa of another shape, such as planar, conical, semi-parabolic, or parabolic, and a base area of the mesa may be circular, rectangular, hexagonal, or triangular. For example, the LED may include a mesa of a curved shape (e.g., paraboloid shape) and/or a non-curved shape (e.g., conic shape). The mesa may be truncated or non-truncated.

FIG. 7B is a cross-sectional view of an example of an LED 705 having a parabolic mesa structure. Similar to LED 700, LED 705 may include multiple layers of semiconductor materials, such as multiple layers of III-V semiconductor materials. The semiconductor material layers may be epitaxially grown on a substrate 715, such as a GaN substrate or a sapphire substrate. For example, a semiconductor layer 725 may be grown on substrate 715. Semiconductor layer 725 may include a III-V material, such as GaN, and may be p-doped (e.g., with Mg, Ca, Zn, or Be) or n-doped (e.g., with Si or Ge). One or more active layer 735 may be grown on semiconductor layer 725. Active layer 735 may include III-V materials, such as one or more InGaN layers, one or more AlInGaP layers, and/or one or more GaN layers, which may form one or more heterostructures, such as one or more quantum wells. A semiconductor layer 745 may be grown on active layer 735. Semiconductor layer 745 may include a III-V material, such as GaN, and may be p-doped (e.g., with Mg, Ca, Zn, or Be) or n-doped (e.g., with Si or Ge). One of semiconductor layer 725 and semiconductor layer 745 may be a p-type layer and the other one may be an n-type layer.

To make contact with semiconductor layer 725 (e.g., an n-type GaN layer) and to more efficiently extract light emitted by active layer 735 from LED 705, the semiconductor layers may be etched to expose semiconductor layer 725 and to form a mesa structure that includes layers 725-745. The mesa structure may confine carriers within the injection area of the device. Etching the mesa structure may lead to the formation of mesa side walls (also referred to herein as facets) that may be non-parallel with, or in some cases, orthogonal, to the growth planes associated with crystalline growth of layers 725-745.

As shown in FIG. 7B, LED 705 may have a mesa structure that includes a flat top. A dielectric layer 775 (e.g., SiO₂ or SiNx) may be formed on the facets of the mesa structure. In some embodiments, dielectric layer 775 may include multiple layers of dielectric materials. In some embodiments, a metal layer 795 may be formed on dielectric layer 775. Metal layer 795 may include one or more metal or metal alloy materials, such as aluminum (Al), silver (Ag), gold (Au), platinum (Pt), titanium (Ti), copper (Cu), or any combination thereof. Dielectric layer 775 and metal layer 795 may form a mesa reflector that can reflect light emitted by active layer 735 toward substrate 715. In some embodiments, the mesa reflector may be parabolic-shaped to act as a parabolic reflector that may at least partially collimate the emitted light.

Electrical contact 765 and electrical contact 785 may be formed on semiconductor layer 745 and semiconductor layer 725, respectively, to act as electrodes. Electrical contact 765 and electrical contact 785 may each include a conductive material, such as Al, Au, Pt, Ag, Ni, Ti, Cu, or any combination thereof (e.g., Ag/Pt/Au or Al/Ni/Au), and may act as the electrodes of LED 705. In the example shown in FIG. 7B, electrical contact 785 may be an n-contact, and electrical contact 765 may be a p-contact. Electrical contact 765 and semiconductor layer 745 (e.g., a p-type semiconductor layer) may form a back reflector for reflecting light emitted by active layer 735 back toward substrate 715. In some embodiments, electrical contact 765 and metal layer 795 include same material(s) and can be formed using the same processes. In some embodiments, an additional conductive layer (not shown) may be included as an intermediate conductive layer between the electrical contacts 765 and 785 and the semiconductor layers.

When a voltage signal is applied across contacts 765 and 785, electrons and holes may recombine in active layer 735. The recombination of electrons and holes may cause photon emission, thus producing light. The wavelength and energy of the emitted photons may depend on the energy bandgap between the valence band and the conduction band in active layer 735. For example, InGaN active layers may emit green or blue light, while AlInGaP active layers may emit red, orange, yellow, or green light. The emitted photons may propagate in many different directions, and may be reflected by the mesa reflector and/or the back reflector and may exit LED 705, for example, from the bottom side (e.g., substrate 715) shown in FIG. 7B. One or more other secondary optical components, such as a lens or a grating, may be formed on the light emission surface, such as substrate 715, to focus or collimate the emitted light and/or couple the emitted light into a waveguide.

One or two-dimensional arrays of the LEDs described above may be manufactured on a wafer to form light sources (e.g., light source 642). Driver circuits (e.g., driver circuit 644) may be fabricated, for example, on a silicon wafer using CMOS processes. The LEDs and the driver circuits on wafers may be diced and then bonded together, or may be bonded on the wafer level and then diced. Various bonding techniques can be used for bonding the LEDs and the driver circuits, such as adhesive bonding, metal-to-metal bonding, metal oxide bonding, wafer-to-wafer bonding, die-to-wafer bonding, hybrid bonding, and the like.

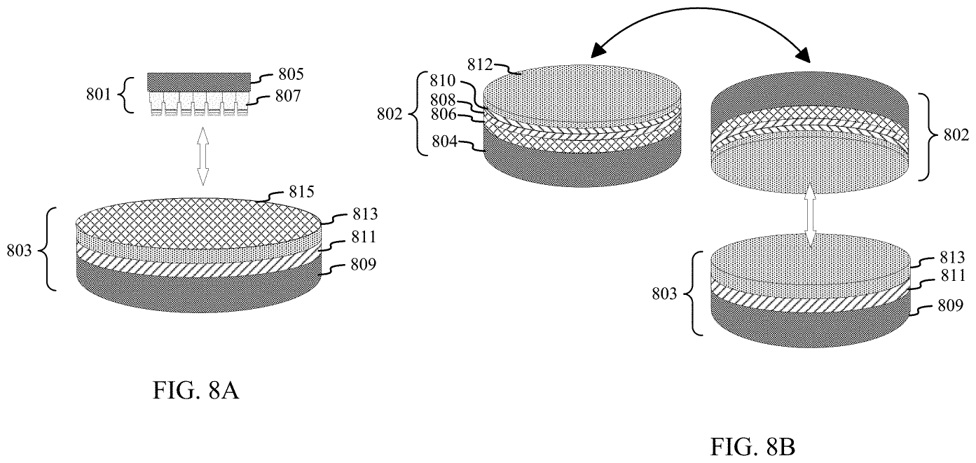

FIG. 8A illustrates an example of a method of die-to-wafer bonding for arrays of LEDs according to certain embodiments. In the example shown in FIG. 8A, an LED array 801 may include a plurality of LEDs 807 on a carrier substrate 805. Carrier substrate 805 may include various materials, such as GaAs, InP, GaN, AlN, sapphire, SiC, Si, or the like. LEDs 807 may be fabricated by, for example, growing various epitaxial layers, forming mesa structures, and forming electrical contacts or electrodes, before performing the bonding. The epitaxial layers may include various materials, such as GaN, InGaN, (AlGaIn)P, (AlGaIn)AsP, (AlGaIn)AsN, (AlGaIn)Pas, (Eu:InGa)N, (AlGaIn)N, or the like, and may include an n-type layer, a p-type layer, and an active layer that includes one or more heterostructures, such as one or more quantum wells or MQWs. The electrical contacts may include various conductive materials, such as a metal or a metal alloy.

A wafer 803 may include a base layer 809 having passive or active integrated circuits (e.g., driver circuits 811) fabricated thereon. Base layer 809 may include, for example, a silicon wafer. Driver circuits 811 may be used to control the operations of LEDs 807. For example, the driver circuit for each LED 807 may include a 2T1C pixel structure that has two transistors and one capacitor. Wafer 803 may also include a bonding layer 813. Bonding layer 813 may include various materials, such as a metal, an oxide, a dielectric, CuSn, AuTi, and the like. In some embodiments, a patterned layer 815 may be formed on a surface of bonding layer 813, where patterned layer 815 may include a metallic grid made of a conductive material, such as Cu, Ag, Au, Al, or the like.

LED array 801 may be bonded to wafer 803 via bonding layer 813 or patterned layer 815. For example, patterned layer 815 may include metal pads or bumps made of various materials, such as CuSn, AuSn, or nanoporous Au, that may be used to align LEDs 807 of LED array 801 with corresponding driver circuits 811 on wafer 803. In one example, LED array 801 may be brought toward wafer 803 until LEDs 807 come into contact with respective metal pads or bumps corresponding to driver circuits 811. Some or all of LEDs 807 may be aligned with driver circuits 811, and may then be bonded to wafer 803 via patterned layer 815 by various bonding techniques, such as metal-to-metal bonding. After LEDs 807 have been bonded to wafer 803, carrier substrate 805 may be removed from LEDs 807.

FIG. 8B illustrates an example of a method of wafer-to-wafer bonding for arrays of LEDs according to certain embodiments. As shown in FIG. 8B, a first wafer 802 may include a substrate 804, a first semiconductor layer 806, active layers 808, and a second semiconductor layer 810. Substrate 804 may include various materials, such as GaAs, InP, GaN, AlN, sapphire, SiC, Si, or the like. First semiconductor layer 806, active layers 808, and second semiconductor layer 810 may include various semiconductor materials, such as GaN, InGaN, (AlGaIn)P, (AlGaIn)AsP, (AlGaIn)AsN, (AlGaIn)Pas, (Eu:InGa)N, (AlGaIn)N, or the like. In some embodiments, first semiconductor layer 806 may be an n-type layer, and second semiconductor layer 810 may be a p-type layer. For example, first semiconductor layer 806 may be an n-doped GaN layer (e.g., doped with Si or Ge), and second semiconductor layer 810 may be a p-doped GaN layer (e.g., doped with Mg, Ca, Zn, or Be). Active layers 808 may include, for example, one or more GaN layers, one or more InGaN layers, one or more AlInGaP layers, and the like, which may form one or more heterostructures, such as one or more quantum wells or MQWs.

In some embodiments, first wafer 802 may also include a bonding layer. Bonding layer 812 may include various materials, such as a metal, an oxide, a dielectric, CuSn, AuTi, or the like. In one example, bonding layer 812 may include p-contacts and/or n-contacts (not shown). In some embodiments, other layers may also be included on first wafer 802, such as a buffer layer between substrate 804 and first semiconductor layer 806. The buffer layer may include various materials, such as polycrystalline GaN or AlN. In some embodiments, a contact layer may be between second semiconductor layer 810 and bonding layer 812. The contact layer may include any suitable material for providing an electrical contact to second semiconductor layer 810 and/or first semiconductor layer 806.

First wafer 802 may be bonded to wafer 803 that includes driver circuits 811 and bonding layer 813 as described above, via bonding layer 813 and/or bonding layer 812. Bonding layer 812 and bonding layer 813 may be made of the same material or different materials. Bonding layer 813 and bonding layer 812 may be substantially flat. First wafer 802 may be bonded to wafer 803 by various methods, such as metal-to-metal bonding, eutectic bonding, metal oxide bonding, anodic bonding, thermo-compression bonding, ultraviolet (UV) bonding, and/or fusion bonding.

As shown in FIG. 8B, first wafer 802 may be bonded to wafer 803 with the p-side (e.g., second semiconductor layer 810) of first wafer 802 facing down (i.e., toward wafer 803). After bonding, substrate 804 may be removed from first wafer 802, and first wafer 802 may then be processed from the n-side. The processing may include, for example, the formation of certain mesa shapes for individual LEDs, as well as the formation of optical components corresponding to the individual LEDs.

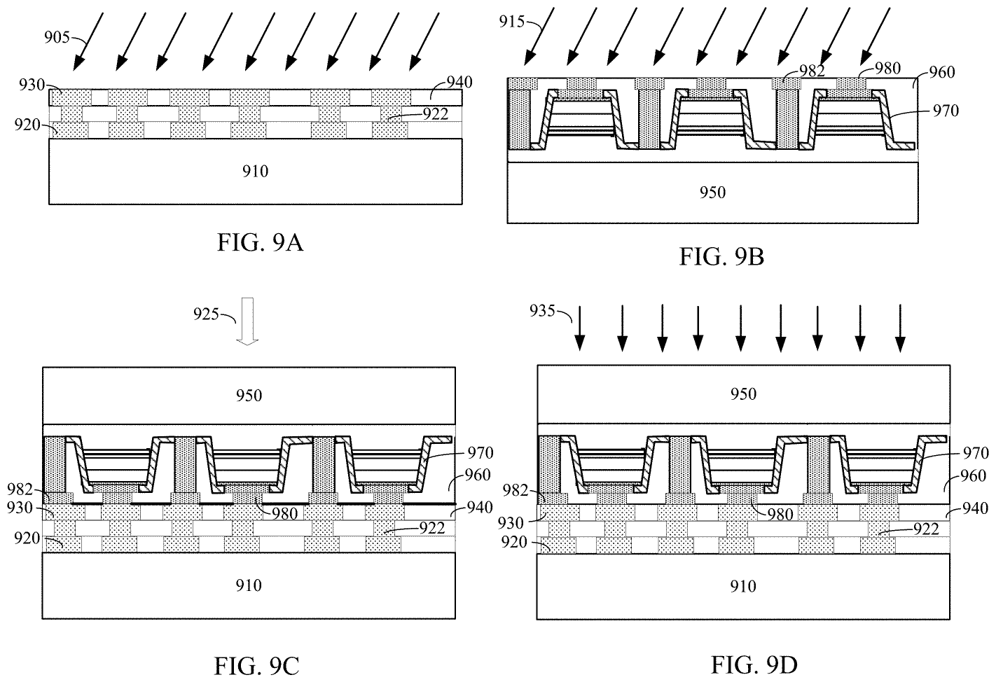

FIGS. 9A-9D illustrate an example of a method of hybrid bonding for arrays of LEDs according to certain embodiments. The hybrid bonding may generally include wafer cleaning and activation, high-precision alignment of contacts of one wafer with contacts of another wafer, dielectric bonding of dielectric materials at the surfaces of the wafers at room temperature, and metal bonding of the contacts by annealing at elevated temperatures. FIG. 9A shows a substrate 910 with passive or active circuits 920 manufactured thereon. As described above with respect to FIGS. 8A-8B, substrate 910 may include, for example, a silicon wafer. Circuits 920 may include driver circuits for the arrays of LEDs. A bonding layer may include dielectric regions 940 and contact pads 930 connected to circuits 920 through electrical interconnects 922. Contact pads 930 may include, for example, Cu, Ag, Au, Al, W, Mo, Ni, Ti, Pt, Pd, or the like. Dielectric materials in dielectric regions 940 may include SiCN, SiO₂, SiN, Al₂O₃, HfO₂, ZrO₂, Ta₂O₅, or the like. The bonding layer may be planarized and polished using, for example, chemical mechanical polishing, where the planarization or polishing may cause dishing (a bowl like profile) in the contact pads. The surfaces of the bonding layers may be cleaned and activated by, for example, an ion (e.g., plasma) or fast atom (e.g., Ar) beam 905. The activated surface may be atomically clean and may be reactive for formation of direct bonds between wafers when they are brought into contact, for example, at room temperature.

FIG. 9B illustrates a wafer 950 including an array of micro-LEDs 970 fabricated thereon as described above with respect to, for example, FIGS. 7A-8B. Wafer 950 may be a carrier wafer and may include, for example, GaAs, InP, GaN, AlN, sapphire, SiC, Si, or the like. Micro-LEDs 970 may include an n-type layer, an active region, and a p-type layer epitaxially grown on wafer 950. The epitaxial layers may include various III-V semiconductor materials described above, and may be processed from the p-type layer side to etch mesa structures in the epitaxial layers, such as substantially vertical structures, parabolic structures, conic structures, or the like. Passivation layers and/or reflection layers may be formed on the sidewalls of the mesa structures. P-contacts 980 and n-contacts 982 may be formed in a dielectric material layer 960 deposited on the mesa structures and may make electrical contacts with the p-type layer and the n-type layers, respectively. Dielectric materials in dielectric material layer 960 may include, for example, SiCN, SiO₂, SiN, Al₂O₃, HfO₂, ZrO₂, Ta₂O₅, or the like. P-contacts 980 and n-contacts 982 may include, for example, Cu, Ag, Au, Al, W, Mo, Ni, Ti, Pt, Pd, or the like. The top surfaces of p-contacts 980, n-contacts 982, and dielectric material layer 960 may form a bonding layer. The bonding layer may be planarized and polished using, for example, chemical mechanical polishing, where the polishing may cause dishing in p-contacts 980 and n-contacts 982. The bonding layer may then be cleaned and activated by, for example, an ion (e.g., plasma) or fast atom (e.g., Ar) beam 915. The activated surface may be atomically clean and reactive for formation of direct bonds between wafers when they are brought into contact, for example, at room temperature.

FIG. 9C illustrates a room temperature bonding process for bonding the dielectric materials in the bonding layers. For example, after the bonding layer that includes dielectric regions 940 and contact pads 930 and the bonding layer that includes p-contacts 980, n-contacts 982, and dielectric material layer 960 are surface activated, wafer 950 and micro-LEDs 970 may be turned upside down and brought into contact with substrate 910 and the circuits formed thereon. In some embodiments, compression pressure 925 may be applied to substrate 910 and wafer 950 such that the bonding layers are pressed against each other. Due to the surface activation and the dishing in the contacts, dielectric regions 940 and dielectric material layer 960 may be in direct contact because of the surface attractive force, and may react and form chemical bonds between them because the surface atoms may have dangling bonds and may be in unstable energy states after the activation. Thus, the dielectric materials in dielectric regions 940 and dielectric material layer 960 may be bonded together with or without heat treatment or pressure.

FIG. 9D illustrates an annealing process for bonding the contacts in the bonding layers after bonding the dielectric materials in the bonding layers. For example, contact pads 930 and p-contacts 980 or n-contacts 982 may be bonded together by annealing at, for example, about 200-400° C. or higher. During the annealing process, heat 935 may cause the contacts to expand more than the dielectric materials (due to different coefficients of thermal expansion), and thus may close the dishing gaps between the contacts such that contact pads 930 and p-contacts 980 or n-contacts 982 may be in contact and may form direct metallic bonds at the activated surfaces.

In some embodiments where the two bonded wafers include materials having different coefficients of thermal expansion (CTEs), the dielectric materials bonded at room temperature may help to reduce or prevent misalignment of the contact pads caused by the different thermal expansions. In some embodiments, to further reduce or avoid the misalignment of the contact pads at a high temperature during annealing, trenches may be formed between micro-LEDs, between groups of micro-LEDs, through part or all of the substrate, or the like, before bonding.

After the micro-LEDs are bonded to the driver circuits, the substrate on which the micro-LEDs are fabricated may be thinned or removed, and various secondary optical components may be fabricated on the light emitting surfaces of the micro-LEDs to, for example, extract, collimate, and redirect the light emitted from the active regions of the micro-LEDs. In one example, micro-lenses may be formed on the micro-LEDs, where each micro-lens may correspond to a respective micro-LED and may help to improve the light extraction efficiency and collimate the light emitted by the micro-LED. In some embodiments, the secondary optical components may be fabricated in the substrate or the n-type layer of the micro-LEDs. In some embodiments, the secondary optical components may be fabricated in a dielectric layer deposited on the n-type side of the micro-LEDs. Examples of the secondary optical components may include a lens, a grating, an antireflection (AR) coating, a prism, a photonic crystal, or the like.

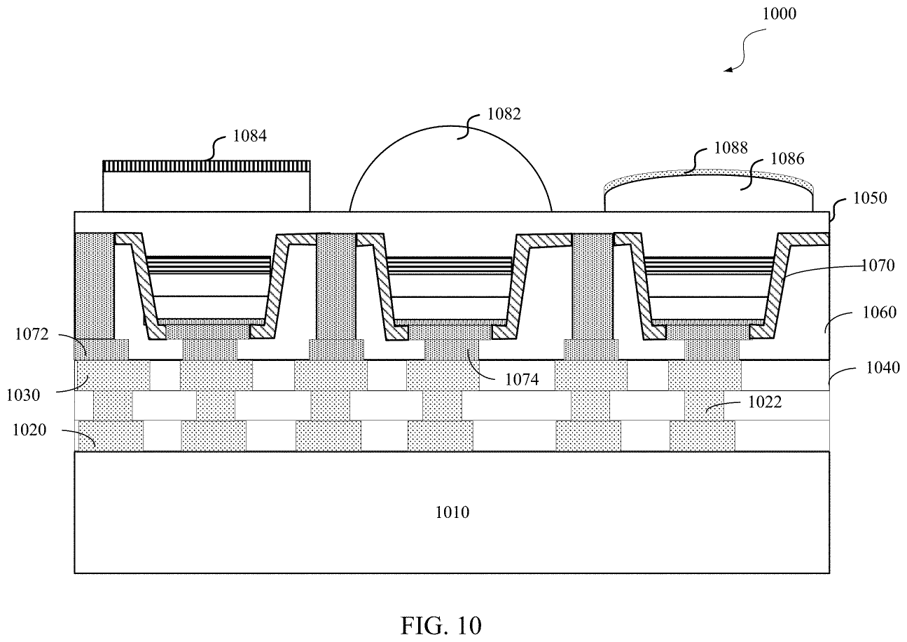

FIG. 10 illustrates an example of an LED array 1000 with secondary optical components fabricated thereon according to certain embodiments. LED array 1000 may be made by bonding an LED chip or wafer with a silicon wafer including electrical circuits fabricated thereon, using any suitable bonding techniques described above with respect to, for example, FIGS. 8A-9D. In the example shown in FIG. 10, LED array 1000 may be bonded using a wafer-to-wafer hybrid bonding technique as described above with respect to FIG. 9A-9D. LED array 1000 may include a substrate 1010, which may be, for example, a silicon wafer. Integrated circuits 1020, such as LED driver circuits, may be fabricated on substrate 1010. Integrated circuits 1020 may be connected to p-contacts 1074 and n-contacts 1072 of micro-LEDs 1070 through interconnects 1022 and contact pads 1030, where contact pads 1030 may form metallic bonds with p-contacts 1074 and n-contacts 1072. Dielectric layer 1040 on substrate 1010 may be bonded to dielectric layer 1060 through fusion bonding.

The substrate (not shown) of the LED chip or wafer may be thinned or may be removed to expose the n-type layer 1050 of micro-LEDs 1070. Various secondary optical components, such as a spherical micro-lens 1082, a grating 1084, a micro-lens 1086, an antireflection layer 1088, and the like, may be formed in or on top of n-type layer 1050. For example, spherical micro-lens arrays may be etched in the semiconductor materials of micro-LEDs 1070 using a gray-scale mask and a photoresist with a linear response to exposure light, or using an etch mask formed by thermal reflowing of a patterned photoresist layer. The secondary optical components may also be etched in a dielectric layer deposited on n-type layer 1050 using similar photolithographic techniques or other techniques. For example, micro-lens arrays may be formed in a polymer layer through thermal reflowing of the polymer layer that is patterned using a binary mask. The micro-lens arrays in the polymer layer may be used as the secondary optical components or may be used as the etch mask for transferring the profiles of the micro-lens arrays into a dielectric layer or a semiconductor layer. The dielectric layer may include, for example, SiCN, SiO₂, SiN, Al₂O₃, HfO₂, ZrO₂, Ta₂O₅, or the like. In some embodiments, a micro-LED 1070 may have multiple corresponding secondary optical components, such as a micro-lens and an anti-reflection coating, a micro-lens etched in the semiconductor material and a micro-lens etched in a dielectric material layer, a micro-lens and a grating, a spherical lens and an aspherical lens, and the like. Three different secondary optical components are illustrated in FIG. 10 to show some examples of secondary optical components that can be formed on micro-LEDs 1070, which does not necessary imply that different secondary optical components are used simultaneously for every LED array.

LEDs with High Reflectivity Electrodes

As discussed above, some LEDs have a metal electrode formed on sidewalls of the first layer of semiconductor material in an LED stack and another metal electrode formed on a metal contact layer disposed on the other layer of semiconductor material in the LED stack. In these constructs, the metal electrodes may receive and absorb light from the active region of the LED stack, which can affect light extraction from the LEDs.

According to certain embodiments, an LED device includes LEDs having at least one layer of a material between a metal electrode and the LED stack with an index of refraction lower than the first semiconductor material and/or the second semiconductor material in the LED stack. The layer(s) of low index material may cause TIR of at least some light emitted by the active region of the LED stack and reduce light propagated to, and absorbed by, the metal electrode.

In certain implementations, an LED device includes multiple LEDs with individual mesa structures where each mesa structure has an LED stack including a layer of a first semiconductor material (e.g., an n-type semiconductor layer), an active layer grown on the layer of the first semiconductor material, and layer of a second semiconductor material (e.g., a p-type semiconductor layer) grown on the active layer. The LEDs include a layer of low refractive index material formed on sidewalls of the mesa structures between the layer of the first semiconductor material and a metal layer providing ohmic contact to the layer of the first semiconductor material to act as an electrode. The low refractive index conductive material has a lower index of refraction than the first semiconductor material and may cause constructive interference of light emitted by the active region of the LED stack to promote total internal reflection (TIR) and improve light extraction from the LED device such that the metal layer acts as a high reflectivity mesa sidewall electrode (e.g., n-electrode). In some cases, the LEDs also include a layer of low index non-conductive material such as a dielectric layer and/or a distributed Bragg reflector (DBR) between the layer of low refractive index conductive material and the metal layer. The low index non-conductive material may have a lower refractive index than the low refractive index conductive material. The DBR includes one or more material layers that may have a thickness or thicknesses selected for high reflectivity of a wavelength band emitted from the active region of the LED stack to further promote TIR and improve light extraction from the LED device. In addition or alternatively, the LEDs may include a layer of low refractive index material or a DBR between the layer of the second semiconductor material in the LED stack and another metal layer in ohmic contact to the layer of second semiconductor material. The low refractive index material has a lower refractive index than the second semiconductor material. The layer of low refractive index material or DBR may promote TIR and improve light extraction from the LED device such that the metal layer acts as a high reflectivity wide bonding pad electrode (e.g., p-electrode). In one of these implementations, the micro-LED also includes one or more layers of transparent conductive material, such as ITO, that are formed on the layer of the second semiconductor material. At least one of the transparent conductive layers may have a footprint larger than the footprint of the mesa structure to provide an end portion in a dead zone between adjacent mesa structures where the quantum well layers have been etched. The metal layer in ohmic contact with the layer of the second semiconductor material may contact, via a metal plug for example, the end portion of this conductive material in the dead zone to avoid light absorption by the metal electrode. The location of the metal plug in the dead zone may be particularly advantageous in micro-LED implementations where the area of a metal plug may take up a large portion (e.g., 25%) of the active area in a small pixel micro-LED to improve reflectivity and reduce absorption.

### Examples of Micro-LEDs with High Reflectivity Mesa Sidewall Electrodes

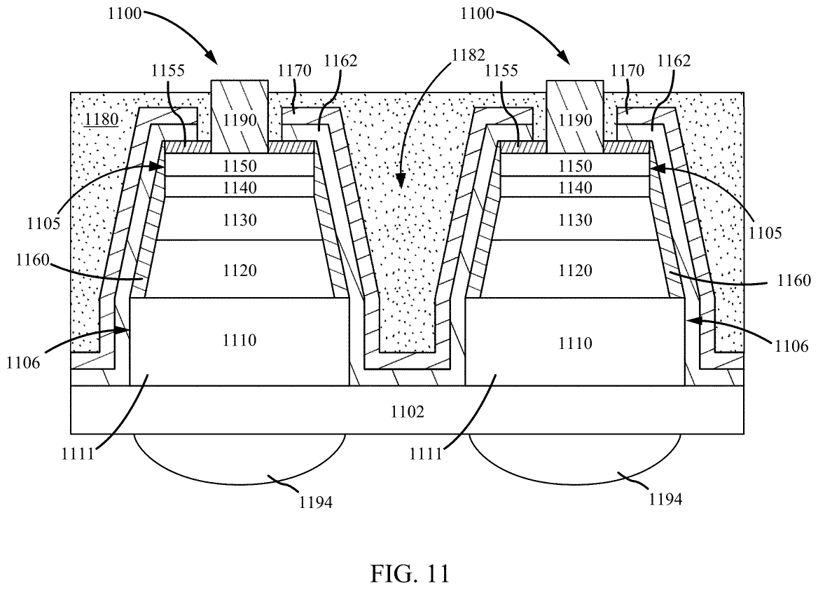

FIG. 11 is a cross-sectional view of an example of an LED device including micro-LEDs 1100 with high reflectivity mesa sidewall electrodes (e.g., n-electrodes), according to certain embodiments. The two micro-LEDs 1100 may be adjacent to each other in a micro-LED array or other LED device. Each micro-LED 1100 may be an example of a light emitter in, e.g., light source 510, 540, or 642. Each micro-LED 1100 includes a mesa structure 1105 with sidewalls 1106. Even though FIG. 11 shows conical mesa structures 1105 with a circular base area, the mesa structures may have another shape such as a vertical, parabolic, semi-parabolic, inward-tilted, or outward-tilted mesa shape, and in addition or alternatively, the base area may have another shape such as rectangular, hexagonal, or triangular. Even though the examples in this section refer to micro-LEDs, it would be understood that these examples apply to other LEDs according to alternative implementations.

Although certain illustrated examples (e.g., in FIGS. 11, 12, 13, 16, 17, and 20) show two micro-LEDs of an LED device, it would be understood that the LED device may include thousands or even millions of micro-LEDs. In some cases, the LED devices may be 2-D arrays having a plurality of micro-LEDs.

In FIG. 11, each mesa structure 1105 has an LED stack that includes a layer of a first semiconductor material 1110, an active layer 1120 formed on the layer of the first semiconductor material 1110 and a layer of a second semiconductor material 1130 formed on the active layer 1120. Layer of the first semiconductor material 1110 may be epitaxially grown on a substrate (not shown) with a buffer layer 1102 disposed thereon. The substrate may be similar to, for example, substrate 710 or substrate 715. Layer of the first semiconductor material 1110 may include a III-V material, such as GaN, and may be p-doped (e.g., with Mg, Ca, Zn, or Be) or n-doped (e.g., with Si or Ge). In one example, the substrate may include a GaN substrate, silicon substrate with a buffer layer or a sapphire substrate with a buffer layer, and layer of the first semiconductor material 1110 may include a GaN layer n-doped with, for example, Si or Ge. In another example, the substrate may include a GaAs substrate. In one implementation, the layer of the first semiconductor material 1110 and the layer of a second semiconductor material 1130 may include the same base material with different doping. Each mesa structure 1105 also includes one or more epitaxial layers, such as, e.g., GaN barrier layers and InGaN quantum well layers, or AlGaInP barrier layers and GaInP quantum well layers, that may be grown on layer of the first semiconductor material 1110 to form an active layer 1120 that includes one or more quantum wells. Active layer 1120 may include III-V materials, such as one or more InGaN layers, one or more AlInGaP layers, and/or one or more GaN layers, which may form one or more heterostructures, such as one or more quantum wells or MQWs. In one aspect, active layer 1120 may comprise a nitride, phosphide, or arsenide alloy. Layer of the second semiconductor material 1130 may include a III-V material, such as GaN, and may be p-doped (e.g., with Mg, Ca, Zn, or Be) or n-doped (e.g., with Si or Ge). One of layer of the first semiconductor material 1110 and layer of the second semiconductor material 1130 may be a p-type layer (e.g., a p-GaN layer) and the other one may be an n-type layer (e.g., n-GaN layer). For example, layer of the first semiconductor material 1110 may be an n-GaN layer and layer of the second semiconductor material 1130 may be a p-GaN layer. Layer of the first semiconductor material 1110 and layer of the second semiconductor material 1130 sandwich active layer 1120 and may form a light emitting region.

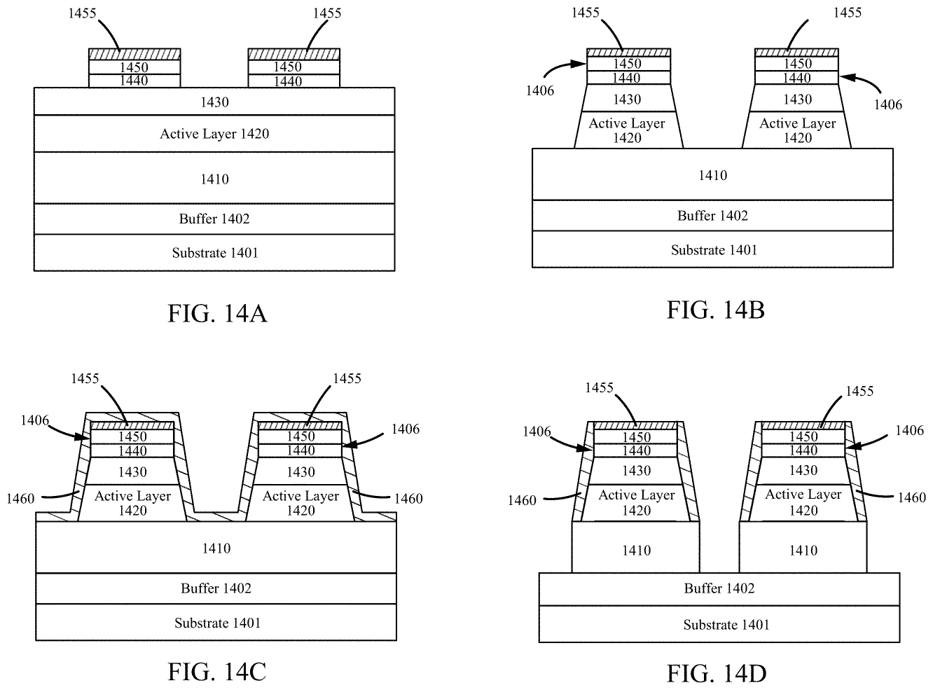

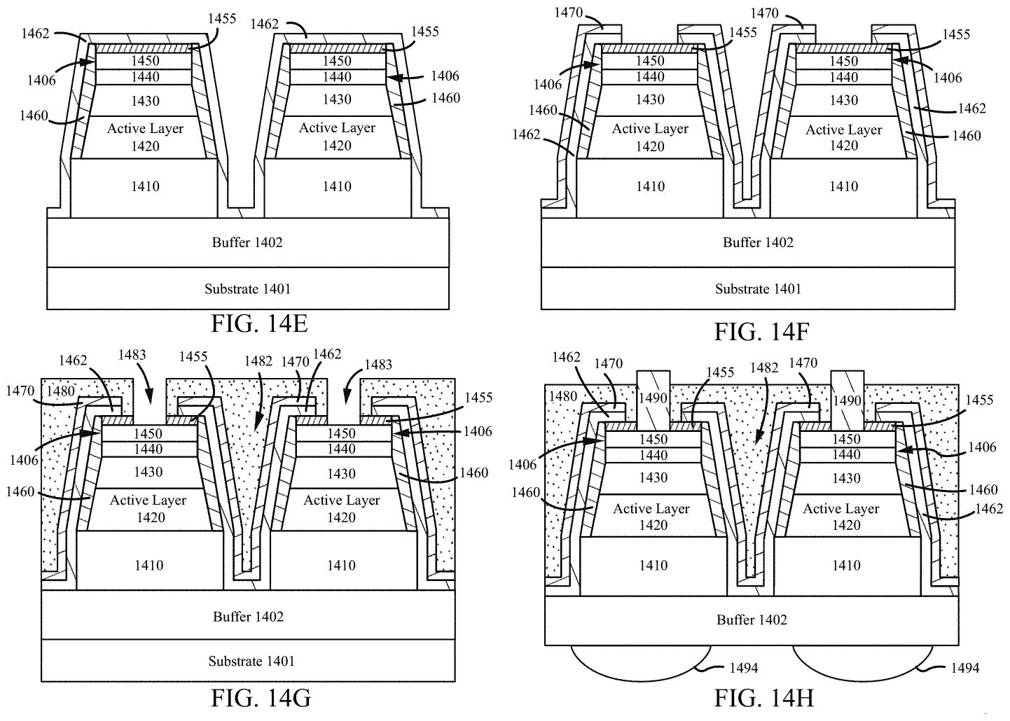

Each mesa structure 1105 also includes a contact layer 1140 (e.g., a p-contact layer) disposed on layer of the second semiconductor material 1130. Contact layer 1140 may be, for example, a layer of indium tin oxide (ITO), another conductive oxide, or a metal film such as Al/Ni/Au film. Each mesa structure 1105 may also include a metal layer 1150 on contact layer 1140. In this example, a mask layer 1155 (e.g., a layer of SiNₓ) is formed on the top surface of metal layer 1150 to be able to selectively etch a stack of layers including active layer 1120, layer of the second semiconductor material 1130, contact layer 1140, and metal layer 1150 to form mesa structures 1105 of desired sizes and pitches. In other examples, mesa structures 1105 may omit or have removed one or both of mask layer 1155 and metal layer 1150. In some embodiments, the mask layer 1155 may also be used as an etch stopping layer as depicted in FIG. 14F.

In the illustrated example, each micro-LED 1100 includes a dielectric layer 1160 (e.g., a layer of SiO₂). Dielectric layer 1160 is formed on sidewalls of active layer 1120, layer of the second semiconductor material 1130, contact layer 1140, metal layer 1150, and mask layer 1155 of mesa structures 1105. In other examples, dielectric layer 1160 may contact fewer layers. Dielectric layer 1160 may also isolate contact layer 1140 and other layers of the stack and may act as a passivation layer. Dielectric layer 1160 may have a lower refractive index than active layer 1120 to reflect emitted light.

Micro-LEDs 1100 also includes a layer of low index conductive material 1162 (e.g., ITO) disposed on at least the sidewalls of layer of the first semiconductor material 1110. The layer of low index conductive material 1162 may help reduce resistance to the layer of first semiconductor material 1110. In the illustrated example, low index conductive material layer 1162 is also disposed on dielectric layer 1160 and between the mesa structures 1105. Layer of the first semiconductor material 1110 may be at least partially etched to provide a portion 1111 with a contact surface on which layer of low index conductive material 1162 may be formed.

Micro-LEDs 1100 also include a metal layer 1170 formed on low index conductive material 1162. Metal layer 1170 may include one or more metal or metal alloy materials, such as aluminum (Al), silver (Ag), gold (Au), platinum (Pt), titanium (Ti), copper (Cu), or any combination thereof. In this example, the metal layer 1170 is formed on the low index conductive material layer 1162. The low index conductive material layer 1162 lies between metal layer 1170 and layer of the first semiconductor material 1110. Layer of low index conductive material 1162 has a lower refractive index than layer of the first semiconductor material 1110 and can increase constructive interference of light emitted by active layer 1120 of micro-LEDs 1100 to promote total internal reflection (TIR) and improve light extraction. For example, low index conductive material may include ITO having an index of refraction ˜2.0 and first semiconductor material may be a GaN layer n-doped with, for example, Si or Ge having an index of refraction of ˜2.5. In this example, light with incident angle greater than a critical angle of about 53° may be totally internally reflected. Alternatively, the low index conductive material may be another transparent conductive oxide (TCO) such as indium zinc oxide (IZO), aluminum doped zinc oxide (AZO), or fluorine doped tin oxide (FTO).

A dielectric material 1180 may be coated on micro-LEDs 1100. In the illustrated example, dielectric material 1180 fills in the gaps between adjacent micro-LEDs 1100. Dielectric material 1180 may be, for example, SiO₂ or SiNₓ.

In the illustrated example, micro-LEDs 1100 also include metal plugs 1190 formed in a dielectric window in dielectric material 1180. The metal plugs 1190 may form p-electrodes and bonding pads for the p-electrodes to, for example, a CMOS backplane. The metal plugs 1190 pass through an aperture in the layer of low index conductive material 1162 and metal layer 1170 to contact metal layer 1150. Each micro-LED 1100 also includes a lens 1194 on a light emission surface to focus and/or collimate the emitted light or couple the emitted light into a waveguide. Although a single lens is shown in the illustrated example, in other implementations additional optical elements may be included such as additional lenses, a grating, a waveguide, a prism, etc.

Even though FIG. 11 shows layer of low index conductive material 1162 and metal layer 1170 extending along sidewalls of all illustrated layers of mesa structures 1105, in other examples, one or both of the low index conductive material layer 1162 and metal layer 1170 may extend along a portion of the sidewalls. For example, low index conductive material layer 1162 and/or metal layer 1170 may extend along sidewalls of layer of the first semiconductor material 1110 and not extend or extend only a portion of sidewalls of other layers of mesa structures 1105. In one aspect, the first semiconductor material is n-doped and metal layer 1170 acts as a high reflectivity mesa sidewall n-electrode. In another aspect, the first semiconductor material is p-doped and metal layer 1170 acts as a high reflectivity mesa sidewall p-electrode.

In one aspect, micro-LEDs in an LED device include additional layer(s) of material (e.g., a SiO₂ layer, a SiNₓ layer, or a distributed Bragg reflector (DBR) structure) between the low index conductive material layer in direct contact with the n-type semiconductor layer and the metal layer to further promote TIR and improve light extraction. In one implementation, the additional layer(s) have a lower index of refraction than the low index conductive material layer in contact with the n-type semiconductor layer. For example, a layer of SiO₂ (index of refraction ˜1.5) may be formed between a low index conductive material layer comprising ITO (index of refraction ˜2.0) and an Aluminum (Al) layer. In this example, light with incident angle greater than a critical angle of about 53° may be totally internally reflected. In another implementation, a distributed Bragg reflector (DBR) structure may be formed between the low index conductive material layer and the metal layer. The DBR structure may include a plurality layers such as low-index dielectric layers. In some cases, the DBR structure includes conductive materials of different refractive indices. The thicknesses and materials in the layers of a DBR structure may be selected to cause constructive interference between light reflected at the interfaces between the layers of the DBR to achieve a high reflectivity for particular wavelength and/or other optical properties. For example, the thicknesses and materials of the layers in a DBR structure may be selected for high reflectivity of a target wavelength emitted from the active layer. In some embodiments, the DBR can include conductive materials.

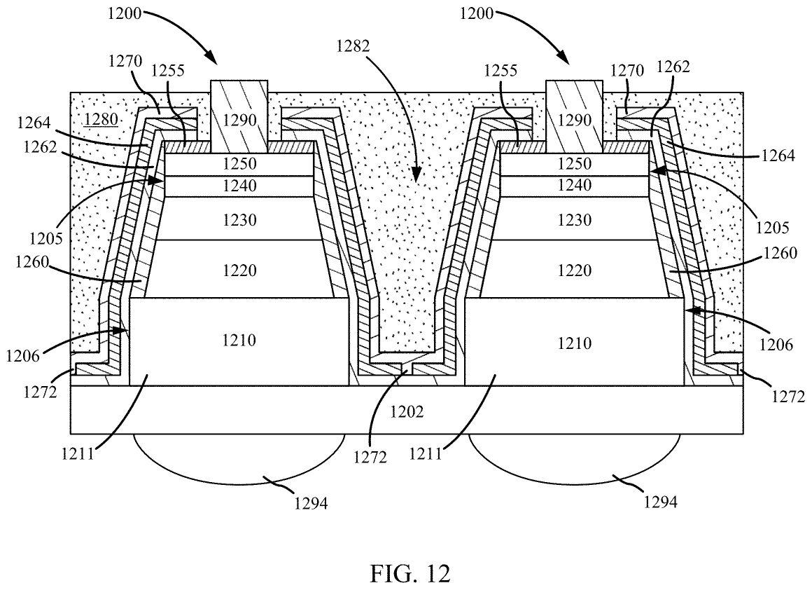

FIG. 12 is a cross-sectional view of another example of an LED device including micro-LEDs 1200 with high reflectivity mesa sidewall electrodes (e.g., n-electrodes), according to certain embodiments. In this example, micro-LEDs 1200 include a layer of low refractive index material (e.g., a SiO₂ layer) 1264 between the layer of low index conductive material 1262 and the metal layer 1270. The low refractive index material in layer 1264 may have a lower refractive index than the low index conductive material in layer 1262 to further promote TIR and improve light extraction.

The two micro-LEDs 1200 may be adjacent to each other in a micro-LED array or other LED device and may be an example of a light emitter in, e.g., light source 510, 540, or 642. Each micro-LED 1200 includes a mesa structure 1205 with sidewalls 1206. Although FIG. 12 shows conical mesa structures 1205 with a circular base, the micro-LEDs 1200 may have mesa structures of other shapes and the base area may be circular, rectangular, hexagonal, or triangular.

In FIG. 12, each mesa structure 1205 has an LED stack that includes a layer of the first semiconductor material 1210, an active layer 1220 formed on the layer of the first semiconductor material 1210 and a layer of a second semiconductor material 1230 formed on the active layer 1220. Layer of the first semiconductor material 1210 may be epitaxially grown on a substrate (not shown) with a buffer layer 1202 disposed thereon. The substrate may be similar to, for example, substrate 710 or substrate 715. Layer of the first semiconductor material 1210 may include a III-V material, such as GaN, and may be p-doped (e.g., with Mg, Ca, Zn, or Be) or n-doped (e.g., with Si or Ge). In one example, the substrate may include a GaN substrate, a silicon substrate with a buffer layer or a sapphire substrate with a buffer layer, and layer of the first semiconductor material 1210 may include a GaN layer n-doped with, for example, Si or Ge. In another example, the substrate may include a GaAs substrate. In one implementation, the layer of the first semiconductor material 1210 and the layer of a second semiconductor material 1230 may include the same base material with different doping. Each mesa structure 1205 also includes one or more epitaxial layers, such as, e.g., GaN barrier layers and InGaN quantum well layers, or AlGaInP barrier layers and GaInP quantum well layers, that may be grown on layer of the first semiconductor material 1210 to form an active layer 1220 that includes one or more quantum wells. Active layer 1220 may include multiple quantum well layers having lower bandgap materials that are sandwiched by barrier layers having higher bandgap materials (e.g., III-V materials) to form one or more quantum wells or MQWs. In one aspect, active layer 1220 may comprise a nitride, phosphide, or arsenide alloy. Layer of the second semiconductor material 1230 may include a III-V material, such as GaN, and may be p-doped (e.g., with Mg, Ca, Zn, or Be) or n-doped (e.g., with Si or Ge). One of layer of the first semiconductor material 1210 and layer of the second semiconductor material 1230 may be a p-type layer (e.g., a p-GaN layer) and the other one may be an n-type layer (e.g., n-GaN layer). For example, layer of the first semiconductor material 1210 may be an n-GaN layer and layer of the second semiconductor material 1230 may be a p-GaN layer. Layer of the first semiconductor material 1210 and layer of the second semiconductor material 1230 sandwich active layer 1220 and may form a light emitting region.

Each mesa structure 1205 also includes a contact layer 1240 (e.g., a p-contact layer) disposed on layer of the second semiconductor material 1230. Contact layer 1240 may be, for example, a layer of indium tin oxide (ITO), another conductive oxide, or an Al/Ni/Au film. Each mesa structure 1205 may also include a metal layer 1250 on contact layer 1240. In this example, a mask layer 1255 (e.g., a layer of SiNₓ) is formed on the top surface of metal layer 1250 to be able to selectively etch a stack of layers including active layer 1220, layer of the second semiconductor material 1230, contact layer 1240, and metal layer 1250 to form mesa structures 1205 of desired sizes and pitches. The mask layer 1255 may also be used as an etch stopping layer as depicted in FIG. 14F. In other examples, mesa structures 1205 may omit or have removed one or both of mask layer 1255 and metal layer 1250.

In the illustrated example, each micro-LED 1200 includes a dielectric layer 1260 that may include, for example, SiO₂ or SiNₓ. Dielectric layer 1260 is formed on sidewalls of active layer 1220, layer of the second semiconductor material 1230, contact layer 1240, metal layer 1250, and mask layer 1255 of mesa structures 1205. In other examples, dielectric layer 1260 may be disposed on sidewalls of fewer layers. Dielectric layer 1260 may also isolate contact layer 1240 and other layers of the stack and may act as a passivation layer. Dielectric layer 1260 may have a lower refractive index than active layer 1220 to reflect emitted light.

Micro-LEDs 1200 also include a layer of low index conductive material 1262 formed on at least the sidewalls of the layer of the first semiconductor material 1210. In the illustrated example, low index conductive material layer 1262 is also disposed on dielectric layer 1260. The layer of low index conductive material 1262 may help reduce resistance to the layer of first semiconductor material 1210. Layer of the first semiconductor material 1210 may be at least partially etched to provide a portion 1211 with a contact surface on which layer of low index conductive material 1262 may be formed. Layer of low index conductive material 1262 has a lower refractive index than layer of the first semiconductor material 1210 to increase constructive interference of light emitted by active layer 1220 of micro-LEDs 1200 to promote total internal reflection (TIR) and improve light extraction.

Micro-LEDs 1200 also include a layer of low index material 1264 such as, for example, dielectric material, formed on layer of low index conductive material 1262. Layer of low index material 1264 may have a lower refractive index than low index conductive material 1262 to further increase constructive interference of light emitted by active layer 1220 of micro-LEDs 1200 to promote total internal reflection (TIR) and improve light extraction.

Micro-LEDs 1200 also include a metal layer 1270 formed on the other layer of low index material 1264. Metal layer 1270 may include one or more metal or metal alloy materials, such as aluminum (Al), silver (Ag), gold (Au), platinum (Pt), titanium (Ti), copper (Cu), or any combination thereof. The layer of low index material 1264 lies between layer of low index conductive material 1262 and metal layer 1270. Metal layer 1270 includes metal plugs 1272 formed through the layer of low index material 1264 and in contact with, and/or partially passing through, the layer of low index conductive material 1262. Metal plugs 1272 may be located in a dead zone 1282 in a region between mesa structures 1205 where the quantum well layers have been etched. The location of metal plugs 1272 in the dead zone may help avoid absorption of light emitted by active layer 1220 by the metal plugs 1272.

Even though certain examples, such as the illustrated examples of FIGS. 12, 13, and 20, show a metal plug (e.g., metal plug 1272 in FIG. 12) in contact with, but not passing through, the layer of low index conductive material, in other implementations, the metal plug may pass through a portion of, or entire thickness of, the layer of low index conductive material. In these implementations, passing the metal plug through at least a portion of the layer of low index conductive material increases contact area between the metal layer and the layer of low index conductive material and may reduce resistance.

Returning to FIG. 12, a dielectric material 1280 may be coated on micro-LEDs 1200. In the illustrated example, dielectric material 1280 fills in the gaps between adjacent micro-LEDs 1200. Dielectric material 1280 may be, for example, SiO₂ or SiNₓ. Micro-LEDs 1200 also include metal plugs 1290 formed in a dielectric window in dielectric material 1280. The metal plugs 1290 may form p-electrodes and bonding pads for the p-electrodes to, for example, a CMOS backplane. The metal plugs 1290 pass through an aperture in the layer of low index conductive material 1262 and metal layer 1270 to contact metal layer 1250. Each micro-LED 1200 also includes a lens 1294 on a light emission surface to focus and/or collimate the emitted light or couple the emitted light into a waveguide. Although a single lens is shown in the illustrated example, in other implementations additional optical elements may be included such as additional lenses, a grating, a waveguide, a prism, etc.

Even though FIG. 12 shows layer of low index conductive material 1262, metal layer 1270, and layer of low index material 1264 extending along sidewalls of all illustrated layers of mesa structures 1205, in other examples, one or more of these layers may extend along a portion of the sidewalls. For example, one or more of these layers may extend along sidewalls of layer of the first semiconductor material 1210 and not extend or extend only a portion of sidewalls of other layers of mesa structures 1205. In one aspect, the first semiconductor material is n-doped and metal layer 1270 acts as a high reflectivity mesa sidewall n-electrode. In another aspect, the first semiconductor material is p-doped and metal layer 1270 acts as a high reflectivity mesa sidewall p-electrode.

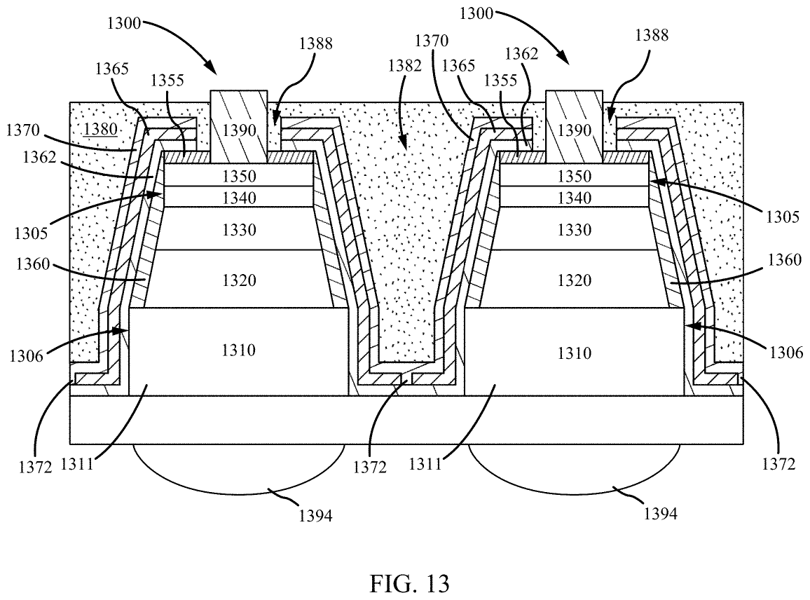

FIG. 13 is a cross-sectional view of another example of two micro-LEDs 1300 with high reflectivity mesa sidewall electrodes (e.g., n-electrodes), according to certain embodiments. In this example, micro-LEDs 1300 include a DBR 1365 between the layer of low index conductive material 1362 and the metal layer 1370. The two micro-LEDs 1300 may be adjacent to each other in a micro-LED array or other LED device and may be an example of a light emitter in, e.g., light source 510, 540, or 642. Each micro-LED 1300 includes a mesa structure 1305 with sidewalls 1306. Although FIG. 13 shows conical mesa structures 1305 with a circular base, the micro-LEDs 1300 may have mesa structures of other shapes and the base area may be circular, rectangular, hexagonal, or triangular.

In FIG. 13, each mesa structure 1305 has an LED stack that includes a layer of a first semiconductor material 1310, an active layer 1320 formed on the layer of the first semiconductor material 1310 and a layer of a second semiconductor material 1330 formed on the active layer 1320. Layer of the first semiconductor material 1310 may be epitaxially grown on a substrate (not shown) with a buffer layer 1302 disposed thereon. The substrate may be similar to, for example, substrate 710 or substrate 715. Layer of the first semiconductor material 1310 may include a III-V material, such as GaN, and may be p-doped (e.g., with Mg, Ca, Zn, or Be) or n-doped (e.g., with Si or Ge). In one example, the substrate may include a GaN substrate, a silicon substrate with a buffer layer or a sapphire substrate with a buffer layer, and layer of the first semiconductor material 1310 may include a GaN layer n-doped with, for example, Si or Ge. In another example, the substrate may include a GaAs substrate. In one implementation, the layer of the first semiconductor material 1310 and the layer of a second semiconductor material 1330 may include the same base material with different doping. Each mesa structure 1305 also includes one or more epitaxial layers, such as, e.g., GaN barrier layers and InGaN quantum well layers, or AlGaInP barrier layers and GaInP quantum well layers, that may be grown on layer of the first semiconductor material 1310 to form an active layer 1320 that includes one or more quantum wells. Active layer 1320 may include multiple quantum well layers having lower bandgap materials that are sandwiched by barrier layers having higher bandgap materials (e.g., III-V materials) to form one or more quantum wells or MQWs. In one aspect, active layer 1320 may comprise a nitride, phosphide, or arsenide alloy. Layer of the second semiconductor material 1330 may include a III-V material, such as GaN, and may be p-doped (e.g., with Mg, Ca, Zn, or Be) or n-doped (e.g., with Si or Ge). One of layer of the first semiconductor material 1310 and layer of the second semiconductor material 1330 may be a p-type layer (e.g., a p-GaN layer) and the other one may be an n-type layer (e.g., n-GaN layer). For example, layer of the first semiconductor material 1310 may be an n-GaN layer and layer of the second semiconductor material 1330 may be a p-GaN layer. Layer of the first semiconductor material 1310 and layer of the second semiconductor material 1330 sandwich active layer 1320 and may form a light emitting region.

Each mesa structure 1305 also includes a contact layer 1340 (e.g., a p-contact layer) disposed on layer of the second semiconductor material 1330. Contact layer 1340 may be, for example, a layer of indium tin oxide (ITO), another conductive oxide, or a metal film such as an Al/Ni/Au film. Each mesa structure 1305 may also include a metal layer 1350 on contact layer 1340. In this example, a mask layer 1355 (e.g., a layer of SiNₓ) is formed on the top surface of metal layer 1350 to be able to selectively etch a stack of layers including active layer 1320, layer of the second semiconductor material 1330, contact layer 1340, and metal layer 1350 to form mesa structures 1305 of desired sizes and pitches. The mask layer 1355 may also be used as an etch stopping layer as depicted in FIG. 14F. In other examples, mesa structures 1305 may omit or have removed one or both of mask layer 1355 and metal layer 1350.

In the illustrated example, each micro-LED 1300 includes a dielectric layer 1360 that may include, for example, SiO₂ or SiNₓ. Dielectric layer 1360 is formed on sidewalls of active layer 1320, layer of the second semiconductor material 1330, contact layer 1340, metal layer 1350, and mask layer 1355 of mesa structures 1305. In other examples, dielectric layer 1360 may be formed on fewer layers. Dielectric layer 1360 may also isolate contact layer 1340 and other layers of the stack and may act as a passivation layer. Dielectric layer 1360 may have a lower refractive index than active layer 1320 to reflect emitted light.

Micro-LEDs 1300 also include a layer of low index conductive material 1362 formed on at least the sidewalls of the layer of the first semiconductor material 1310. The layer of low index conductive material 1362 may help reduce resistance to the layer of first semiconductor material 1310. In the illustrated example, low index conductive material layer 1362 is also disposed on dielectric layer 1360. Layer of the first semiconductor material 1310 may be at least partially etched to provide a portion 1311 with a contact surface on which layer of low index conductive material 1362 may be formed. Layer of low index conductive material 1362 has a lower refractive index than layer of the first semiconductor material 1310 to increase constructive interference of light emitted by active layer 1320 of micro-LEDs 1300 to promote total internal reflection (TIR) and improve light extraction.

Micro-LEDs 1300 also include a layer of low index material 1364 such as, for example, dielectric material, formed on layer of low index conductive material 1362. Layer of low index material 1364 may have a lower refractive index than low index conductive material 1362 to further increase constructive interference of light emitted by active layer 1320 of micro-LEDs 1300 to promote total internal reflection (TIR) and improve light extraction.

Micro-LEDs 1300 also include a distributed Bragg reflector (DBR) structure 1365 formed on layer of low index conductive material 1362 and a metal layer 1370 formed on DBR structure 1365. Metal layer 1370 may include one or more metal or metal alloy materials, such as aluminum (Al), silver (Ag), gold (Au), platinum (Pt), titanium (Ti), copper (Cu), or any combination thereof. DBR structure 1365 lies between low index conductive material 1362 and metal layer 1370. The DBR structure may include a plurality of layers such as low-index dielectric layers. In some cases, the DBR structure includes conductive materials of different refractive indices. The thicknesses and/or materials in the layers of a DBR structure may be selected to cause constructive interference between light reflected at the interfaces between the layers of the DBR to achieve high reflectivity for a particular wavelength band and/or other optical properties. For example, the thicknesses and materials of the layers in a DBR structure may be selected for high reflectivity (e.g., about 100%) of a target wavelength emitted from the active layer. In some embodiments, the DBR can include conductive materials.

In FIG. 13, metal layer 1370 includes metal plugs 1372 formed through DBR structure 1365 and in contact with, and/or at least partially going into, layer of low index conductive material 1362. Metal plugs 1372 may be located in a dead zone 1382 in a region between mesa structures 1305 where the quantum well layers have been etched. The location of metal plugs 1372 in the dead zone may help avoid absorption of light emitted by active layer 1320. A dielectric material 1380 may be coated on micro-LEDs 1300. In the illustrated example, dielectric material 1380 fills in the gaps between adjacent micro-LEDs 1300. Dielectric material 1380 may include, for example, an oxide such as SiO₂ or SiNₓ. Micro-LEDs 1300 also include metal plugs 1390 formed in a dielectric window formed in dielectric material 1380 that may form p-electrodes and bonding pads for the p-electrodes to, for example, a CMOS backplane. The metal plugs 1390 pass through an aperture in the layer of low index conductive material 1362 and metal layer 1370 to contact metal layer 1350. Each micro-LED 1300 also includes a lens 1394 on a light emission surface to focus and/or collimate the emitted light or couple the emitted light into a waveguide. Although a single lens is shown in the illustrated example, in other implementations additional optical elements may be included such as additional lenses, a grating, a waveguide, a prism, etc.

Even though FIG. 13 shows layer of low index conductive material 1362, metal layer 1370, and DBR structure 1365 extending along sidewalls of all illustrated layers of mesa structures 1305, in other examples, one or more of these layers may extend along a portion of the sidewalls. For example, one or more of these layers may extend along sidewalls of layer of the first semiconductor material 1310 and not extend or extend only a portion of sidewalls of other layers of mesa structures 1305. In one aspect, the first semiconductor material is n-doped and metal layer 1370 acts as a high reflectivity mesa sidewall n-electrode. In another aspect, the first semiconductor material is p-doped and metal layer 1370 acts as a high reflectivity mesa sidewall p-electrode.

In certain implementations, an LED device includes a plurality of micro-LEDs having a pixel pitch between adjacent micro-LEDs. In one aspect, the pixel pitch is about 2 μm. In another aspect, the pixel pitch is about 3 μm. In another aspect, the pixel pitch is less than about 5 μm. In micro-LEDs having a small pixel pitch (e.g., pixel pitch of about 2 μm) there may be high contact resistance between the contact layer and the layer of first semiconductor material, which may reduce the voltage and/or current applied to the active regions and the efficiency of the micro-LEDs. In one aspect, a low index conductive layer is formed at sidewalls of the layer of the first semiconductor material, which is close to the active region, rather than at regions between the mesas. The location of the low index conductive layer can reduce resistance on the n-side. For LED arrays with small pixel pitch, the regions between mesas may be small and having the low index conductive layer at the sidewalls may be advantageous. In addition, micro-LEDs with a lower index material layer between a metal layer and the layer of first semiconductor material may improve total internal reflection of the micro-LEDs to compensate for inefficiencies due to this high contact resistance in micro-LEDs with small pixel pitch.

FIGS. 14A-14H illustrate an example of a method of fabricating micro-LEDs with high reflectivity mesa sidewall electrodes such as high reflectivity mesa sidewall n-electrodes, according to certain embodiments. The illustrated method may be used to fabricate the micro-LEDs 1100, 1200, and 1300 illustrated in FIGS. 11, 12, and 13. The methods includes multiple mesa etching steps.

FIG. 14A depicts an LED layer stack including multiple epitaxial layers grown on a substrate 1401. Substrate 1401 may be a substantially planar substrate. Substrate 1401 may have an in-plane lattice constant that is close to the in-plane lattice constants of the epitaxial layers to be grown on the substrate, in order to reduce lattice mismatch. For example, substrate 1401 may be a sapphire substrate or a silicon substrate. In the illustrated example, a buffer layer 1402 is formed on substrate 1401 to, for example, provide a surface suitable for formation of a layer of a first semiconductor material 1410 (e.g., an n-GaN layer). Layer of first semiconductor material 1410 may be epitaxially grown on buffer layer 1402, using any suitable process such as an MOCVD process or an MBE process. The first semiconductor material may include a III-V material, such as GaN, and may be n-doped (e.g., with Si or Ge) or p-doped. In one example, layer of first semiconductor material 1410 may have an n-doping (e.g., Si or Ge doping) density of about 5×10¹⁸ cm⁻³ or higher.

Following formation of layer of first semiconductor material 1410, active layer 1420 may be epitaxially grown on layer of first semiconductor material 1410. The active layer 1420 may include multiple quantum well layers having lower bandgap materials that are sandwiched by barrier layers having higher bandgap materials (e.g., III-V materials) to form one or more quantum wells or MQWs. In one aspect, active layer 1420 may comprise a nitride, phosphide, or arsenide alloy.

Following formation of active layer 1420, a layer of a second semiconductor material 1430 (e.g., an p-GaN layer) may be epitaxially grown on active layer 1420. The second semiconductor material may include a III-V material, such as GaN, and may be p-doped or n-doped (e.g., with Si or Ge).

Following formation of layer of second semiconductor material 1430, a contact layer 1440 may be formed on the layer of second semiconductor material 1430. The contact layer 1440 (e.g., p-contact layer) may include a conductive oxide such as indium tin oxide (ITO) or a metal film such as, e.g., a Ag/Pt/Au film or a Al/Ni/Au film. Next, a metal layer 1450 may be formed on the contact layer 1440. The metal layer 1450 may include, for example, Al, Pt, Au, Ag, Ni, Ti, Cu, W, or any combination thereof (e.g., Ag/Pt/Au or Al/Ni/Au). The metal layer 1450 may act as a light reflector for reflecting light emitted from active layer 1420. An etch mask layer 1455 (e.g., SiNₓ) may be formed on the metal layer 1450. In one aspect, a photoresist layer is also included and used to pattern the etch mask layer 1455.

FIG. 14A shows that etch mask layer 1455 may be patterned using a lithography process to form an etch mask. Etch mask layer 1455 can be used to etch precursor mesa structures and pixel mesa structures for individual micro-LEDs. In addition, metal layer 1450 and contact layer 1440 (e.g., ITO) may be patterned or etched using etch mask layer 1455.

FIG. 14B depicts a first mesa etching process that uses the patterned etch mask 1455 to etch through layer of second semiconductor material 1430 and the active layer 1420 to form precursor mesa structures of individual micro-LEDs. Each of these precursor mesa structures includes an active layer 1420, a layer of second semiconductor material 1430 (e.g., p-GaN), a contact layer 1440 (e.g., ITO), a metal layer 1450, and a patterned etch mask 1455. In other implementations, one or both of etch mask layer 1455 and metal layer 1450 may be removed. Although the depicted method in FIGS. 14A-H are described with reference to two mesa structures, additional mesa structures may be formed by this method such as, e.g., 4, 6, 8, 9, or more mesa structures may be formed.

A dielectric layer may be formed on sidewalls of one or more layers of the pixel mesa structures to, for example, electrically isolate these layers at their sidewalls and may act as a passivation layer. FIG. 14C depicts that a dielectric layer 1460 may be conformally deposited on surfaces including sidewalls 1406 of the precursor mesa structures and in regions between the precursor mesa structures. Dielectric layer 1460 may be, for example, a layer of SiO₂. Dielectric layer 1460 may have any desired thickness. In one aspect, the dielectric layer 1460 may have a thickness greater than about 50 nm and lower than about 500 nm in a surface normal direction of the mesa sidewall surfaces.

FIG. 14D depicts that a self-aligned second mesa etching processes may be performed using patterned etch mask 1455. The self-aligned second mesa etching process may vertically etch through dielectric layer 1460 and at least a portion of the layer of the first semiconductor material 1410 to form pixel mesa structures of individual micro-LEDs. In the illustrated example, the self-aligned second mesa etching process may vertically etch through, or substantially through, the layer of the first semiconductor material 1410. Each pixel mesa structure includes a layer of a first semiconductor material 1410 (e.g., n-GaN layer), active layer 1420, layer of second semiconductor material 1430 (e.g., p-GaN layer), contact layer (e.g., p-contact layer) 1440, metal layer 1450, and etch mask layer 1455. In another implementation, after the self-aligned second mesa etching process, etch mask layer 1455 and/or metal layer 1450 may be removed. After the self-aligned second mesa etching process, dielectric layer 1460 remains on sidewalls of active layer 1420, layer of second semiconductor material 1430, contact layer 1440, metal layer 1450, and etch mask layer 1455.

FIG. 14E depicts that a layer of low index conductive material 1462 may be formed on sidewalls 1406 of the pixel mesa structures shown in FIG. 14D. The low index conductive material may have a lower refractive index than the first semiconductor material. In one aspect, the low index conductive material is ITO. In one example, low index conductive material may include ITO having an index of refraction ˜2.0 and first semiconductor material may be a GaN layer n-doped with, for example, Si or Ge and having an index of refraction of ˜2.5. In this example, light with incident angle greater than a critical angle of about 53° may be totally internally reflected. Alternatively, the low index conductive material may be another transparent conductive oxide (TCO) such as indium zinc oxide (IZO), aluminum doped zinc oxide (AZO), or fluorine doped tin oxide (FTO). Although the illustrated example shows layer of low index conductive material 1462 extending along the length of the sidewalls of the pixel mesa structures, in other examples layer of low index conductive material 1462 may extend along only sidewalls of layer of the first semiconductor material 1410 and not extend or only extend a portion of the length of the sidewalls of other layers of the individual pixel mesa structures. In one aspect, low index conductive material 1462 may be formed on sidewalls of at least the layer the first semiconductor material of the individual pixel mesa structures.

FIG. 14F depicts that a metal layer 1470 may be deposited on layer of low index conductive material 1462 on the sidewalls of the pixel mesa structures shown in FIG. 14E and between adjacent mesa structures. In the illustrated example, a window is formed in metal layer 1470 and/or layer of low index conductive material 1462, for example, by an etching operation. The etch mask layer 1455 may be used as an etch stop layer for etching layer of low index conductive material 1462 and metal layer 1470. Metal layer 1470 may include one or more metal or metal alloy materials, such as aluminum (Al), silver (Ag), gold (Au), platinum (Pt), titanium (Ti), copper (Cu), or any combination thereof. In one aspect, the first semiconductor material is n-doped and metal layer 1470 acts as a high reflectivity mesa sidewall n-electrode. In another aspect, the first semiconductor material is p-doped and metal layer 1470 acts as a high reflectivity mesa sidewall p-electrode.

In certain implementations, a layer of lower index of refraction (substantially nonconductive) material or a DBR with high reflectivity is formed on the layer of low index conductive material 1462 as shown in FIGS. 12 and 13. This additional layer or layers of material lie between the layer of low index conductive material 1462 and the metal layer 1470. In this case, the metal layer 1470 been deposited to form a metal plug in a window that passes through these additional layer or layers of material to contact the layer of low index conductive material 1462. For example, the additional layer of material may be a layer of SiO₂ or a DBR, the low index conductive material may be ITO, and the first semiconductor material may be n-GaN. The layer of low index conductive material 1462 and layer of lower index of refraction (substantially nonconductive) material or DBR may reflect light emitted from the active region of the LED stack before light reaches the metal layer 1470 to lessen light absorption.

FIG. 14G depicts that a dielectric material 1480 may be formed on the pixel mesa structures shown in FIG. 14F. The dielectric material 1480 may then be planarized. Dielectric material 1480 may include, for example, an oxide such as SiO₂. Dielectric material 1480 may fill the gaps between individual pixel mesa structures. A dielectric window may be opened (formed) in the dielectric material 1480 and through the etch mask layer 1455 to contact metal layer 1450.

FIG. 14H depicts that metal plugs 1490 may be formed in dielectric layer 1480 to form p-electrodes and bonding pads for the p-electrodes, and/or n-electrodes and bonding pads for the n-electrodes. Metal plugs may be formed by depositing a metal material into the dielectric window shown formed in FIG. 14F. In addition, FIG. 14H depicts that the substrate 1401 may be removed (or thinned) and the buffer layer 1402 may be thinned, and lenses 1494 are formed on the backside. In one implementation, the metal plugs 1490 may be bonded to a CMOS backplane.

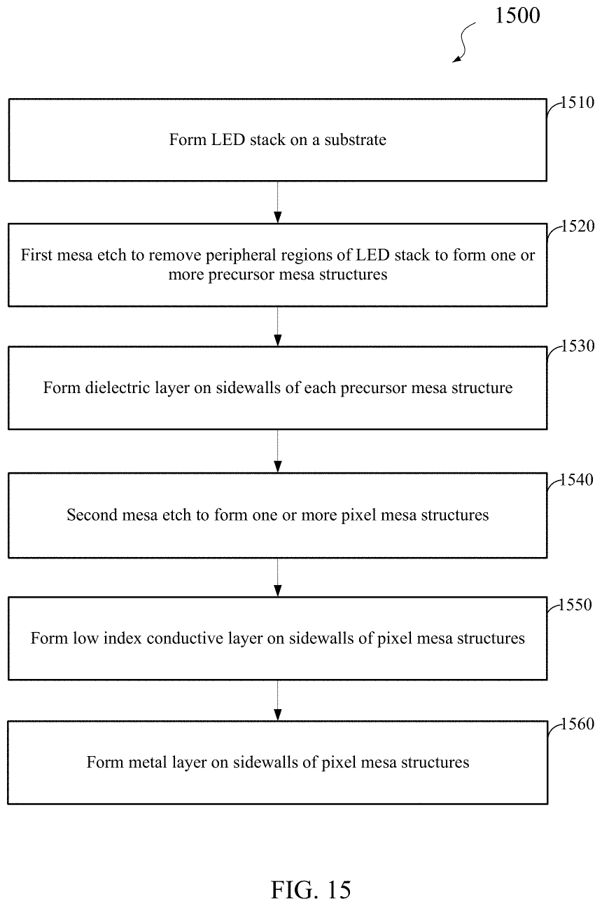

FIG. 15 includes a flowchart 1500 illustrating operations in an example of a method of fabricating an LED device having one or more LEDs (e.g., micro-LEDs), each having a high reflectivity mesa sidewall electrode (e.g., an n-electrode), according to certain embodiments. Although FIG. 15 illustrates particular example operations for fabricating the LED device, other sequences of operations can also be performed according to alternative embodiments. For example, alternative embodiments may perform the operations in a different order. Moreover, the illustrated operations may include multiple sub-operations that can be performed in various sequences as appropriate for the individual operation. Furthermore, some operations can be added or removed depending on the particular applications. In some implementations, two or more operations may be performed in parallel. One of ordinary skill in the art would recognize many variations, modifications, and alternatives.

Operations in block 1510 include forming an LED layer stack (sometimes referred to herein as “LED stack”) including multiple epitaxial layers grown on a substrate. The substrate may have a buffer layer disposed thereon. As described above with respect to, for example, FIG. 14A, in some embodiments, forming the LED layer stack on the substrate may include growing an epitaxial layer stack on the substrate. The epitaxial layer stack may be etched using a patterned etch mask to form the plurality of precursor mesa structures. For example, each LED stack may include a layer of a first semiconductor material (e.g., n-GaN), an active layer, a layer of a second semiconductor material (e.g., p-GaN), a metal layer (e.g., Al layer) a contact layer (e.g., ITO), and a patterned etch mask. In other implementations, metal layer and/or patterned etch mask may be omitted. The first semiconductor material may include a III-V material, such as GaN, and may be n-doped (e.g., with Si or Ge) or p-doped. The contact layer (e.g., p-contact layer) may include a conductive oxide such as indium tin oxide (ITO) or a metal film such as, e.g., a Ag/Pt/Au film or a Al/Ni/Au film. The metal layer may include, for example, Al, Pt, Au, Ag, Ni, Ti, Cu, W, or any combination thereof (e.g., Ag/Pt/Au or Al/Ni/Au). The active layer may include III-V materials, such as one or more InGaN layers, one or more AlInGaP layers, and/or one or more GaN layers, which may form one or more heterostructures, such as one or more quantum wells or MQWs. Any suitable number of precursor mesa structures may be formed such as, for example, 2, 4, 6, 8, 9, or more mesas may be formed. In one aspect, the active layer may comprise a nitride, phosphide, or arsenide alloy.

At block 1520, a first mesa etch is performed to remove peripheral regions of the LED layer stack to form one or more precursor mesa structures, for example, as shown in FIG. 14B. In some embodiments, the etching may form multiple precursor mesa structures, such as 2, 4, 6, 8, 9, or more precursor mesa structures. In one example, the etching may etch through at least the contact layer, the layer of second semiconductor material, and the active layer.

At block 1530, a dielectric layer may be deposited on surfaces of the precursor mesa structures and in regions between the precursor mesa structures as shown in, for example, FIG. 14C. The dielectric layer may isolate the contact layer and may act as a passivation layer at the sidewalls of the active layer. The dielectric layer may be on at least a portion of the sidewalls of the layer of the active layer and second semiconductor material. The dielectric layer may include, for example, SiO₂ or Si₃N₄.

At block 1540, a second mesa etch is performed using a patterned mask to vertically etch through at least a portion of the layer of the first semiconductor material to form individual pixel mesa structures of, for example, individual micro-LEDs as shown in, for example, FIG. 14D. In one example, the pixel mesa structure formed includes the layer of first semiconductor material (e.g., n-GaN layer), the active layer, the layer of second semiconductor material (e.g., p-GaN layer), a contact layer (e.g., p-contact layer), a metal layer and a mask layer. The second mesa etch process also etches a portion of the dielectric layer leaving the dielectric layer on sidewalls of the pixel mesa structures in contact with at least the layer of the active layer and the second semiconductor material. In one example, after the second mesa etching process, etch mask layer and/or metal layer may be removed.

At block 1550, a layer of low index conductive material may be formed on sidewalls of the pixel mesa structures. For example, the layer of low index conductive material may be deposited on and between the pixel mesa structures as shown, for example, in FIG. 14E. As another example, the layer of low index conductive material may be formed on at least the sidewall of the layer of the first semiconductor material. The low index conductive material has a lower refractive index than the first semiconductor material. In one aspect, the low index conductive material is ITO. For example, low index conductive material may include ITO having an index of refraction ˜2.0 and first semiconductor material may be a GaN layer n-doped with, for example, Si or Ge having an index of refraction of ˜2.5. In this example, light with incident angle greater than a critical angle of about 53° may be totally internally reflected. Alternatively, the low index conductive material may be another transparent conductive oxide (TCO) such as indium zinc oxide (IZO), aluminum doped zinc oxide (AZO), or fluorine doped tin oxide (FTO).

At block 1560, a metal layer may be formed on sidewalls of the pixel mesa structures as shown, for example, in FIG. 14F. Metal layer may include one or more metal or metal alloy materials, such as aluminum (Al), silver (Ag), gold (Au), platinum (Pt), titanium (Ti), copper (Cu), or any combination thereof. In one aspect, the first semiconductor material is n-doped and the metal layer acts as a high reflectivity mesa sidewall n-electrode. In another aspect, the first semiconductor material is p-doped and the metal layer acts as a high reflectivity mesa sidewall p-electrode.

In one implementation, a window may be formed, e.g., by etching, in the metal layer and layer of low index conductive material and a dielectric layer may be deposited on the micro-LEDs as shown, for example, in FIG. 14G. The dielectric layer may fill the gaps between individual micro-LEDs. A dielectric window may be opened (formed) in the dielectric layer and through the etch mask layer to contact metal layer. Metal plugs may be formed in the dielectric layer to form p-electrodes and bonding pads for the p-electrodes, and/or n-electrodes and bonding pads for the n-electrodes. The metal plugs may be bonded to a CMOS backplane.

In an alternate example, a layer of a material having a lower index of refraction than the low index conductive material or a DBR is formed on the layer of low index conductive material. This additional layer of material lies between the layer of low index conductive material and the metal layer. In this case, the metal layer may have a plug that passes through the additional layer of material to contact the layer of low index conductive material.

### Examples of Micro-LEDs with High Reflectivity Wide Bonding Pad Electrodes

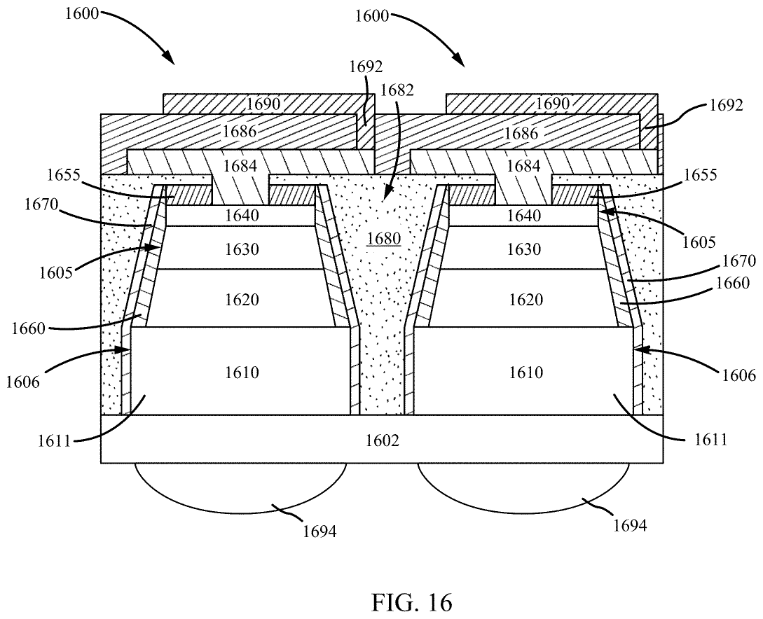

FIG. 16 is a cross-sectional view of an example of two micro-LEDs 1600 with high reflectivity wide bonding pad electrodes (e.g., p-electrodes), according to certain embodiments. The two micro-LEDs 1600 may be adjacent to each other in a micro-LED array or other LED device. Each micro-LED 1600 may be an example of a light emitter in, e.g., light source 510, 540, or 642. Each micro-LED 1600 includes a mesa structure 1605 with sidewalls 1606. Even though FIG. 16 shows conical mesa structures 1605 with a circular base area, the mesa structures may have another shape such as a conical, parabolic, semi-parabolic, inward-tilted, or outward-tilted mesa shape, and in addition or alternatively, the base area may have another shape such as rectangular, hexagonal, or triangular. According to one aspect, micro-LEDs with only high reflectivity wide bonding pad electrodes (e.g., micro-LEDs 1600 and 1700) have a flatter structure than the micro-LEDs with high reflectivity mesa sidewall electrodes (e.g., micro-LED 1100, 1200, and 1300).

In FIG. 16, each mesa structure 1605 includes an LED stack with a layer of a first semiconductor material 1610, an active layer 1620 formed on the layer of the first semiconductor material 1610, and a layer of a second semiconductor material 1630 formed on the active layer 1620. Layer of the first semiconductor material 1610 may be epitaxially grown on a substrate (not shown) with buffer layer 1602 disposed thereon. The substrate may be similar to, for example, substrate 710 or substrate 715. Layer of the first semiconductor material 1610 may include a III-V material, such as GaN, and may be p-doped (e.g., with Mg, Ca, Zn, or Be) or n-doped (e.g., with Si or Ge). In one example, the substrate may include a GaN substrate or a sapphire substrate with a buffer layer, and layer of the first semiconductor material 1610 may include a GaN layer n-doped with, for example, Si or Ge. In another example, the substrate may include a GaAs substrate. In one implementation, the layer of the first semiconductor material 1610 and the layer of a second semiconductor material 1630 may include the same base material with different doping. Each mesa structure 1605 also includes one or more epitaxial layers, such as, e.g., GaN barrier layers and InGaN quantum well layers, or AlGaInP barrier layers and GaInP quantum well layers, that may be grown on layer of the first semiconductor material 1610 to form an active layer 1620 that includes one or more quantum wells. Active layer 1620 may include multiple quantum well layers having lower bandgap materials that are sandwiched by barrier layers having higher bandgap materials (e.g., III-V materials) to form one or more quantum wells or MQWs. In one aspect, active layer may comprise a nitride, phosphide, or arsenide alloy. Layer of the second semiconductor material 1630 may include a III-V material, such as GaN, and may be p-doped (e.g., with Mg, Ca, Zn, or Be) or n-doped (e.g., with Si or Ge). One of layer of the first semiconductor material 1610 and layer of the second semiconductor material 1630 may be a p-type layer (e.g., a p-GaN layer) and the other one may be an n-type layer (e.g., n-GaN layer). For example, layer of the first semiconductor material 1610 may be an n-GaN layer and layer of the second semiconductor material 1630 may be a p-GaN layer. Layer of the first semiconductor material 1610 and layer of the second semiconductor material 1630 sandwich active layer 1620 to form a light emitting region.

In certain embodiments, each micro-LED includes one or more transparent conductive layers in contact with the layer of the second semiconductor material on the active layer of the mesa structure. The one or more transparent conductive layers may comprise a transparent conductive oxide material such as indium tin oxide (ITO). In some cases, the one or more transparent conductive layers includes a single layer of transparent conductive material. In other cases, the one or more transparent conductive layers include multiple layers. In one case, for example, the one or more transparent conductive layers comprise a first transparent conductive layer and a second transparent conductive layer. The first transparent conductive layer in contact with the layer of the second semiconductor material and the second transparent conductive layer in contact with the first transparent conductive layer. For example, in FIG. 16, each mesa structure 1605 also includes a first transparent conductive layer 1640 (e.g., a p-contact layer) formed on layer of the second semiconductor material 1630. First transparent conductive layer 1640 may include, for example, a layer of indium tin oxide (ITO) or another transparent conductive oxide (TCO). In this example, a mask layer 1655 (e.g., a patterned layer of SiNₓ) is formed on the top surface of first transparent conductive layer 1640 to be able to selectively etch the LED stack, for example, to able to form mesa structures of desired sizes and pitches. The mask layer 1655 may also be used as an etch stopping layer. In other examples, mesa structures 1605 may omit or remove mask layer 1655. In the illustrated example, dielectric material 1680 fills in the gaps between adjacent micro-LEDs 1600. Dielectric 1680 may include, for example, SiO₂ or SiNₓ. A dielectric window is formed in the dielectric material and through the mask 1655 to the first transparent conductive layer 1640. The dielectric window may provide a port hole for a light path from the active layer 1620. Although the dielectric window is shown centered about the centerline of the mesa 1605, the dielectric window may be offset in another implementation. Each micro-LED 1600 includes a second transparent conductive layer 1684 formed on the dielectric material 1680 and in the dielectric window to contact the first transparent conductive layer 1640. Second transparent conductive layer 1684 may include, for example, a layer of indium tin oxide (ITO) or another transparent conductive oxide (TCO). In the illustrated example, second transparent conductive layer 1684 may have a footprint wider than the footprint of the mesa structures 1605.

In the illustrated example, each micro-LED 1600 includes a dielectric layer 1660 (e.g., a layer of SiO₂) formed on sidewalls of layer of the second semiconductor material 1630, first transparent conductive layer 1640, and mask layer 1655. In other examples, dielectric layer 1660 may contact fewer layers of the stack. Dielectric layer 1660 may isolate first transparent conductive layer 1640 and other layers of the stack and may act as a passivation layer. In one aspect, the dielectric layer 1660 may include a material having a lower refractive index than the material of the layers in the active region of the LED stack to improve total internal reflection at the interfaces between the dielectric layer 1660 and the material layers in the active region.

In the illustrated example, each micro-LED 1600 also includes a metal layer 1670 formed on sidewalls of layer of the first semiconductor material 1610 and on dielectric layer 1660. Metal layer 1670 may act as an electrode (e.g., an n-electrode) in ohmic contact with layer of the first semiconductor material 1610. Layer of the first semiconductor material 1610 may be at least partially etched to provide a portion 1611 with a contact surface on which metal layer 1670 may be formed. Metal layer 1670 may include one or more metal or metal alloy materials, such as aluminum (Al), silver (Ag), gold (Au), platinum (Pt), titanium (Ti), copper (Cu), or any combination thereof. In an alternate implementation, layer 1670 may be a layer of another conductive material such as a conductive oxide material (e.g., ITO). Even though FIG. 16 shows metal layer 1670 extending along sidewalls of all layers of mesa structures 1605, in other examples, metal layer 1670 may extend along a portion of the sidewalls. For example, metal layer 1670 may extend along sidewalls of layer of the first semiconductor material 1610 and not extend or extend only a portion of sidewalls of other layers of mesa structures 1605. In the illustrated example, dielectric material 1680 may be coated on metal layer 1670 and between mesa structures 1605.

Each micro-LED 1600 includes a layer of a low refractive index material 1686 formed on second transparent conductive layer 1684 and formed on dielectric material 1680. Each micro-LED 1600 also includes another metal layer 1690 formed on layer of low refractive index material 1686. Layer of the low refractive index material 1686 lies between metal layer 1690 and second transparent conductive layer 1684. The low refractive index material may have an index of refraction lower than an index of refraction of one or more of the materials of the second transparent conductive layer 1684, the material or materials of the first transparent conductive layer 1640, and the second semiconductor material to increase constructive interference of light emitted by active layer 1620 of micro-LEDs 1600 to promote total internal reflection (TIR) and improve light extraction. In one example, the layer of low refractive index material 1686 includes SiO₂, which has an index of refraction of about 1.5 and the material of first transparent conductive layer and/or second transparent conductive layer is ITO having an index of refraction of about 2.0.

The metal layer 1690 of each micro-LED 1600 includes a metal plug 1692 formed in a window through layer of a low refractive index material 1686 to second transparent conductive layer 1684. The metal plug 1692 contacts an end portion of the second transparent conductive layer 1684 in a dead zone 1682 between mesa structures 1605. The dead zone 1682 may be outside the active light emitting region of the micro-LED 1600. Placement of the metal plug 1692 in the dead zone may reduce absorption of light by the metal plug 1692. The location of the metal plug 1692 in the dead zone 1682 may be particularly advantageous in micro-LEDs implementations where the area of a metal plug may take up a large portion (e.g., 25%) of the active area in a small pixel micro-LED such as a micro-LED having a pixel pitch of about 2 m. The metal layer 1690 may form a high reflectivity wide bonding pad electrode with a wide bonding pad for bonding to a contact pad of, for example, a CMOS backplane. An LED device with micro-LEDs 1600 having high reflectivity wide bonding pad electrodes may allow for relaxation of the alignment requirements during the bonding process with, for example, the CMOS backplane. In one aspect, the metal plug 1692 may be ring shaped and/or approximately centered around a center axis of each micro-LED 1600. In one example, an inner diameter of a ring-shaped metal plug 1692 may be larger than the diameter of the footprint of the micro-LED 1600. In other aspects, the metal plug 1692 may have another shape including, for example, multiple vias, pillars, linear segments, or arc segments. In one aspect, the second semiconductor material is n-doped and metal layer 1690 may act as a high reflectivity wide bonding pad n-electrode. In another aspect, the second semiconductor material is p-doped and metal layer 1690 acts as a high reflectivity wide bonding pad p-electrode. The metal layer 1690 for each micro-LED 1600 may have a size equal to, or larger than, the size of the mesa structure such as, for example, more than 10%, more than 20%, or more than 30% greater than the size of the mesa structure.

Each micro-LED 1600 also includes a lens 1694 on a light emission surface to focus and/or collimate the emitted light or couple the emitted light into a waveguide. Although a single lens is shown in the illustrated example, in other implementations additional optical elements may be included such as additional lenses, a grating, a waveguide, a prism, etc.

In one aspect, micro-LEDs in an LED device include a distributed Bragg reflector (DBR) structure between a metal layer acting as an electrode to the layer of second semiconductor material and the LED stack to promote TIR and improve light extraction. The DBR structure may include a plurality of layers such as low-index dielectric layers. In some cases, the DBR structure includes conductive materials of different refractive indices. The thicknesses and materials in the layers of a DBR structure may be selected to cause constructive interference between light reflected at the interfaces between the layers of the DBR for high reflectivity of a wavelength emitted from the active region of the micro-LEDs and/or to provide other optical properties. For example, the thicknesses and materials of the layers in a DBR structure may be selected for high reflectivity of a target wavelength emitted from the active layer. In some embodiments, the DBR can include conductive materials.

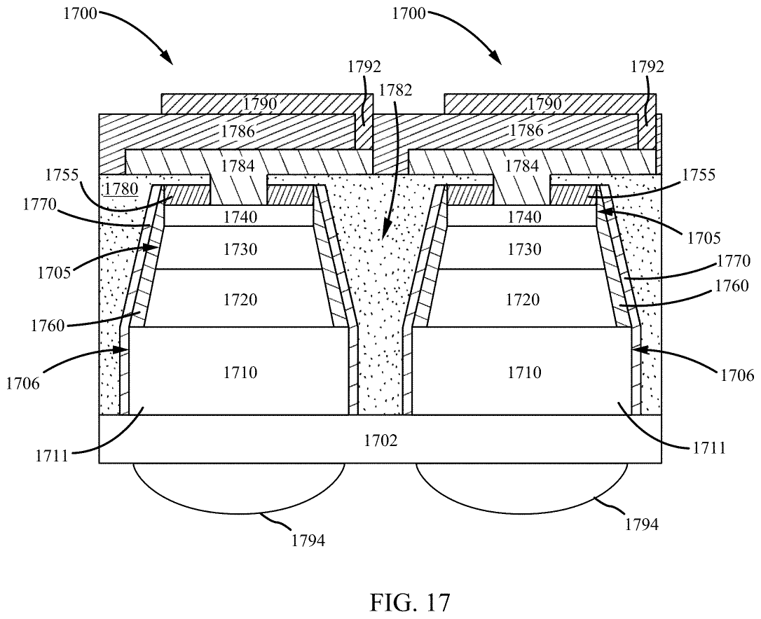

FIG. 17 is a cross-sectional view of an example of two micro-LEDs 1700 with high reflectivity wide bonding pad electrodes (e.g., p-electrodes), according to certain embodiments. The two micro-LEDs 1700 may be adjacent to each other in a micro-LED array or other LED device. Each micro-LED 1700 may be an example of a light emitter in, e.g., light source 510, 540, or 642. Each micro-LED 1700 includes a mesa structure 1705 with sidewalls 1706. Even though FIG. 17 shows conical mesa structures 1705 with a circular base area, the mesa structures may have another shape such as a conical, parabolic, semi-parabolic, inward-tilted, or outward-tilted mesa shape, and in addition or alternatively, the base area may have another shape such as rectangular, hexagonal, or triangular.

In FIG. 17, each mesa structure 1705 includes an LED stack with a layer of a first semiconductor material 1710, an active layer 1720 formed on the layer of the first semiconductor material 1710, and a layer of a second semiconductor material 1730 formed on the active layer 1720. Layer of the first semiconductor material 1710 may be epitaxially grown on a substrate (not shown) with buffer layer 1702 disposed thereon. The substrate may be similar to, for example, substrate 710 or substrate 715. Layer of the first semiconductor material 1710 may include a III-V material, such as GaN, and may be p-doped (e.g., with Mg, Ca, Zn, or Be) or n-doped (e.g., with Si or Ge). In one example, the substrate may include a GaN substrate or a sapphire substrate with a buffer layer, and layer of the first semiconductor material 1710 may include a GaN layer n-doped with, for example, Si or Ge. In another example, the substrate may include a GaAs substrate. In one implementation, the layer of the first semiconductor material 1710 and the layer of a second semiconductor material 1730 may include the same base material with different doping. Each mesa structure 1705 also includes one or more epitaxial layers, such as, e.g., GaN barrier layers and InGaN quantum well layers, or AlGaInP barrier layers and GaInP quantum well layers, that may be grown on layer of the first semiconductor material 1710 to form an active layer 1720 that includes one or more quantum wells. Active layer 1720 may include multiple quantum well layers having lower bandgap materials that are sandwiched by barrier layers having higher bandgap materials (e.g., III-V materials) to form one or more quantum wells or MQWs. In one aspect, active layer 1720 may comprise a nitride, phosphide, or arsenide alloy. Layer of the second semiconductor material 1730 may include a III-V material, such as GaN, and may be p-doped (e.g., with Mg, Ca, Zn, or Be) or n-doped (e.g., with Si or Ge). One of layer of the first semiconductor material 1710 and layer of the second semiconductor material 1730 may be a p-type layer (e.g., a p-GaN layer) and the other one may be an n-type layer (e.g., n-GaN layer). For example, layer of the first semiconductor material 1710 may be an n-GaN layer and layer of the second semiconductor material 1730 may be a p-GaN layer. Layer of the first semiconductor material 1710 and layer of the second semiconductor material 1730 sandwich active layer 1720 to form a light emitting region.

In certain embodiments, each micro-LED includes one or more transparent conductive layers in contact with the layer of the second semiconductor material on the active layer of the mesa structure. The one or more transparent conductive layers may comprise a transparent conductive oxide material such as indium tin oxide (ITO). In some cases, the one or more transparent conductive layers includes a single layer of transparent conductive material. In other cases, the one or more transparent conductive layers include multiple layers. In one case, for example, the one or more transparent conductive layer comprise a first transparent conductive layer and a second transparent conductive layer. The first transparent conductive layer in contact with the layer of the second semiconductor material and the second transparent conductive layer in contact with the first transparent conductive layer. For example, in FIG. 17, each mesa structure 1705 also includes a first transparent conductive layer 1740 (e.g., a p-contact layer) formed on layer of the second semiconductor material 1730. The first transparent conductive layer 1740 may include, for example, a layer of indium tin oxide (ITO) or another conductive oxide. In this example, a mask layer 1755 (e.g., a patterned layer of SiNₓ) is formed on the top surface of first transparent conductive layer 1740 to be able to selectively etch the LED stack, for example, to able to form mesa structures of desired sizes and pitches. The mask layer 1755 may also be used as an etch stopping layer. In other examples, mesa structures 1705 may omit or remove mask layer 1755. In the illustrated example, dielectric material 1780 fills in the gaps between adjacent micro-LEDs 1700. Dielectric 1780 may include, for example, SiO₂ or SiNₓ. A dielectric window is formed in the dielectric material and through the mask 1755 to the first transparent conductive layer 1740. The dielectric window may provide a port hole for a light path from the active layer 1720. Although the dielectric window is shown centered about the centerline of the mesa 1705, the dielectric window may be offset in another implementation. Each micro-LED 1700 includes a second transparent conductive layer 1784 formed on the dielectric material 1780 and in the dielectric window to contact the first transparent conductive layer 1740. Second transparent conductive layer 1784 may include, for example, a layer of indium tin oxide (ITO) or another transparent conductive oxide (TCO). In the illustrated example, second transparent conductive layer 1784 may have a footprint wider than the footprint of the mesa structures 1705.

In the illustrated example, each micro-LED 1700 includes a dielectric layer 1760 (e.g., a layer of SiO₂) formed on sidewalls of layer of the active layer 1720, second semiconductor material 1730, first transparent conductive layer 1740, and mask layer 1755. In other examples, dielectric layer 1760 may contact fewer layers of the stack. Dielectric layer 1760 may isolate first transparent conductive layer 1740 and other layers of the stack and may act as a passivation layer. In one aspect, the dielectric layer 1760 may include a material having a lower refractive index than the material of the layers in the active region of the LED stack to improve total internal reflection at the interfaces between the dielectric layer 1760 and the material layers in the active region.

In the illustrated example, each micro-LED 1700 also includes a metal layer 1770 formed on sidewalls of layer of the first semiconductor material 1710 and on dielectric layer 1760. Metal layer 1770 may act as an electrode (e.g., an n-electrode) in ohmic contact with layer of the first semiconductor material 1710. Layer of the first semiconductor material 1710 may be at least partially etched to provide a portion 1711 with a contact surface on which metal layer 1770 may be formed. Metal layer 1770 may include one or more metal or metal alloy materials, such as aluminum (Al), silver (Ag), gold (Au), platinum (Pt), titanium (Ti), copper (Cu), or any combination thereof. In an alternate implementation, layer 1770 may be a layer of another conductive material such as a conductive oxide material (e.g., ITO). Even though FIG. 17 shows metal layer 1770 extending along sidewalls of all layers of mesa structures 1705, in other examples, metal layer 1770 may extend along a portion of the sidewalls. For example, metal layer 1770 may extend along sidewalls of layer of the first semiconductor material 1710 and not extend or extend only a portion of sidewalls of other layers of mesa structures 1705. In the illustrated example, a dielectric material 1780 may be coated on metal layer 1770 and between mesa structures 1705.

Each micro-LED 1700 includes a layer of a distributed Bragg reflector (DBR) 1786 formed on second transparent conductive layer 1784 and formed on dielectric material 1780. Each micro-LED 1700 also includes another metal layer 1790 formed on the DBR 1786. DBR 1786 lies between metal layer 1790 and second transparent conductive layer 1784. The DBR 1786 may include a plurality of layers with materials and thicknesses designed for selectivity reflectivity of certain wavelengths emitted by the active region of the LED stack. In some cases, the DBR 1786 may include a layer of low refractive index material with an index of refraction lower than the index of refraction of the second transparent conductive layer 1784, the material of first transparent conductive layer 1740, and/or the second semiconductor material.

The metal layer 1790 of each micro-LED 1700 includes a metal plug 1792 formed in a window through layer of DBR 1786 to second transparent conductive layer 1784. The metal plug 1792 contacts an end portion of the second transparent conductive layer 1784 in a dead zone 1782 between mesa structures 1705. The dead zone may be outside the active light emitting region of the micro-LED 1700. Placement of the metal plug 1792 in the dead zone may reduce absorption of light by the metal plug 1792. The location of the metal plug 1792 in the dead zone 1782 may be particularly advantageous in micro-LEDs implementations where the area of a metal plug may take up a large portion (e.g., 25%) of the active area in a small pixel micro-LED such as a micro-LED having a pixel pitch of about 2 μm. The metal layer 1790 may form a high reflectivity wide bonding pad electrode with a wide bonding pad for bonding to a contact pad of, for example, a CMOS backplane. An LED device with micro-LEDs 1700 having high reflectivity wide bonding pad electrodes may allow for relaxation of the alignment requirements during the bonding process with, for example, the CMOS backplane. In one aspect, the metal plug 1792 may be ring shaped and/or approximately centered around a center axis of each micro-LED 1700. In one example, an inner diameter of a ring-shaped metal plug 1792 may be larger than the diameter of the footprint of the micro-LED 1700. In other aspects, the metal plug 1792 may have another shape that includes, for example, multiple vias, pillars, linear segments, or arc segments. In one aspect, the second semiconductor material is n-doped and metal layer 1790 may act as a high reflectivity wide bonding pad n-electrode. In another aspect, the second semiconductor material is p-doped and metal layer 1790 acts as a high reflectivity wide bonding pad p-electrode. The metal layer 1790 for each micro-LED 1700 may have a size equal to, or larger than, the size of the mesa structure such as, for example, more than 10%, more than 20%, or more than 30% greater than the size of the mesa structure.

Each micro-LED 1700 also includes a lens 1794 on a light emission surface to focus and/or collimate the emitted light or couple the emitted light into a waveguide. Although a single lens is shown in the illustrated example, in other implementations additional optical elements may be included such as additional lenses, a grating, a waveguide, a prism, etc.

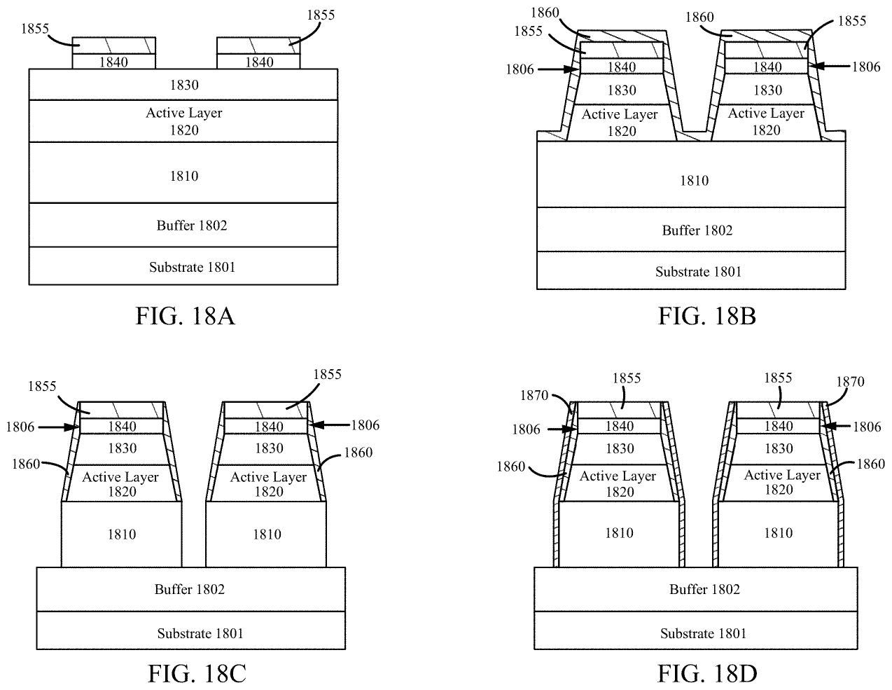

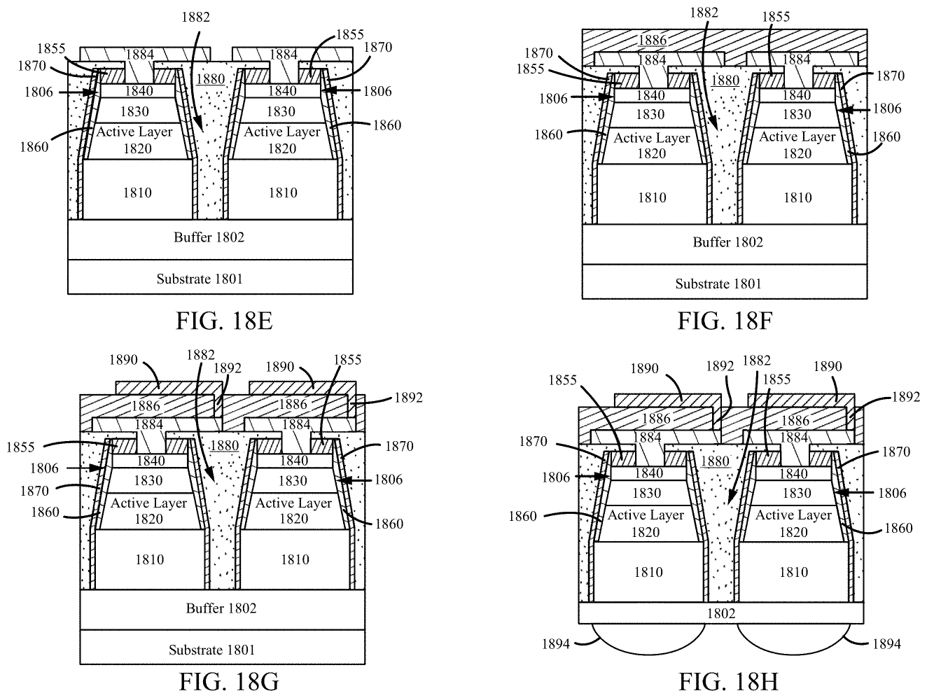

FIGS. 18A-18H illustrate an example of a method of fabricating micro-LEDs with high reflectivity wide bonding pad electrodes such as high reflectivity wide bonding pad p-electrodes, according to certain embodiments. The illustrated method may be used to fabricate the micro-LEDs 1600 and 1700 illustrated in FIGS. 16 and 17. The methods includes multiple mesa etching steps.

FIG. 18A depicts an LED layer stack including multiple epitaxial layers grown on a substrate 1801. Substrate 1801 may be a substantially planar substrate. Substrate 1801 may have an in-plane lattice constant that is close to the in-plane lattice constants of the epitaxial layers to be grown on the substrate, in order to reduce lattice mismatch. For example, substrate 1801 may be a sapphire substrate or a silicon substrate. In the illustrated example, a buffer layer 1802 is formed on substrate 1801 to, for example, provide a surface suitable for formation of a layer of a first semiconductor material 1810 (e.g., an n-GaN layer). Layer of first semiconductor material 1810 may be epitaxially grown on buffer layer 1802, using any suitable process such as an MOCVD process or an MBE process. The first semiconductor material may include a III-V material, such as GaN, and may be n-doped (e.g., with Si or Ge) or p-doped. In one example, layer of first semiconductor material 1810 may have an n-doping (e.g., Si or Ge doping) density of about 5×10¹⁸ cm⁻³.

Following formation of layer of first semiconductor material 1810, active layer 1820 may be epitaxially grown on layer of first semiconductor material 1810. The active layer 1820 may include multiple quantum well layers having lower bandgap materials that are sandwiched by barrier layers having higher bandgap materials (e.g., III-V materials) to form one or more quantum wells or MQWs. In one aspect, active layer may comprise a nitride, phosphide, or arsenide alloy.

Following formation of active layer 1820, a layer of a second semiconductor material 1830 (e.g., an p-GaN layer) may be epitaxially grown on active layer 1820. The second semiconductor material may include a III-V material, such as GaN, and may be p-doped or n-doped (e.g., with Si or Ge).

Following formation of layer of second semiconductor material 1830, one or more transparent conductive layers may be formed on the layer of second semiconductor material 1830. In the illustrated example, a first transparent conductive layer 1840 may be formed on the layer of second semiconductor material 1830.

The first transparent conductive layer 1840 (e.g., p-contact layer) may include a conductive oxide such as indium tin oxide (ITO), for example. An etch mask layer 1855 (e.g., SiNₓ) may be formed on the first transparent conductive layer 1840. In one aspect, a photoresist layer is also included and used to pattern the etch mask layer 1855. FIG. 18A shows that etch mask layer 1855 may be patterned using a lithography process to form an etch mask. Etch mask layer 1855 can be used to etch precursor mesa structures and/or pixel mesa structures for individual micro-LEDs. In addition, first transparent conductive layer 1840 may be patterned or etched using etch mask layer 1855.

FIG. 18B depicts a first mesa etching process that uses the patterned etch mask 1855 to etch through layer of second semiconductor material 1830 and the active layer 1820 to form precursor mesa structures of individual micro-LEDs. Each of these precursor mesa structures includes an active layer 1820, a layer of second semiconductor material 1830 (e.g., p-GaN), a first transparent conductive layer 1840 of (e.g., a first layer of ITO or other conductive oxide layer), and a patterned etch mask 1855. Although the depicted method in FIGS. 18A-H are described with reference to two mesa structures, additional mesa structures may be formed by this method such as, e.g., 4, 6, 8, 9, or more mesa structures may be formed. In one aspect, the first transparent conductive layer 1840 may have a lower index of refraction than the second semiconductor material.

A dielectric layer may be formed on sidewalls of one or more layers of the precursor mesa structures to, for example, electrically isolate these layers at their sidewalls and may act as a passivation layer. FIG. 18B depicts that a dielectric layer 1860 may be conformally deposited on surfaces including sidewalls of the precursor mesa structures and in regions between the precursor mesa structures. Dielectric layer 1860 may be, for example, a layer of SiO₂. Dielectric layer 1860 may have any desired thickness. In one aspect, the dielectric layer 1860 may have a thickness greater than about 50 nm and lower than about 500 nm in a surface normal direction of the mesa sidewall surfaces.

FIG. 18C depicts that a self-aligned second mesa etching processes may be performed using patterned etch mask 1855. The self-aligned second mesa etching process may vertically etch through dielectric layer 1860 and at least a portion of the layer of the first semiconductor material 1810 to form pixel mesa structures of individual micro-LEDs. In the illustrated example, the self-aligned second mesa etching process may vertically etch through, or substantially through, the layer of the first semiconductor material 1810. In the illustrated example, each pixel mesa structure includes a layer of a first semiconductor material 1810 (e.g., n-GaN layer), active layer 1820, layer of second semiconductor material 1830 (e.g., p-GaN layer), first transparent conductive layer (e.g., p-contact layer) 1840, and etch mask layer 1855. After the self-aligned second mesa etching process, dielectric layer 1860 remains on sidewalls of active layer 1820, layer of second semiconductor material 1830, first transparent conductive layer 1840, and etch mask layer 1855. In another implementation, after the self-aligned second mesa etching process, etch mask layer 1855 may be removed.

FIG. 18D depicts that metal layer 1870 may be deposited on sidewalls 1806 of the pixel mesa structures shown in FIG. 18D and a window may be formed in metal layer 1870, for example, by an etching operation. The metal layer 1870 may act as a contact layer in contact with the layer of first semiconductor material 1810. Metal layer 1870 may include one or more metal or metal alloy materials, such as aluminum (Al), silver (Ag), gold (Au), platinum (Pt), titanium (Ti), copper (Cu), or any combination thereof. Although the illustrated example shows metal layer 1870 deposited along the length of the sidewalls 1806 of the pixel mesa structures, in other examples layer of metal layer 1870 may extend along only sidewalls of layer of the first semiconductor material 1810 and not extend or only extend a portion of the length of the sidewalls of other layers of the individual pixel mesa structures. In one aspect, metal layer 1870 may be formed on sidewalls of at least the layer the first semiconductor material of the individual pixel mesa structures.

FIG. 18E depicts that a dielectric material 1880 may be formed on the pixel mesa structures shown in FIG. 18D. The dielectric material 1880 may then be planarized. Dielectric material 1880 may include, for example, an oxide such as SiO₂. Dielectric material 1880 may fill the gaps between individual micro-LEDs. A dielectric window may be opened (formed) in dielectric material 1880 and through the etch mask layer 1855 to first transparent conductive layer 1840. The dielectric window may provide a port hole for a light path from the active layer 1820. Although the dielectric window is shown centered about the centerline of the mesa, the dielectric window may be offset in another implementation. A second transparent conductive layer 1884 (e.g., a second layer of ITO or other conductive oxide material layer) is formed on a portion of the planarized surface of the dielectric material 1880 on each pixel mesa structure and through the dielectric window to contact the first transparent conductive layer 1840.

FIG. 18F depicts that a layer of low index material or a DBR 1886 may be formed on second transparent conductive layer 1884 and dielectric material 1880. The low index material may have a lower refractive index than the second semiconductor material. In one aspect, the low index material is SiO₂. In one example, low index conductive material may include SiO₂ having an index of refraction ˜1.5 and second semiconductor material may be a GaN layer that is p-doped and has an index of refraction of ˜2.5.

FIG. 18G depicts that a window may be formed in the layer of low index material or DBR 1886 and a metal material 1890 may be deposited over the layer of low index material or DBR 1886 and through the window forming a metal plug 1892 in contact with second transparent conductive layer 1884. In one aspect, the metal plug 1892 may be formed to contact an end portion of the second transparent conductive layer 1884 in a dead zone 1882 between pixel mesa structures. If the second semiconductor material is p-doped, the metal material 1890 may form high reflectivity wide bonding pad p-electrodes. If the second semiconductor material is n-doped, the metal material 1890 may form high reflectivity wide bonding pad n-electrodes.

In certain implementations, the metal plug of the metal layer may have a shape that is formed partially or entirely outside the perimeter of the pixel mesa structure. For example, there may be a separation distance (e.g., greater than 1 μm, greater than 2 μm, greater than 3 μm, etc.), as measured from a top view of the micro-LEDs, between an inner portion of the metal plug and the outer perimeter of the pixel mesa structure. In one aspect, the metal plug may be ring-shaped. For example, the metal plug may be ring shaped and centered around a central axis of the pixel mesa structure. In other aspects, the metal plug may have another shape that includes, for example, multiple vias, pillars, linear segments, or arc segments. For example, the metal plug may be polygon-shaped such as rectangular-shaped or hexagonal-shaped. The metal material for each micro-LED may have a size (e.g., outer perimeter) equal to, or larger than, the size (e.g., outer perimeter) of the mesa structure such as, for example, more than 10%, more than 20%, or more than 30% greater than the size of the mesa structure.

FIG. 18H depicts that the substrate 1801 may be removed (or thinned) and the buffer layer 1802 may be thinned, and lenses 1894 are formed on the backside. In one implementation, the metal material 1890 forms pads that may be bonded to a CMOS backplane.

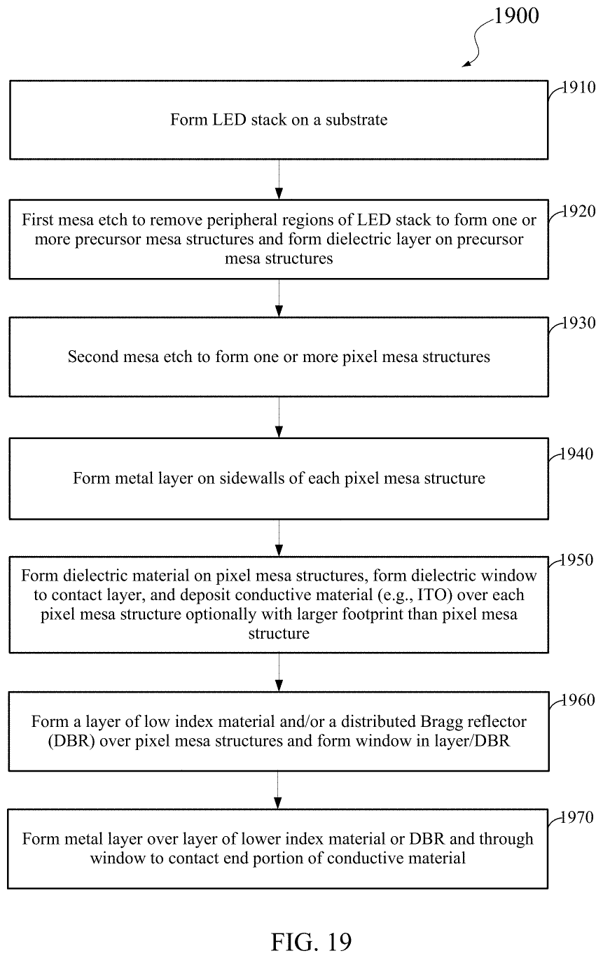

FIG. 19 includes a flowchart 1900 illustrating operations in an example of a method of fabricating an LED device having one or more LEDs (e.g., micro-LEDs), each having a high reflectivity wide bonding pad electrode (e.g., an n-electrode), according to certain embodiments. Although FIG. 19 illustrates particular example operations for fabricating the LED device, other sequences of operations can also be performed according to alternative embodiments. For example, alternative embodiments may perform the operations in a different order. Moreover, the illustrated operations may include multiple sub-operations that can be performed in various sequences as appropriate for the individual operation. Furthermore, some operations can be added or removed depending on the particular applications. In some implementations, two or more operations may be performed in parallel. One of ordinary skill in the art would recognize many variations, modifications, and alternatives.

In certain embodiments, each micro-LED includes one or more transparent conductive layers formed on the layer of the second semiconductor material of the mesa structure. In one aspect, at least one of the one or more transparent conductive layers is part of the mesa structure. The one or more transparent conductive layers may comprise a transparent conductive oxide material such as indium tin oxide (ITO). In one implementation, the one or more transparent conductive layers comprise a first transparent conductive layer and a second transparent conductive layer. In another implementation, a single transparent conductive layer is formed on the layer of the second semiconductor material of the mesa structure.

Returning to FIG. 19, operations in block 1910 include forming an LED layer stack (sometimes referred to herein as “LED stack”) including multiple epitaxial layers grown on a substrate. The substrate may have a buffer layer disposed thereon. As described above with respect to, for example, FIG. 18A, in some embodiments, forming the LED layer stack on the substrate may include growing an epitaxial layer stack on the substrate. The epitaxial layer stack may be etched using a patterned etch mask to form the plurality of precursor mesa structures. For example, each LED stack may include a layer of a first semiconductor material (e.g., n-GaN), an active layer, a layer of a second semiconductor material (e.g., p-GaN), a first transparent conductive layer (e.g., ITO), and a patterned etch mask. The first semiconductor material may include a III-V material, such as GaN, and may be n-doped (e.g., with Si or Ge) or p-doped. The first transparent conductive layer (e.g., p-contact layer) may include a conductive oxide such as indium tin oxide (ITO) or a metal film such as, e.g., a Ag/Pt/Au film or a Al/Ni/Au film. The active layer may include multiple quantum well layers having lower bandgap materials that are sandwiched by barrier layers having higher bandgap materials (e.g., III-V materials) to form one or more quantum wells or MQWs. Any suitable number of precursor mesa structures may be formed such as, for example, 2, 4, 6, 8, 9, or more mesas may be formed. In one aspect, active layer may comprise a nitride, phosphide, or arsenide alloy.

At block 1920, a first mesa etch is performed using a patterned mask to remove peripheral regions of the LED layer stack to form one or more precursor mesa structures, for example, as shown in FIG. 18B. In some embodiments, the etching may form multiple precursor mesa structures, such as 2, 4, 6, 8, 9, or more precursor mesa structures. In one example, the first mesa etching operation may etch through the first transparent conductive layer, the active layer, and the layer of the second semiconductor material. Also, at block 1920, a dielectric layer is conformally deposited on surfaces of the precursor mesa structures and in regions between the precursor mesa structures as. The dielectric layer may electrically isolate the first transparent conductive layer and may act as a passivation layer at the sidewalls of the active layer. The dielectric layer may be on at least a portion of the sidewalls of the layer of the active layer and second semiconductor material. The dielectric layer may include, for example, SiO₂ or Si₃N₄.

At block 1930, a second mesa etch is performed using a patterned mask to vertically etch through at least a portion of the layer of the first semiconductor material to form individual pixel mesa structures of, for example, individual micro-LEDs as shown in, for example, FIG. 18C. Each pixel mesa structure includes at least the layer of first semiconductor material (e.g., n-GaN layer), the active layer, the layer of second semiconductor material (e.g., p-GaN layer), and a first transparent conductive layer (e.g., p-contact layer). In one example, the pixel mesa structure formed at block 1930 includes the layer of first semiconductor material (e.g., n-GaN layer), the active layer, the layer of second semiconductor material (e.g., p-GaN layer), a first transparent conductive layer (e.g., p-contact layer), and a mask layer. In another example, the mask layer is removed. The second mesa etch process also etches a portion of the dielectric layer leaving the dielectric layer on sidewalls of the pixel mesa structures in contact with at least the layer of the active layer and second semiconductor material. In one example, after the second mesa etching process, etch mask layer may be removed.

At block 1940, a metal layer may be deposited on sidewalls of the pixel mesa structures, for example, as shown in FIG. 18D. Metal layer may include one or more metal or metal alloy materials, such as aluminum (Al), silver (Ag), gold (Au), platinum (Pt), titanium (Ti), copper (Cu), or any combination thereof. The metal layer may be in direct contact with a layer of first semiconductor material of the LED stack or may be in contact with a conductive material that is in contact with the layer of first semiconductor material.

At block 1950, a dielectric material is formed on the pixel mesa structures and fill in the gaps between pixel mesa structures, for example, as shown in FIG. 18E. The dielectric material may then be planarized. Dielectric material may include, for example, an oxide such as SiO₂. A dielectric window may be opened (formed) in the dielectric material to a first transparent conductive layer in contact with the layer of second semiconductor material. The first transparent conductive layer may be, for example, a first ITO layer or other conductive oxide layer. Also, at block 1950, a second transparent layer such as, e.g., a second ITO layer, is formed on a portion of the surface of the dielectric material on each pixel mesa structure and through the dielectric window to contact the first transparent conductive layer. The second transparent conductive layer may be formed to have a larger footprint than the pixel mesa structure so that an edge portion is in a dead zone between adjacent pixel mesa structures.

At block 1960, a layer of low index material and/or a DBR is formed over the pixel mesa structures and on the second transparent conductive layer with the larger footprint than the pixel mesa structures, for example, as shown in FIG. 18F. In one example, the low index material may include SiO₂. A window may be formed in the layer/DBR to the second transparent conductive layer.

At block 1970, a metal layer is deposited on the layer of low index material and/or a DBR and through the window to contact the second transparent conductive layer, for example, as shown in FIG. 18G. A metal plug may be formed in the window through the layer of low index material and/or a DBR. The metal layer may include one or more metal or metal alloy materials, such as aluminum (Al), silver (Ag), gold (Au), platinum (Pt), titanium (Ti), copper (Cu), or any combination thereof. In this example, the high reflectivity wide bonding pad electrode includes the metal layer. In one implementation, the metal layer forms pads that may be bonded to a CMOS backplane. In one implementation, the substrate may be removed and lenses formed on the backside as shown, for example, in FIG. 18H.

In certain implementations, the metal layer includes a metal plug passing through the layer of low index material and/or a DBR. According to one aspect, the metal plug is formed to contact an end portion of the second transparent conductive layer having a larger footprint than the pixel mesa structure such that the metal plug may be located in a dead zone between micro-LEDs. In one example, the metal layer is ring-shaped. In another example, the metal plug is ring shaped and centered around a central axis of the pixel mesa structure. In other aspects, the metal plug 1692 may have another shape including, for example, multiple vias, pillars, linear segments, or arc segments. In one example, the metal plug may be polygon shaped such as rectangular, hexagonal. The metal layer for each micro-LED may have a size equal to, or larger than, the size of the mesa structure such as, for example, more than 10%, more than 20%, or more than 30% greater than the size of the mesa structure.

### Examples of Micro-LEDs with High Reflectivity Mesa Sidewall Electrode and Wide Bonding Pad Electrode

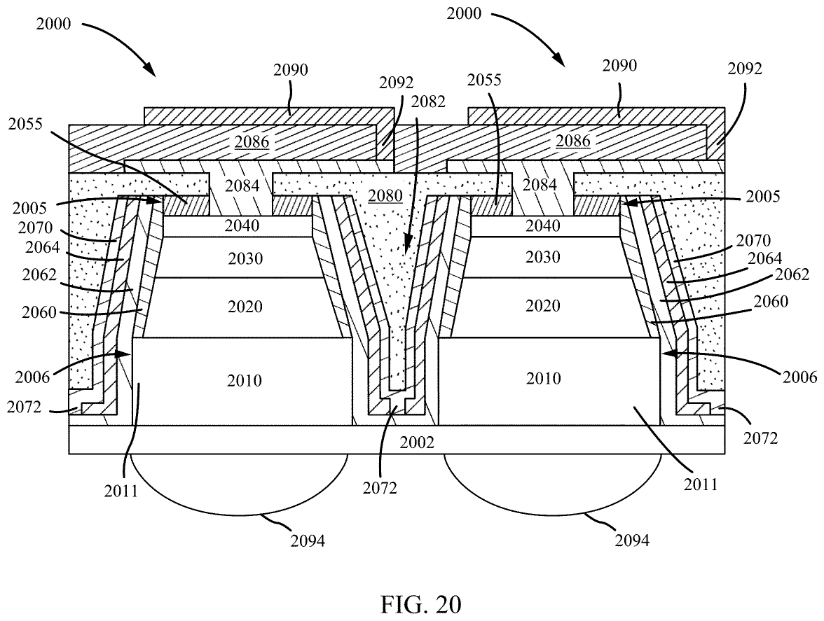

FIG. 20 is a cross-sectional view of another example of two micro-LEDs 2000 with high reflectivity mesa sidewall electrodes and high reflectivity wide bonding pad electrodes, according to certain embodiments. The two micro-LEDs 2000 may be adjacent to each other in a micro-LED array or other LED device and may be an example of a light emitter in, e.g., light source 510, 540, or 642. Each micro-LED 2000 includes a mesa structure 2005 with sidewalls 2006. Although FIG. 20 shows conical mesa structures 2005 with a circular base, the micro-LEDs 2000 may have mesa structures of other shapes and the base area may be circular, rectangular, hexagonal, or triangular.

In FIG. 20, each mesa structure 2005 has an LED stack that includes a layer of the first semiconductor material 2010, an active layer 2020 formed on the layer of the first semiconductor material 2010 and a layer of a second semiconductor material 2030 formed on the active layer 2020. Layer of the first semiconductor material 2010 may be epitaxially grown on a substrate (not shown) with a buffer layer 2002 disposed thereon. The substrate may be similar to, for example, substrate 710 or substrate 715. Layer of the first semiconductor material 2010 may include a III-V material, such as GaN, and may be p-doped (e.g., with Mg, Ca, Zn, or Be) or n-doped (e.g., with Si or Ge). In one example, the substrate may include a GaN substrate or a sapphire substrate with a buffer layer, and layer of the first semiconductor material 2010 may include a GaN layer n-doped with, for example, Si or Ge. In another example, the substrate may include a GaAs substrate. In one implementation, the layer of the first semiconductor material 2010 and the layer of a second semiconductor material 2030 may include the same base material with different doping. Each mesa structure 2005 also includes one or more epitaxial layers, such as, e.g., GaN barrier layers and InGaN quantum well layers, or AlGaInP barrier layers and GaInP quantum well layers, that may be grown on layer of the first semiconductor material 2010 to form an active layer 2020 that includes one or more quantum wells. Active layer 2020 may include multiple quantum well layers having lower bandgap materials that are sandwiched by barrier layers having higher bandgap materials (e.g., III-V materials) to form one or more quantum wells or MQWs. In one aspect, active layer 2020 may comprise a nitride, phosphide, or arsenide alloy. Layer of the second semiconductor material 2030 may include a III-V material, such as GaN, and may be p-doped (e.g., with Mg, Ca, Zn, or Be) or n-doped (e.g., with Si or Ge). One of layer of the first semiconductor material 2010 and layer of the second semiconductor material 2030 may be a p-type layer (e.g., a p-GaN layer) and the other one may be an n-type layer (e.g., n-GaN layer). For example, layer of the first semiconductor material 2010 may be an n-GaN layer and layer of the second semiconductor material 2030 may be a p-GaN layer. Layer of the first semiconductor material 2010 and layer of the second semiconductor material 2030 sandwich active layer 2020 and may form a light emitting region.

In certain embodiments, each micro-LED includes one or more transparent conductive layers in contact with the layer of the second semiconductor material on the active layer of the mesa structure. The one or more transparent conductive layers may comprise a transparent conductive oxide material such as indium tin oxide (ITO). In some cases, the one or more transparent conductive layers includes a single layer of transparent conductive material. In other cases, the one or more transparent conductive layers include multiple layers. In one case, for example, the one or more transparent conductive layers comprise a first transparent conductive layer and a second transparent conductive layer. The first transparent conductive layer in contact with the layer of the second semiconductor material and the second transparent conductive layer in contact with the first transparent conductive layer. For example, in FIG. 20 each mesa structure 2005 also includes a first transparent conductive layer 2040 (e.g., a p-contact layer) disposed on layer of the second semiconductor material 2030. First transparent conductive layer 2040 may be, for example, a layer of indium tin oxide (ITO), another transparent conductive oxide, or an Al/Ni/Au film. In this example, a mask layer 2055 (e.g., a layer of SiNₓ) is formed on the top surface of first transparent conductive layer 2040 to be able to selectively etch a stack of layers including active layer 2020, layer of the second semiconductor material 2030, and contact layer 2040 to form mesa structures 2005 of desired sizes and pitches. In other examples, mesa structures 2005 may omit or have removed mask layer 2055. In the illustrated example, dielectric material 2080 fills in the gaps between adjacent micro-LEDs 2000. Dielectric 2080 may include, for example, SiO₂ or SiNₓ. A dielectric window is formed in the dielectric material and through the mask 2055 to the first transparent conductive layer 2040. The dielectric window may provide a port hole for a light path from the active layer 2020. Although the dielectric window is shown centered about the centerline of the mesa 2005, the dielectric window may be offset in another implementation. Each micro-LED 2000 includes a second transparent conductive layer 2084 formed on the dielectric material 2080 and in the dielectric window to contact the first transparent conductive layer 2040. Second transparent conductive layer 2084 may include, for example, a layer of indium tin oxide (ITO) or another transparent conductive oxide (TCO). In the illustrated example, second transparent conductive layer 2084 may have a footprint wider than the footprint of the mesa structures 2005.

In the illustrated example, each micro-LED 2000 includes a dielectric layer 2060 that may include, for example, SiO₂ or SiNₓ. Dielectric layer 2060 is formed on sidewalls of active layer 2020, layer of the second semiconductor material 2030, first transparent conductive layer 2040, and mask layer 2055 of mesa structures 2005. In other examples, dielectric layer 2060 may be disposed on sidewalls of fewer layers. Dielectric layer 2060 may also isolate first transparent conductive layer 2040 and other layers of the stack and may act as a passivation layer. Dielectric layer 2060 may have a lower refractive index than active layer 2020 to reflect emitted light.

Micro-LEDs 2000 also include a layer of low index conductive material 2062 formed on at least the sidewalls of the layer of the first semiconductor material 2010. The layer of low index conductive material 2062 may help reduce resistance to the layer of first semiconductor material 2010. In the illustrated example, low index conductive material layer 2062 is also disposed on dielectric layer 2060. Layer of the first semiconductor material 2010 may be at least partially etched to provide a portion 2011 with a contact surface on which layer of low index conductive material 2062 may be formed. Layer of low index conductive material 2062 has a lower refractive index than layer of the first semiconductor material 2010 to increase constructive interference of light emitted by active layer 2020 of micro-LEDs 2000 to promote total internal reflection (TIR) and improve light extraction.

Micro-LEDs 2000 also include a layer of low index material 2064 such as, for example, dielectric material, formed on layer of low index conductive material 2062. Layer of low index material 2064 may have a lower refractive index than low index conductive material 2062 to further increase constructive interference of light emitted by active layer 2020 of micro-LEDs 2000 to promote total internal reflection (TIR) and improve light extraction.

Micro-LEDs 2000 also include a metal layer 2070 formed on layer of low index material 2064. Metal layer 2070 may include one or more metal or metal alloy materials, such as aluminum (Al), silver (Ag), gold (Au), platinum (Pt), titanium (Ti), copper (Cu), or any combination thereof. Layer of low index material 2064 lies between layer of low index conductive material layer 2062 and metal layer 2070. Metal layer 2070 includes metal plugs 2072 formed through the layer of low index material 2064 and in contact with, and/or partially passing through, the layer of low index conductive material 2062. Metal plugs 2072 may be located in a dead zone 2082 in a region between mesa structures 2005 where the quantum well layers have been etched. The location of metal plugs 2072 in the dead zone may help avoid absorption of light emitted by active layer 2020 by the metal plugs 2072. In one aspect, the second semiconductor material is n-doped and metal layer 2090 may act as a high reflectivity wide bonding pad n-electrode. In another aspect, the second semiconductor material is p-doped and metal layer 2090 acts as a high reflectivity wide bonding pad p-electrode. The metal layer 2090 for each micro-LED 2000 may have a size equal to, or larger than, the size of the mesa structure such as, for example, more than 10%, more than 20%, or more than 30% greater than the size of the mesa structure. A dielectric material 2080 may be coated on micro-LEDs 2000 and between mesa structures 2005.

Each micro-LED 2000 includes a layer of DBR and/or a low refractive index material 2086 formed on second transparent conductive layer 2084 and formed on dielectric material 2080. Each micro-LED 2000 also includes another metal layer 2090 formed on layer of DBR and/or low refractive index material 2086. Layer of DBR and/or low refractive index material 2086 lies between metal layer 2090 and second transparent conductive layer 2084. The DBR and/or low refractive index material may have an index of refraction lower than an index of refraction of one or more of the materials of the second transparent conductive layer 2084, the material of first transparent conductive layer 2040, and second semiconductor material to increase constructive interference of light emitted by active layer 2020 of micro-LEDs 2000 to promote total internal reflection (TIR) and improve light extraction. In one example, the layer of DBR and/or low refractive index material 2086 includes SiO₂, which has an index of refraction of about 1.5 and the material of the conductive layer is ITO having an index of refraction of about 2.0.

The metal layer 2090 of each micro-LED 2000 includes a metal plug 2092 formed in a window through layer of DBR and/or low refractive index material 2086 to second transparent conductive layer 2084. The metal plug 2092 contacts an end portion of the second transparent conductive layer 2084 in a dead zone 2082 between mesa structures 2005. The dead zone may be outside the active light emitting region of the micro-LED 2000. Placement of the metal plug 2092 in the dead zone may reduce absorption of light by the metal plug 2092. The location of the metal plug 2092 in the dead zone 2082 may be particularly advantageous in micro-LEDs implementations where the area of a metal plug may take up a large portion (e.g., 25%) of the active area in a small pixel micro-LED such as a micro-LED having a pixel pitch of about 2 m. The metal layer 2090 may form an electrode and bonding pads for electrodes to, for example, a CMOS backplane. In one aspect, the metal plug 2092 may be ring shaped and/or approximately centered around a center axis of each micro-LED 2000. In one example, an inner diameter of a ring-shaped metal plug 2092 may be larger than the diameter of the footprint of the micro-LED 2000. In other aspects, the metal plug 2092 may have another shape including, for example, multiple vias, pillars, linear segments, or arc segments. In one aspect, the second semiconductor material is n-doped and metal layer 2090 may act as a high reflectivity wide bonding pad n-electrode. In another aspect, the second semiconductor material is p-doped and metal layer 2090 acts as a high reflectivity wide bonding pad p-electrode.

Each micro-LED 2000 also includes a lens 2094 on a light emission surface to focus and/or collimate the emitted light or couple the emitted light into a waveguide. Although a single lens is shown in the illustrated example, in other implementations additional optical elements may be included such as additional lenses, a grating, a waveguide, a prism, etc.

Even though FIG. 20 shows layer of low index conductive material 2062, metal layer 2070, and layer of low index material 2064 extending along sidewalls of all illustrated layers of mesa structures 2005, in other examples, one or more of these layers may extend along a portion of the sidewalls. For example, one or more of these layers may extend along sidewalls of layer of the first semiconductor material 2010 and not extend or extend only a portion of sidewalls of other layers of mesa structures 2005. In one aspect, the first semiconductor material is n-doped and metal layer 2070 acts as a high reflectivity mesa sidewall n-electrode. In another aspect, the first semiconductor material is p-doped and metal layer 2070 acts as a high reflectivity mesa sidewall p-electrode.

In FIG. 20, micro-LEDs 2000 include a layer of low refractive index material 2064 between a layer of low index conductive material 2062 and a metal layer 2070. In another implementation, the layer of low refractive index material 2064 may be omitted.

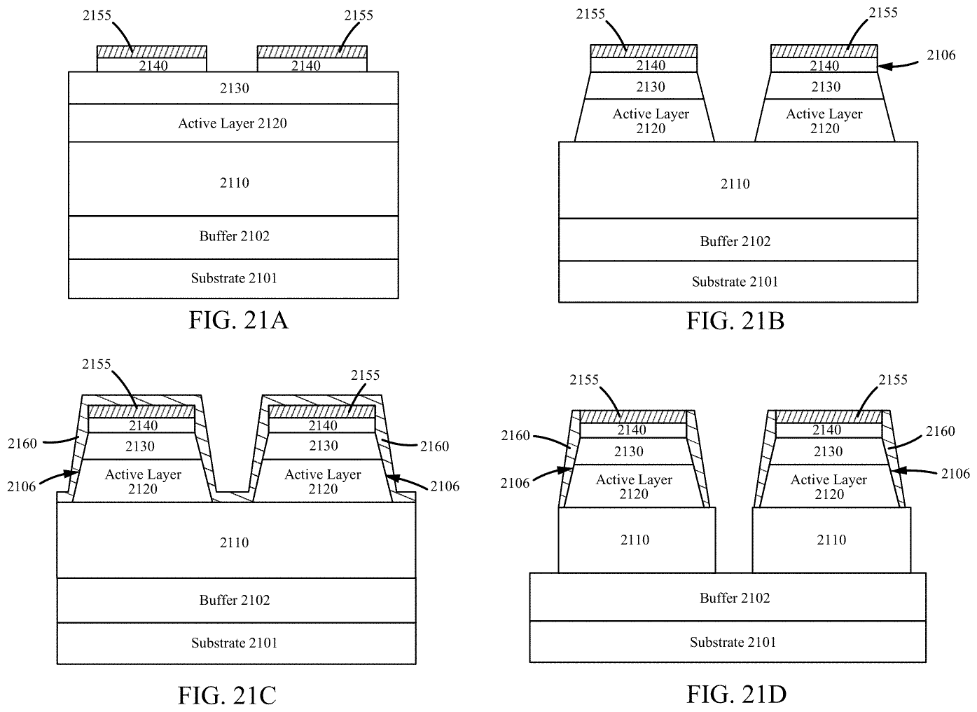

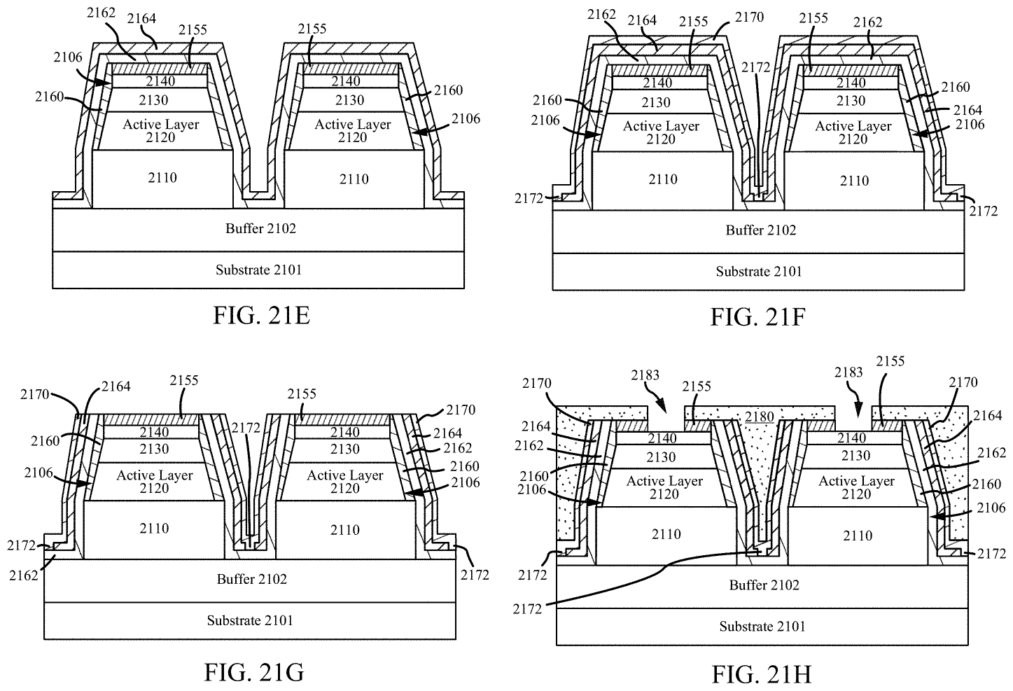

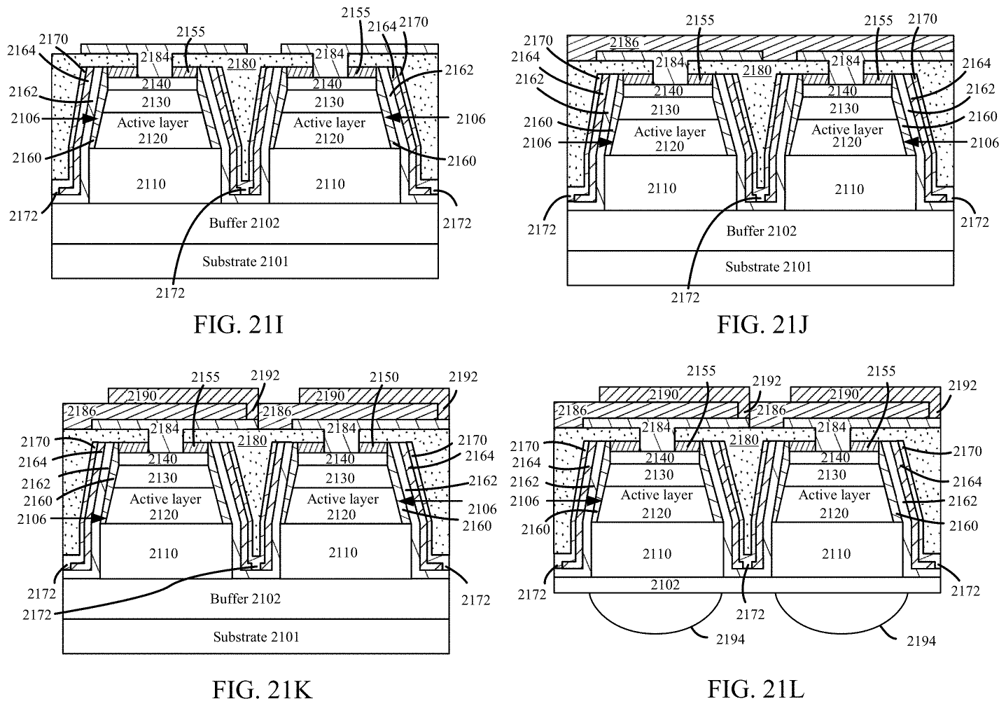

FIGS. 21A-21L illustrate an example of a method of fabricating micro-LEDs with high reflectivity mesa sidewall electrodes and high reflectivity wide bonding pad electrodes, according to certain embodiments. The illustrated method may be used to fabricate the micro-LEDs 2000 illustrated in FIG. 20. The illustrated method includes multiple mesa etching steps.

FIG. 21A depicts an LED layer stack including multiple epitaxial layers grown on a substrate 2101. Substrate 2101 may be a substantially planar substrate. Substrate 2101 may have an in-plane lattice constant that is close to the in-plane lattice constants of the epitaxial layers to be grown on the substrate, in order to reduce lattice mismatch. For example, substrate 2101 may be a sapphire substrate or a silicon substrate. In the illustrated example, a buffer layer 2102 is formed on substrate 2101 to, for example, provide a surface suitable for formation of a layer of a first semiconductor material 2110 (e.g., an n-GaN layer). Layer of first semiconductor material 2110 may be epitaxially grown on buffer layer 2102, using any suitable process such as an MOCVD process or an MBE process. The first semiconductor material may include a III-V material, such as GaN, and may be n-doped (e.g., with Si or Ge) or p-doped. In one example, layer of first semiconductor material 2110 may have an n-doping (e.g., Si or Ge doping) density of about 5×10¹⁸ cm⁻³.

Following formation of layer of first semiconductor material 2110, active layer 2120 may be epitaxially grown on layer of first semiconductor material 2110. The active layer 2120 may include III-V materials, such as one or more InGaN layers, one or more AlInGaP layers, and/or one or more GaN layers, which may form one or more heterostructures, such as one or more quantum wells or MQWs. In one aspect, active layer 2120 may comprise a nitride, phosphide, or arsenide alloy.

Following formation of active layer 2120, a layer of a second semiconductor material 2130 (e.g., an p-GaN layer) may be epitaxially grown on active layer 2120. The second semiconductor material may include a III-V material, such as GaN, and may be p-doped or n-doped (e.g., with Si or Ge).

Following formation of layer of second semiconductor material 2130, one or more transparent conductive layers may be formed on the layer of second semiconductor material 2130. In the illustrated example, a first transparent conductive layer 2140 may be formed on the layer of second semiconductor material 2130. First transparent conductive layer 2140 may be formed on the layer of second semiconductor material 2130. The first transparent conductive layer 2140 (e.g., p-contact layer) may include a conductive oxide such as indium tin oxide (ITO), for example. An etch mask layer 2155 (e.g., SiNₓ) may be formed on the first transparent conductive layer 2140. In one aspect, a photoresist layer is also included and used to pattern etch mask layer 2155. In one example, etch mask layer 2155 may be patterned using a lithography process. Etch mask layer 2155 can be used to etch precursor mesa structures and/or pixel mesa structures of individual micro-LEDs. In addition, first transparent conductive layer 2140 may be patterned or etched using etch mask layer 2155.

FIG. 21B depicts a first mesa etching process that uses the patterned etch mask 2155 to etch through layer of second semiconductor material 2130 and the active layer 2120 to form precursor mesa structures of individual micro-LEDs. Each of these precursor mesa structures includes a stack of an active layer 2120, a layer of second semiconductor material 2130 (e.g., p-GaN), a first transparent conductive layer 2140 of (e.g., a first layer of ITO or other conductive oxide layer), and a patterned etch mask 2155. Although the depicted method in FIGS. 21A-L are described with reference to two mesa structures, additional mesa structures may be formed by this method such as, e.g., 4, 6, 8, 9, or more mesa structures may be formed. In one aspect, the contact layer 2140 may have a lower index of refraction than the second semiconductor material.

FIG. 21C depicts that a dielectric layer may be formed on sidewalls 2106 of one or more layers of the pixel mesa structures to, for example, electrically isolate these layers at their sidewalls and may act as a passivation layer. In one aspect, the dielectric layer 2160 may be conformally deposited on surfaces of the including sidewalls 2106 of the precursor mesa structures and in regions between the precursor mesa structures. Dielectric layer 2160 may be, for example, a layer of SiO₂. Dielectric layer 2160 may have any desired thickness. In one aspect, the dielectric layer 2160 may have a thickness greater than about 50 nm and lower than about 500 nm in a surface normal direction of the mesa sidewall surfaces.

FIG. 21D depicts a second mesa etching processes performed using patterned etch mask 2155. The second mesa etching process may vertically etch through dielectric layer 2160 and at least a portion of the layer of the first semiconductor material 2110 to form pixel mesa structures of individual micro-LEDs. The second mesa etching process may be self-aligning according to one aspect. In the illustrated example, the second mesa etching process is shown to vertically etch through the layer of the first semiconductor material 2110. Each pixel mesa structure includes layer of first semiconductor material 2110 (e.g., n-GaN layer), active layer 2120, layer of second semiconductor material 2130 (e.g., p-GaN layer), first transparent conductive layer (e.g., p-contact layer) 2140, and etch mask layer 2155. After second mesa etching process, dielectric layer 2160 remains on sidewalls of active layer 2120, layer of second semiconductor material 2130, first transparent conductive layer 2140, and etch mask layer 2155.

FIG. 21E depicts that a layer of low index conductive material 2162 and a layer of low index (substantially nonconductive) material or DBR 2164 may be formed on and between pixel mesa structures shown in FIG. 21D. The layer of low index conductive material 2162 may include a material with a lower refractive index than the first semiconductor material. In one example, the low index conductive material is ITO. The layer of low index material or DBR 2164 includes a material with a refractive index lower than the layer of low index conductive material 2162. For example, layer of low index conductive material or DBR 2162 may be a layer of ITO having an index of refraction of ˜2.0, the layer of low index material 2164 may be SiO₂ having an index of refraction of ˜1.5, and the first semiconductor material may be GaN having an index of refraction of ˜2.5. Although the illustrated example shows layer of low index conductive material 2162 extending along the length of the sidewalls 2106 of the pixel mesa structures, in other examples layer of low index conductive material 2162 may extend along only sidewalls of layer of the first semiconductor material 2110 and not extend or only extend a portion of the length of the sidewalls of other layers of the individual pixel mesa structures. In one aspect, low index conductive material 2162 may be formed on sidewalls of at least the layer the first semiconductor material of the individual pixel mesa structures.

Although the illustrated example shown in FIG. 21E depicts forming both a layer of low index conductive material 2162 and a layer of low index (substantially nonconductive) material or DBR 2164, in another embodiment the layer of low index material or DBR 2164 is omitted.

FIG. 21F depicts a window may be formed in layer of low index conductive material 2162 and metal layer 2170 The metal layer 2170 is deposited in the window to form a metal plug 2172 with ohmic contact to layer of low index conductive material 2162. Metal layer 2170 may include one or more metal or metal alloy materials, such as aluminum (Al), silver (Ag), gold (Au), platinum (Pt), titanium (Ti), copper (Cu), or any combination thereof. The layer of low index conductive material 2162 and/or layer of low index material or DBR 2164 may reflect light emitted from the active region before light reaches the metal layer 2170. If the first semiconductor material is p-doped, the metal layer 2170 may act as a high reflectivity mesa sidewall p-electrode. If the first semiconductor material is n-doped, the metal layer 2170 may act as a high reflectivity mesa sidewall n-electrode.

FIG. 21G depicts a third etching processes performed using patterned etch mask 2155. The third mesa etching process may etch material stopping at patterned etch mask 2155.

FIG. 21H depicts that a dielectric material 2180 may be deposited on the pixel mesa structures shown in FIG. 21G. The dielectric material 2180 may then be planarized. Dielectric material 2180 may include, for example, an oxide such as SiO₂. Dielectric material 2180 may fill the gaps between individual pixel mesa structures. At each pixel mesa structure, a dielectric window 2183 may be opened (formed) in the dielectric material 2180 and through the etch mask layer 2155 to first transparent conductive layer 2140. The dielectric window may provide a port hole for a light path from the active layer 2120. Although the dielectric window is shown centered about the centerline of the mesa, the dielectric window may be offset in another implementation.

FIG. 21I depicts depositing a second transparent conductive layer 2184 (e.g., a second layer of ITO or other conductive oxide material layer) on each pixel mesa structure and through the dielectric window to contact the first transparent conductive layer 2140. In one aspect, the second transparent conductive layer 2184 has a footprint that is larger than the footprint of the pixel mesa structure to provide an end portion that is in the dead zone between adjacent pixel mesa structures.

FIG. 21J depicts that a layer of low index material or a DBR 2186 may be formed on second transparent conductive layer 2184 and dielectric material 2180. The low index material may have a lower refractive index than the second semiconductor material. In one aspect, the low index material is SiO₂. In one example, low index conductive material may include SiO₂ having an index of refraction ˜1.5 and second semiconductor material may be a GaN layer that is p-doped and has an index of refraction of ˜2.5.

FIG. 21K depicts that a window may be formed in the layer of low index material or DBR 2186 and a metal material 2190 may be deposited over the layer of low index material or DBR 2186 and through the window forming a metal plug 2192 in contact with the second transparent conductive layer 2184. In one aspect, the metal plug 2192 may be formed to contact an end portion of the second transparent conductive layer 2184 in a dead zone 2182 between pixel mesa structures. If the second semiconductor material is p-doped, the metal material 2190 may form high reflectivity wide bonding pad p-electrodes. If the second semiconductor material is n-doped, the metal material 2190 may form high reflectivity wide bonding pad n-electrodes. In one aspect, the metal material 2190 is ring-shaped. In another example, the metal plug 2192 is ring shaped and centered around a central axis of the pixel mesa structure. In other aspects, the metal plug 2192 may have another shape including, for example, multiple vias, pillars, linear segments, or arc segments. In another aspect, the metal plug 2192 may be polygon shaped such as rectangular, hexagonal. The metal layer 2190 for each micro-LED 2100 may have a size equal to, or larger than, the size of the mesa structure such as, for example, more than 10%, more than 20%, or more than 30% greater than the size of the mesa structure.

FIG. 21L depicts that the substrate 2101 may be removed (or thinned) and the buffer layer 2102 may be thinned, and lenses 2194 are formed on the backside. In one implementation, the metal material 2190 forms pads that may be bonded to a CMOS backplane. Although some examples are described herein as thinning the buffer layer, in some cases, the buffer layer may be removed.

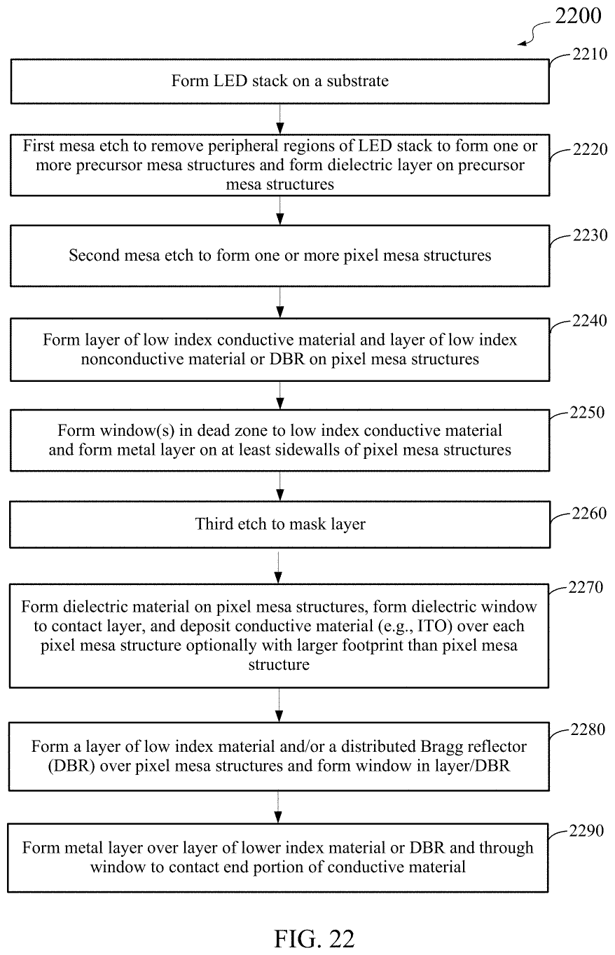

FIG. 22 includes a flowchart 2200 illustrating operations in an example of a method of fabricating an LED device having one or more LEDs (e.g., micro-LEDs), each LED having a high reflectivity mesa sidewall electrode and high reflectivity wide bonding pad electrode, according to certain embodiments. Although FIG. 22 illustrates a particular example of sequence of operations for fabricating the LED device with high reflectivity electrodes other sequences of operations can also be performed according to alternative embodiments. For example, alternative embodiments may perform the operations in a different order. Moreover, the illustrated operations may include multiple sub-operations that can be performed in various sequences as appropriate for the individual operation. Furthermore, some operations can be added or removed depending on the particular applications. In some implementations, two or more operations may be performed in parallel. One of ordinary skill in the art would recognize many variations, modifications, and alternatives.

Operations in block 2210 include forming an LED layer stack including multiple epitaxial layers grown on a substrate. The substrate may have a buffer layer disposed thereon. As described above with respect to, for example, FIG. 21A, in some embodiments, forming the LED layer stack on the substrate may include growing an epitaxial layer stack on the substrate. The epitaxial layer stack may be etched using a patterned etch mask to form the plurality of precursor mesa structures. For example, each LED stack may include a layer of a first semiconductor material (e.g., n-GaN), an active layer, a layer of a second semiconductor material (e.g., p-GaN), a first transparent conductive layer (e.g., ITO), and a patterned etch mask. The first semiconductor material may include a III-V material, such as GaN, and may be n-doped (e.g., with Si or Ge) or p-doped. The first transparent conductive layer (e.g., p-contact layer) may include a conductive oxide such as indium tin oxide (ITO) or a metal film such as, e.g., a Ag/Pt/Au film or a Al/Ni/Au film. The active layer may include III-V materials, such as one or more InGaN layers, one or more AlInGaP layers, and/or one or more GaN layers, which may form one or more heterostructures, such as one or more quantum wells or MQWs. In one aspect, active layer may comprise a nitride, phosphide, or arsenide alloy. Any suitable number of precursor mesa structures may be formed such as, for example, 2, 4, 6, 8, 9, or more mesas may be formed.

At block 2220, a first mesa etch is performed using a patterned mask to remove peripheral regions of the LED layer stack to form one or more precursor mesa structures, for example, as shown in FIG. 21B. In some embodiments, the etching may form multiple precursor mesa structures, such as 2, 4, 6, 8, 9, or more precursor mesa structures. In one example, the first mesa etching operation may etch through the first transparent conductive layer, the active layer, and the layer of the second semiconductor material. Also, at block 2220, a dielectric layer is conformally deposited on surfaces of the precursor mesa structures and in regions between the precursor mesa structures as shown in, for example FIG. 21C. The dielectric layer may isolate the first transparent conductive layer and may act as a passivation layer at the sidewalls of the active layer. The dielectric layer may be on at least a portion of the sidewalls of the layer of the second semiconductor material. The dielectric layer may include, for example, SiO₂ or Si₃N₄.

At block 2230, a second mesa etch is performed using a patterned mask to vertically etch through at least a portion of the layer of the first semiconductor material to form individual pixel mesa structures of, for example, individual micro-LEDs as shown in, for example, FIG. 21D. Each pixel mesa structure includes at least the layer of first semiconductor material (e.g., n-GaN layer), the active layer, the layer of second semiconductor material (e.g., p-GaN layer), and a contact layer (e.g., p-contact layer). In one example, the pixel mesa structure formed at block 2230 includes the layer of first semiconductor material (e.g., n-GaN layer), the active layer, the layer of second semiconductor material (e.g., p-GaN layer), a first transparent conductive layer (e.g., p-contact layer), and a mask layer. In another example, the mask layer is removed. The second mesa etch process also etches a portion of the dielectric layer leaving the dielectric layer on sidewalls of the pixel mesa structures in contact with at least the layer of the active layer and second semiconductor material. In one example, after the second mesa etching process, etch mask layer may be removed.

At block 2240, a layer of low index conductive material and a layer of low index (substantially nonconductive) material or a DBR are formed one or more of the sidewalls of layers of the pixel mesa structures. For example, layer of low index conductive material and a layer of low index material or the DBR may be deposited over and between the pixel mesa structures as shown, for example, in FIG. 21E. In another implementation, the layer of low index (substantially nonconductive) material or DBR is omitted. In this implementation, the layer of low index conductive material may be formed only along the sidewall of the layer of the first semiconductor material or may be formed on sidewalls of two or more layers of the pixel mesa structure. The low index conductive material has a lower refractive index than the first semiconductor material. In one aspect, the low index conductive material is ITO. In one example, low index conductive material may include ITO having an index of refraction ˜2.0 and first semiconductor material may be a GaN layer n-doped with, for example, Si or Ge having an index of refraction of ˜2.5. In this example, light with incident angle greater than a critical angle of about 53° may be totally internally reflected. Alternatively, the low index conductive material may be another transparent conductive oxide (TCO) such as indium zinc oxide (IZO), aluminum doped zinc oxide (AZO), or fluorine doped tin oxide (FTO).

In implementations with a layer of low index substantially nonconductive material or a DBR disposed over the layer of low index conductive material, at block 2250, at least one window may be formed in the layer of low index material or DBR in a dead zone between adjacent pixel mesa structures. A metal layer may then be deposited over the pixel mesa structures to form a metal plug through each window to the layer of low index conductive material. The metal layer may include one or more metal or metal alloy materials, such as aluminum (Al), silver (Ag), gold (Au), platinum (Pt), titanium (Ti), copper (Cu), or any combination thereof. If the first semiconductor material is p-doped, the metal layer may act as a high reflectivity mesa sidewall p-electrode. If the first semiconductor material is n-doped, the metal layer may act as a high reflectivity mesa sidewall n-electrode.

At block 2260, a third etch or other removal operation is performed to remove material to the mask layer such as shown, for example, in FIG. 21G.

At block 2270, a dielectric material is formed on the pixel mesa structures and fill in the gaps between pixel mesa structures, for example, as shown in FIG. 21H. The dielectric material may then be planarized. Dielectric material may include, for example, an oxide such as SiO₂. A dielectric window may be opened (formed) in the dielectric material to a first transparent conductive layer in contact with the layer of second semiconductor material. The contact layer may be, for example, a first ITO layer or other conductive oxide layer. Also, at block 2270, a second transparent conductive layer such as, e.g., a second layer of ITO, is formed on a portion of the surface of the dielectric material on each pixel mesa structure and through the dielectric window to contact the contact layer, for example, as shown in FIG. 21I. The second transparent conductive layer may be formed to have a larger footprint than the pixel mesa structure so that an edge portion is in a dead zone between pixel mesa structures.

At block 2280, a layer of low index material and/or a DBR is formed over the pixel mesa structures and on the second transparent conductive layer with the larger footprint than the pixel mesa structures, for example, as shown in FIG. 21J. In one example, the low index material may include SiO₂. A window may be formed in the layer/DBR to the second transparent conductive layer.

At block 2290, a metal layer is deposited on the layer of low index material and/or a DBR and through the window to contact the second transparent conductive layer, for example, as shown in FIG. 21K. A metal plug may be formed in the window through the layer of low index material and/or a DBR. The metal layer may include one or more metal or metal alloy materials, such as aluminum (Al), silver (Ag), gold (Au), platinum (Pt), titanium (Ti), copper (Cu), or any combination thereof. In this example, the high reflectivity wide bonding pad electrode includes the metal layer. In one implementation, the metal layer forms pads that may be bonded to a CMOS backplane. In one implementation, the substrate may be removed and lenses formed on the backside as shown, for example, in FIG. 21L.

Although certain illustrated examples are discussed with respect to micro-LED implementations, it would be understood that these examples may be implemented in other LEDs as well. Also, even though some of the Figures includes examples of materials, other materials may be used in these implementations.

Simulation Data

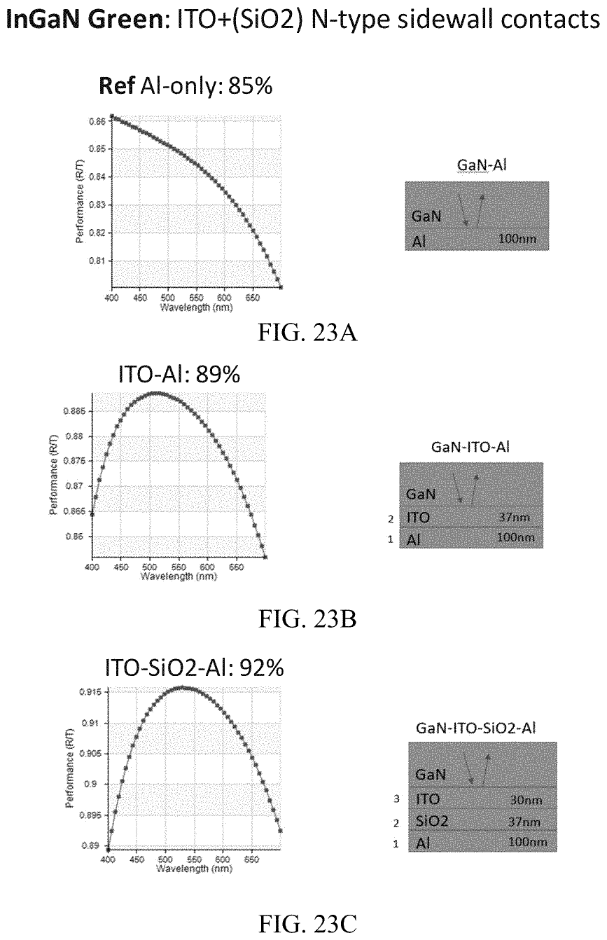

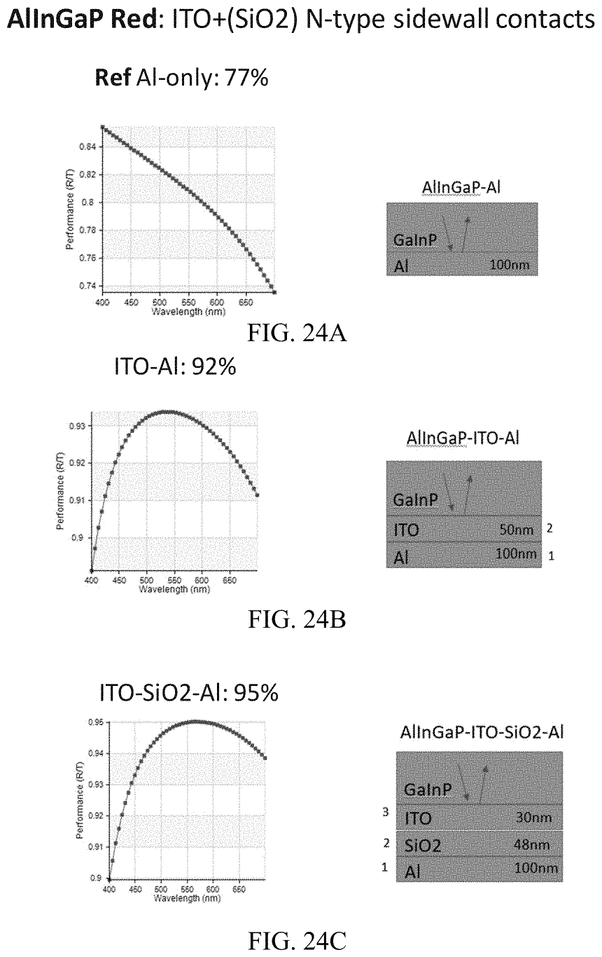

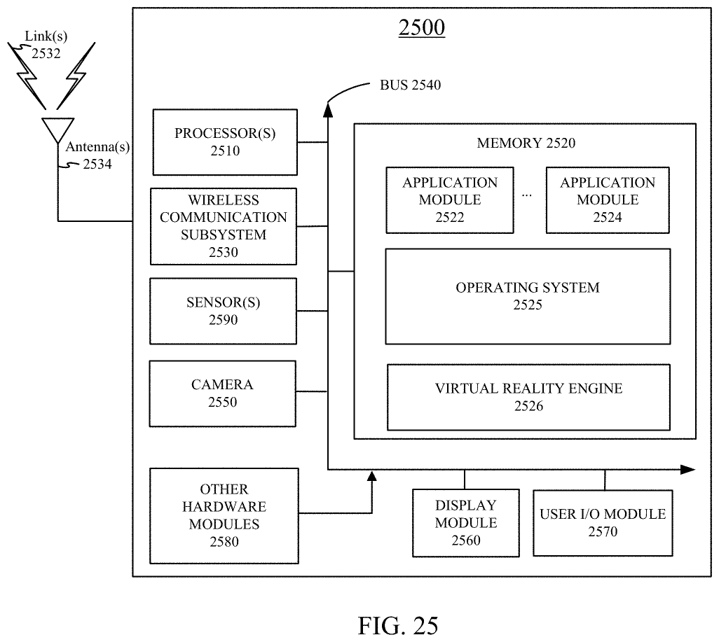

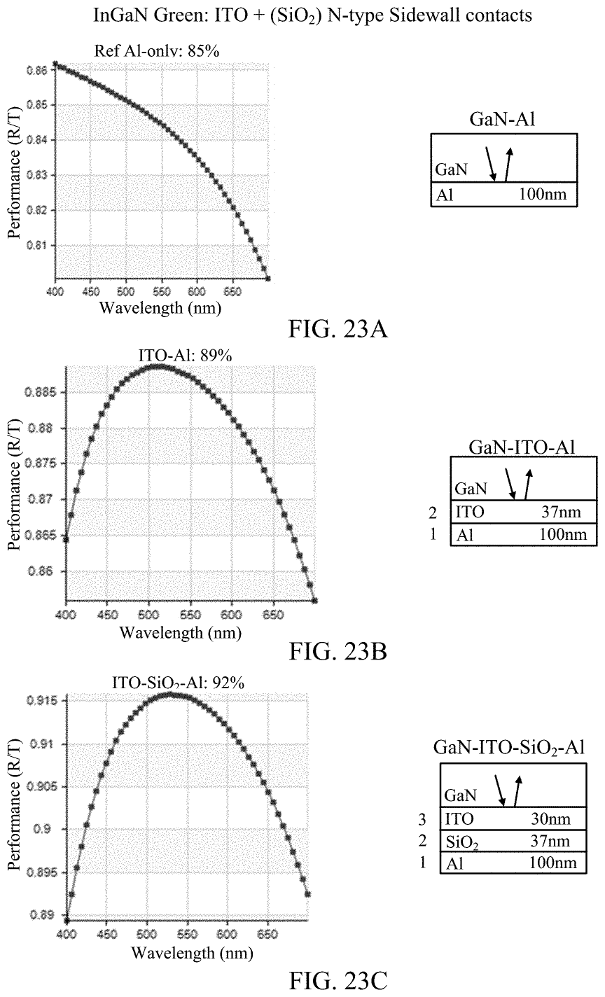

FIG. 23A is a plot of simulation data of performance for an InGaN-based green light emitting micro LED having an Aluminum (Al) electrode formed on sidewalls of an n-type semiconductor layer of a mesa structure, according to an aspect. FIG. 23B is a plot of simulation data of performance for a micro-LED having a layer of low index conductive material in the form of an ITO layer that is formed on sidewalls of an n-type semiconductor layer of a mesa structure and followed by an Aluminium layer such as, for example, the mesa structure 1105 shown in FIG. 11, according to an aspect. FIG. 23C is a plot of simulation data of performance for a micro-LED having a layer of low index conductive material in the form of an ITO layer and a layer of nonconductive low index material in the form of a layer of SiO₂ that are formed on sidewalls of an n-type semiconductor layer of a mesa structure and followed by an Aluminium layer such as, for example, the mesa structure 1205 shown in FIG. 12, according to an aspect.

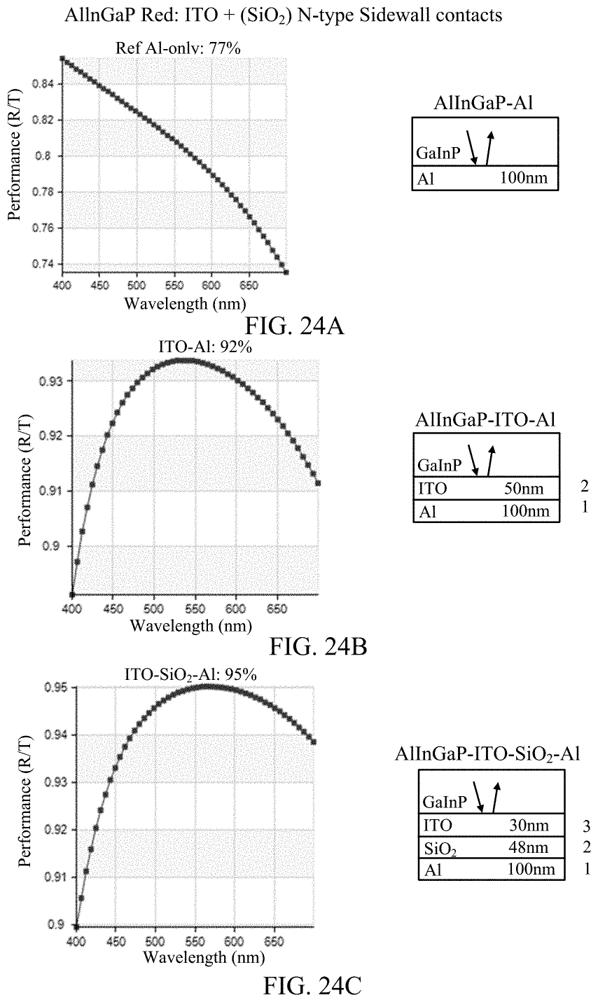

FIG. 24A is a plot of simulation data of performance for an AlInGaP-based red light emitting micro LED having an Aluminum (Al) electrode formed on sidewalls of an n-type semiconductor layer of a mesa structure, according to an aspect. FIG. 24B is a plot of simulation data of performance for a micro-LED having a layer of low index conductive material in the form of an ITO layer that is formed on sidewalls of an n-type semiconductor layer of a mesa structure and followed by an Aluminium layer such as, for example, the mesa structure 1105 shown in FIG. 11, according to an aspect. FIG. 24C is a plot of simulation data of performance for a micro-LED having a layer of low index conductive material in the form of an ITO layer and a layer of nonconductive low index material in the form of a layer of SiO₂ that are formed on sidewalls of an n-type semiconductor layer of a mesa structure and followed by an Aluminium layer such as, for example, the mesa structure 1205 shown in FIG. 12, according to an aspect.

Embodiments disclosed herein may be used to implement components of an artificial reality system or may be implemented in conjunction with an artificial reality system. Artificial reality is a form of reality that has been adjusted in some manner before presentation to a user, which may include, for example, a virtual reality, an augmented reality, a mixed reality, a hybrid reality, or some combination and/or derivatives thereof. Artificial reality content may include completely generated content or generated content combined with captured (e.g., real-world) content. The artificial reality content may include video, audio, haptic feedback, or some combination thereof, and any of which may be presented in a single channel or in multiple channels (such as stereo video that produces a three-dimensional effect to the viewer). Additionally, in some embodiments, artificial reality may also be associated with applications, products, accessories, services, or some combination thereof, that are used to, for example, create content in an artificial reality and/or are otherwise used in (e.g., perform activities in) an artificial reality. The artificial reality system that provides the artificial reality content may be implemented on various platforms, including an HMD connected to a host computer system, a standalone HMD, a mobile device or computing system, or any other hardware platform capable of providing artificial reality content to one or more viewers.

FIG. 25 is a simplified block diagram of an example electronic system 2500 of an example near-eye display (e.g., HMD device) for implementing some of the examples disclosed herein. Electronic system 2500 may be used as the electronic system of an HMD device or other near-eye displays described above. In this example, electronic system 2500 may include one or more processor(s) 2510 and a memory 2520. Processor(s) 2510 may be configured to execute instructions for performing operations at a number of components, and can be, for example, a general-purpose processor or microprocessor suitable for implementation within a portable electronic device. Processor(s) 2510 may be communicatively coupled with a plurality of components within electronic system 2500. To realize this communicative coupling, processor(s) 2510 may communicate with the other illustrated components across a bus 2540. Bus 2540 may be any subsystem adapted to transfer data within electronic system 2500. Bus 2540 may include a plurality of computer buses and additional circuitry to transfer data.

Memory 2520 may be coupled to processor(s) 2510. In some embodiments, memory 2520 may offer both short-term and long-term storage and may be divided into several units. Memory 2520 may be volatile, such as static random access memory (SRAM) and/or dynamic random access memory (DRAM) and/or non-volatile, such as read-only memory (ROM), flash memory, and the like. Furthermore, memory 2520 may include removable storage devices, such as secure digital (SD) cards. Memory 2520 may provide storage of computer-readable instructions, data structures, program modules, and other data for electronic system 2500. In some embodiments, memory 2520 may be distributed into different hardware modules. A set of instructions and/or code might be stored on memory 2520. The instructions might take the form of executable code that may be executable by electronic system 2500, and/or might take the form of source and/or installable code, which, upon compilation and/or installation on electronic system 2500 (e.g., using any of a variety of generally available compilers, installation programs, compression/decompression utilities, etc.), may take the form of executable code.

In some embodiments, memory 2520 may store a plurality of application modules 2522 through 2524, which may include any number of applications. Examples of applications may include gaming applications, conferencing applications, video playback applications, or other suitable applications. The applications may include a depth sensing function or eye tracking function. Application modules 2522-2524 may include particular instructions to be executed by processor(s) 2510. In some embodiments, certain applications or parts of application modules 2522-2524 may be executable by other hardware modules 2580. In certain embodiments, memory 2520 may additionally include secure memory, which may include additional security controls to prevent copying or other unauthorized access to secure information.

In some embodiments, memory 2520 may include an operating system 2525 loaded therein. Operating system 2525 may be operable to initiate the execution of the instructions provided by application modules 2522-2524 and/or manage other hardware modules 2580 as well as interfaces with a wireless communication subsystem 2530 which may include one or more wireless transceivers. Operating system 2525 may be adapted to perform other operations across the components of electronic system 2500 including threading, resource management, data storage control and other similar functionality.

Wireless communication subsystem 2530 may include, for example, an infrared communication device, a wireless communication device and/or chipset (such as a Bluetooth® device, an IEEE 802.11 device, a Wi-Fi device, a WiMax device, cellular communication facilities, etc.), and/or similar communication interfaces. Electronic system 2500 may include one or more antennas 2534 for wireless communication as part of wireless communication subsystem 2530 or as a separate component coupled to any portion of the system. Depending on desired functionality, wireless communication subsystem 2530 may include separate transceivers to communicate with base transceiver stations and other wireless devices and access points, which may include communicating with different data networks and/or network types, such as wireless wide-area networks (WWANs), wireless local area networks (WLANs), or wireless personal area networks (WPANs). A WWAN may be, for example, a WiMax (IEEE 802.16) network. A WLAN may be, for example, an IEEE 802.11x network. A WPAN may be, for example, a Bluetooth network, an IEEE 802.15x, or some other types of network. The techniques described herein may also be used for any combination of WWAN, WLAN, and/or WPAN. Wireless communications subsystem 2530 may permit data to be exchanged with a network, other computer systems, and/or any other devices described herein. Wireless communication subsystem 2530 may include a means for transmitting or receiving data, such as identifiers of HMD devices, position data, a geographic map, a heat map, photos, or videos, using antenna(s) 2534 and wireless link(s) 2532. Wireless communication subsystem 2530, processor(s) 2510, and memory 2520 may together comprise at least a part of one or more of a means for performing some functions disclosed herein.

Embodiments of electronic system 2500 may also include one or more sensors 2590. Sensor(s) 2590 may include, for example, an image sensor, an accelerometer, a pressure sensor, a temperature sensor, a proximity sensor, a magnetometer, a gyroscope, an inertial sensor (e.g., a module that combines an accelerometer and a gyroscope), an ambient light sensor, or any other similar module operable to provide sensory output and/or receive sensory input, such as a depth sensor or a position sensor. For example, in some implementations, sensor(s) 2590 may include one or more inertial measurement units (IMUs) and/or one or more position sensors. An IMU may generate calibration data indicating an estimated position of the HMD device relative to an initial position of the HMD device, based on measurement signals received from one or more of the position sensors. A position sensor may generate one or more measurement signals in response to motion of the HMD device. Examples of the position sensors may include, but are not limited to, one or more accelerometers, one or more gyroscopes, one or more magnetometers, another suitable type of sensor that detects motion, a type of sensor used for error correction of the IMU, or any combination thereof. The position sensors may be located external to the IMU, internal to the IMU, or any combination thereof. At least some sensors may use a structured light pattern for sensing.

Electronic system 2500 may include a display module 2560. Display module 2560 may be a near-eye display, and may graphically present information, such as images, videos, and various instructions, from electronic system 2500 to a user. Such information may be derived from one or more application modules 2522-2524, virtual reality engine 2526, one or more other hardware modules 2580, a combination thereof, or any other suitable means for resolving graphical content for the user (e.g., by operating system 2525). Display module 2560 may use LCD technology, LED technology (including, for example, OLED, ILED, μ-LED, AMOLED, TOLED, etc.), light emitting polymer display (LPD) technology, or some other display technology.

Electronic system 2500 may include a user input/output module 2570. User input/output module 2570 may allow a user to send action requests to electronic system 2500. An action request may be a request to perform a particular action. For example, an action request may be to start or end an application or to perform a particular action within the application. User input/output module 2570 may include one or more input devices. Example input devices may include a touchscreen, a touch pad, microphone(s), button(s), dial(s), switch(es), a keyboard, a mouse, a game controller, or any other suitable device for receiving action requests and communicating the received action requests to electronic system 2500. In some embodiments, user input/output module 2570 may provide haptic feedback to the user in accordance with instructions received from electronic system 2500. For example, the haptic feedback may be provided when an action request is received or has been performed.

Electronic system 2500 may include a camera 2550 that may be used to take photos or videos of a user, for example, for tracking the user's eye position. Camera 2550 may also be used to take photos or videos of the environment, for example, for VR, AR, or MR applications. Camera 2550 may include, for example, a complementary metal-oxide-semiconductor (CMOS) image sensor with a few millions or tens of millions of pixels. In some implementations, camera 2550 may include two or more cameras that may be used to capture 3-D images.

In some embodiments, electronic system 2500 may include a plurality of other hardware modules 2580. Each of other hardware modules 2580 may be a physical module within electronic system 2500. While each of other hardware modules 2580 may be permanently configured as a structure, some of other hardware modules 2580 may be temporarily configured to perform specific functions or temporarily activated. Examples of other hardware modules 2580 may include, for example, an audio output and/or input module (e.g., a microphone or speaker), a near field communication (NFC) module, a rechargeable battery, a battery management system, a wired/wireless battery charging system, etc. In some embodiments, one or more functions of other hardware modules 2580 may be implemented in software.

In some embodiments, memory 2520 of electronic system 2500 may also store a virtual reality engine 2526. Virtual reality engine 2526 may execute applications within electronic system 2500 and receive position information, acceleration information, velocity information, predicted future positions, or any combination thereof of the HMD device from the various sensors. In some embodiments, the information received by virtual reality engine 2526 may be used for producing a signal (e.g., display instructions) to display module 2560. For example, if the received information indicates that the user has looked to the left, virtual reality engine 2526 may generate content for the HMD device that mirrors the user's movement in a virtual environment. Additionally, virtual reality engine 2526 may perform an action within an application in response to an action request received from user input/output module 2570 and provide feedback to the user. The provided feedback may be visual, audible, or haptic feedback. In some implementations, processor(s) 2510 may include one or more GPUs that may execute virtual reality engine 2526.

In various implementations, the above-described hardware and modules may be implemented on a single device or on multiple devices that can communicate with one another using wired or wireless connections. For example, in some implementations, some components or modules, such as GPUs, virtual reality engine 2526, and applications (e.g., tracking application), may be implemented on a console separate from the head-mounted display device. In some implementations, one console may be connected to or support more than one HMD.

In alternative configurations, different and/or additional components may be included in electronic system 2500. Similarly, functionality of one or more of the components can be distributed among the components in a manner different from the manner described above. For example, in some embodiments, electronic system 2500 may be modified to include other system environments, such as an AR system environment and/or an IR environment.

The methods, systems, and devices discussed above are examples. Various embodiments may omit, substitute, or add various procedures or components as appropriate. For instance, in alternative configurations, the methods described may be performed in an order different from that described, and/or various stages may be added, omitted, and/or combined. Also, features described with respect to certain embodiments may be combined in various other embodiments. Different aspects and elements of the embodiments may be combined in a similar manner. Also, technology evolves and, thus, many of the elements are examples that do not limit the scope of the disclosure to those specific examples.

Specific details are given in the description to provide a thorough understanding of the embodiments. However, embodiments may be practiced without these specific details. For example, well-known circuits, processes, systems, structures, and techniques have been shown without unnecessary detail in order to avoid obscuring the embodiments. This description provides example embodiments only, and is not intended to limit the scope, applicability, or configuration of the invention. Rather, the preceding description of the embodiments will provide those skilled in the art with an enabling description for implementing various embodiments. Various changes may be made in the function and arrangement of elements without departing from the spirit and scope of the present disclosure.

Also, some embodiments were described as processes depicted as flow diagrams or block diagrams. Although each may describe the operations as a sequential process, many of the operations may be performed in parallel or concurrently. In addition, the order of the operations may be rearranged. A process may have additional steps not included in the figure. Furthermore, embodiments of the methods may be implemented by hardware, software, firmware, middleware, microcode, hardware description languages, or any combination thereof. When implemented in software, firmware, middleware, or microcode, the program code or code segments to perform the associated tasks may be stored in a computer-readable medium such as a storage medium. Processors may perform the associated tasks.

It will be apparent to those skilled in the art that substantial variations may be made in accordance with specific requirements. For example, customized or special-purpose hardware might also be used, and/or particular elements might be implemented in hardware, software (including portable software, such as applets, etc.), or both. Further, connection to other computing devices such as network input/output devices may be employed.

With reference to the appended figures, components that can include memory can include non-transitory machine-readable media. The term “machine-readable medium” and “computer-readable medium” may refer to any storage medium that participates in providing data that causes a machine to operate in a specific fashion. In embodiments provided hereinabove, various machine-readable media might be involved in providing instructions/code to processing units and/or other device(s) for execution. Additionally or alternatively, the machine-readable media might be used to store and/or carry such instructions/code. In many implementations, a computer-readable medium is a physical and/or tangible storage medium. Such a medium may take many forms, including, but not limited to, non-volatile media, volatile media, and transmission media. Common forms of computer-readable media include, for example, magnetic and/or optical media such as compact disk (CD) or digital versatile disk (DVD), punch cards, paper tape, any other physical medium with patterns of holes, a RAM, a programmable read-only memory (PROM), an erasable programmable read-only memory (EPROM), a FLASH-EPROM, any other memory chip or cartridge, a carrier wave as described hereinafter, or any other medium from which a computer can read instructions and/or code. A computer program product may include code and/or machine-executable instructions that may represent a procedure, a function, a subprogram, a program, a routine, an application (App), a subroutine, a module, a software package, a class, or any combination of instructions, data structures, or program statements.

Those of skill in the art will appreciate that information and signals used to communicate the messages described herein may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Terms, “and” and “or” as used herein, may include a variety of meanings that are also expected to depend at least in part upon the context in which such terms are used. Typically, “or” if used to associate a list, such as A, B, or C, is intended to mean A, B, and C, here used in the inclusive sense, as well as A, B, or C, here used in the exclusive sense. In addition, the term “one or more” as used herein may be used to describe any feature, structure, or characteristic in the singular or may be used to describe some combination of features, structures, or characteristics. However, it should be noted that this is merely an illustrative example and claimed subject matter is not limited to this example. Furthermore, the term “at least one of” if used to associate a list, such as A, B, or C, can be interpreted to mean any combination of A, B, and/or C, such as A, AB, AC, BC, AA, ABC, AAB, AABBCCC, etc.

Further, while certain embodiments have been described using a particular combination of hardware and software, it should be recognized that other combinations of hardware and software are also possible. Certain embodiments may be implemented only in hardware, or only in software, or using combinations thereof. In one example, software may be implemented with a computer program product containing computer program code or instructions executable by one or more processors for performing any or all of the steps, operations, or processes described in this disclosure, where the computer program may be stored on a non-transitory computer readable medium. The various processes described herein can be implemented on the same processor or different processors in any combination.

Where devices, systems, components or modules are described as being configured to perform certain operations or functions, such configuration can be accomplished, for example, by designing electronic circuits to perform the operation, by programming programmable electronic circuits (such as microprocessors) to perform the operation such as by executing computer instructions or code, or processors or cores programmed to execute code or instructions stored on a non-transitory memory medium, or any combination thereof. Processes can communicate using a variety of techniques, including, but not limited to, conventional techniques for inter-process communications, and different pairs of processes may use different techniques, or the same pair of processes may use different techniques at different times.

The specification and drawings are, accordingly, to be regarded in an illustrative rather than a restrictive sense. It will, however, be evident that additions, subtractions, deletions, and other modifications and changes may be made thereunto without departing from the broader spirit and scope as set forth in the claims. Thus, although specific embodiments have been described, these are not intended to be limiting. Various modifications and equivalents are within the scope of the following claims.

What is claimed is:

1. A light emitting diode (LED) device, comprising:
a plurality of mesa structures, each mesa structure comprising:
a layer of a first semiconductor material;
an active layer disposed on the layer of the first semiconductor material, the active layer configured to emit light; and
a layer of a second semiconductor material on the active layer; and
one or more transparent conductive layers disposed on the layer of second semiconductor material;
a first metal layer in contact with the one or more transparent conductive layers; and
a layer of low refractive index material between the first metal layer and the one or more transparent conductive layers;
wherein the layer of low refractive index material comprises material having a refractive index lower than a refractive index of the second semiconductor material and/or material of the one or more conductive layers.

2. The LED device of claim 1, wherein at least one of the one or more conductive layers is part of each mesa structure.

3. The LED device of claim 1, further comprising a contact layer formed on sidewalls of at least the layer of the first semiconductor material of each mesa structure.

4. The LED device of claim 1, further comprising a distributed Bragg reflector (DBR), the DBR comprising a plurality of material layers including the layer of low refractive index material, the plurality of material layers having a thickness or thicknesses configured to cause constructive interference with a wavelength band which the active layer is configured to emit.

5. The LED device of claim 1, wherein the one or more transparent conductive layers comprises a transparent conductive oxide material.

6. The LED device of claim 1, wherein at least one of the one or more transparent conductive layers has a footprint larger than a footprint of the mesa structure.

7. The LED device of claim 1, wherein the one or more transparent conductive layers comprises (i) a first transparent conductive layer in contact with the layer of the second semiconductor material and (ii) a second transparent conductive layer in contact with the first transparent conductive layer.

8. The LED device of claim 6, wherein the first metal layer comprises a metal plug passing through the layer of low refractive index material to contact an end portion of the conductive layer in a dead zone between adjacent mesa structures.

9. The LED device of claim 8, wherein the metal plug is ring-shaped and approximately centered around each mesa structure.

10. The LED device of claim 1, wherein (i) the first and second semiconductor material comprises GaN and the active layer comprises InGaN or (ii) the first semiconductor material comprises AlInGaP and the active layer comprises GaInP.

11. The LED device of claim 1, wherein (i) the first semiconductor material is n-doped and/or the second semiconductor material is p-doped or (ii) the second semiconductor material is n-doped and/or the first semiconductor material is p-doped.

12. The LED device of claim 1, further comprising a dielectric layer on sidewalls of the at least one of the one or more transparent conductive layers, the layer of the second semiconductor material, and the active layer.

13. The LED device of claim 1, wherein the LED device comprises a plurality of micro-LEDs having a pixel pitch between adjacent micro-LEDs of 2 μm.

14. A method of fabricating a light emitting diode (LED) device, the method comprising:
forming an LED layer stack comprising:
a layer of a first semiconductor material grown on a substrate;
an active layer on the layer of a first semiconductor material;
a layer of a second semiconductor material on the active layer;
a patterned conductive oxide layer on the layer of the second semiconductor material;
etching, using a mask layer, to remove peripheral regions of the active layer and the layer of the second semiconductor material from the LED layer stack to form one or more precursor mesa structures;
forming a first dielectric layer on the one or more precursor mesa structures;
etching, using the mask layer, to remove peripheral regions of the layer of the first semiconductor material to form one or more pixel mesa structures;
depositing a metal contact layer on sidewalls of at least the layer of the first semiconductor material of the one or more pixel mesa structures;
depositing a dielectric material on the metal contact layer and between the one or more pixel mesa structures;
opening a dielectric window in the dielectric material to the patterned conductive oxide layer;
depositing a second conductive oxide layer through the dielectric window to contact the patterned conductive oxide layer;
depositing a second dielectric layer or a distributed Bragg reflector (DBR) on the second conductive oxide layer;
opening a window in the second dielectric layer or the DBR, the window opened in a dead zone between adjacent mesa structures; and
forming a second metal layer in the window.

15. The method of claim 14, wherein the window is formed in a dead zone between adjacent mesa structures.

16. The method of claim 14, wherein forming the DBR comprises forming a plurality of material layers having a thickness or thicknesses configured to cause the DBR to constructively interfere with a wavelength band to which the active region is configured to emit.

17. The method of claim 14, wherein the substrate has a buffer layer disposed thereon.

18. A light emitting diode (LED) device, comprising:
a plurality of mesa structures, each mesa structure comprising:
a layer of a first semiconductor material;
an active layer disposed on the layer of the first semiconductor material, the active layer configured to emit light; and
a layer of a second semiconductor material on the active layer; and
one or more conductive layers disposed on the layer of second semiconductor material;
a first metal layer in contact with the one or more conductive layers;
a layer of a first low refractive index material between the first metal layer and at least one of the conductive layers, wherein the layer of low refractive index material comprises material having a refractive index lower than a refractive index of the second semiconductor material and/or material of the one or more conductive layers;
a layer of a second low index conductive material formed on sidewalls of the layer of the first semiconductor material of each mesa structure, the second low index conductive material having a refractive index lower than the first semiconductor material; and
a second metal layer formed on at least a portion of sidewalls of each mesa structure, the second metal layer in contact with the layer of the low index conductive material, wherein the layer of the low index conductive material is disposed between the second metal layer and the layer of the first semiconductor material.

19. The LED device of claim 18, wherein the second metal layer is formed on the layer of the second low index conductive material.

20. The LED device of claim 18, further comprising a dielectric layer or a second distributed Bragg reflector (DBR) disposed between the second metal layer and the layer of the second low index conductive material.
